(19) United States
(12) Patent Application Publication
(10) Pub. No.: US 2016/0372683 A1
(43) Pub. Date: Dec. 22, 2016

(54) ORGANIC ELECTROLUMINESCENCE ELEMENT, DISPLAY DEVICE, ILLUMINATION DEVICE, AND LIGHT-EMITTING COMPOSITION

(71) Applicant: KONICA MINOLTA, INC., Tokyo (JP)

(72) Inventors: Shuho TANIMOTO, Fukuoka-shi (JP); Dai IKEMIZU, Hachioji-shi (JP); Tomohiro OSHIYAMA, Hachioji-shi (JP); Hiroshi KITA, Hachioji-shi (JP); Hideo TAKA, Inagi-shi (JP)

(21) Appl. No.: 15/122,282

(22) PCT Filed: Feb. 26, 2015
(86) PCT No.: PCT/JP2015/055522

§ 371 Date: Aug. 29, 2016

(30) Foreign Application Priority Data
Mar. 7, 2014 (JP) 2014-045357

(51) Int. Cl. H01L 51/00; C09K 11/06

(52) U.S. Cl. CPC H01L 51/0072; C09K 11/06; H01L 51/0067; H01L 51/0052; H01L 51/0071; H01L 51/0074; H01L 51/007; H01L 51/0073; C09K 2211/1044; C09K 2211/1007; H01L 2251/552; H01L 51/5012

(57) ABSTRACT

An organic electroluminescent element includes an organic layer including a compound having an electron donor moiety and an electron acceptor moiety in a single molecule. The compound satisfies the following expression: (ΔE_{H}+ΔE_{L})≧2.0 eV. ΔE_{H} represents a difference in energy level between a highest energy occupied molecular orbital spreading over the electron donor moiety and a highest energy occupied molecular orbital spreading over the electron acceptor moiety, and ΔE_{L} represents a difference in energy level between a lowest energy unoccupied molecular orbital spreading over the electron donor moiety and a lowest energy unoccupied molecular orbital spreading over the electron acceptor moiety, determined by molecular orbital calculation. A highest energy occupied molecular orbital of the compound has an energy level of −5.2 eV or more. A lowest energy unoccupied molecular orbital of the compound has an energy level of −1.2 eV or less.

### TECHNICAL FIELD

The present invention relates to an organic electroluminescent element. The present invention also relates to a display device and a lighting device, each of the devices including the organic electroluminescent element, and to a luminous composition. In particular, the present invention relates to, for example, an organic electroluminescent element exhibiting improved emission efficiency.

### BACKGROUND ART

Organic electroluminescent (hereinafter may be referred to as “EL”) elements, which are based on electroluminescence of organic materials, have already been put into practice as new light-emitting systems capable of planar emission. Organic EL elements have recently been applied to electronic displays and also to lighting devices. Thus, a demand has arisen for further development of organic EL elements.

Organic EL elements emit light based on either the following two emission modes: “phosphorescence,” which occurs during transfer of excitons from the triplet excited state to the ground state, and “fluorescence,” which occurs during transfer of excitons from the singlet excited state to the ground state.

Under an electric field applied to such an organic EL element, holes and electrons are respectively injected from an anode and a cathode into a luminous layer, and the injected hole and electrons are recombined in the luminous layer, to generate excitons. In this case, singlet excitons and triplet excitons are generated at a ratio of 25%:75%; i.e., a phosphorescent mode, which is based on triplet excitons, theoretically provides internal quantum efficiency higher than that of a fluorescent mode.

Unfortunately, achievement of high quantum efficiency in a phosphorescent mode requires the use of a complex of iridium or platinum (i.e., a rare metal) as a central metal, which may cause future problems in the industry in terms of the reserves and price of rare metals.

In recent years, new techniques have been proposed for development of various fluorescent elements having improved emission efficiency.

For example, PTL 1 discloses a technique focused on a triplet-triplet annihilation (TTA) phenomenon (hereinafter also called “triplet-triplet fusion (TTF)”) wherein singlet excitons are generated by collision of two triplet excitons. This technique prompts the TTA phenomenon to occur effectively and thus improves the emission efficiency of a fluorescent element. Although this technique can increase the power efficiency of the fluorescent material (hereinafter may be referred to as “fluorescent compound”) to two to three times that of a traditional fluorescent material, the emission efficiency is not as high as that of a phosphorescent material because singlet excitons are theoretically generated at an efficiency of only about 40% by the TTA phenomenon.

Adachi, et al. have recently reported fluorescent materials based on a thermally activated delayed fluorescence (hereinafter may be referred to as “TADF”) mechanism and applicability of the materials to organic EL elements (refer to, for example, NPLs 1 to 4).

As illustrated in FIG. 1A, the TADF mechanism of a fluorescent material involves a phenomenon wherein excitons undergo reverse intersystem crossing from the triplet excited state to the singlet excited state if the difference between singlet excited energy level and triplet excited energy level (ΔEst) is smaller than that in a common fluorescent compound (i.e., ΔEst (TADF) is smaller than ΔEst (F) in FIG. 1A). This small difference in energy level (ΔEst) allows fluorescence to occur. In detail, triplet excitons generated at a probability of 75% through electrical excitation, which would otherwise fail to contribute to fluorescence, are transferred to the singlet excited state by heat energy during operation of the organic EL element. Fluorescence occurs by radiative deactivation (also referred to as “radiative transition”) during transfer of the excitons from the singlet excited state to the ground state. The TADF mechanism can theoretically achieve 100% internal quantum efficiency even in a fluorescent material.

A known technique effective for achieving high emission efficiency involves incorporation of a third component or TADF compound (also referred to as “luminous assisting material” or “assist dopant”) into a luminous layer containing a host compound and a luminous compound (refer to, for example, NPL 5). When singlet excitons (25%) and triplet excitons (75%) are generated on the compound or assist dopant by electrical excitation, the triplet excitons are converted into singlet excitons through reverse intersystem crossing (RISC).

The energy of the singlet excitons is transferred to the luminous compound (i.e., fluorescence resonance energy transfer (FRET)), and the luminous compound emits light by the transferred energy. Thus, the luminous compound emits light by the exciton energy (theoretically 100%), resulting in high emission efficiency.

As described above, various studies have been conducted to improve the emission efficiency of traditional organic EL elements, and some studies have shown successful results. Unfortunately, such traditional organic EL elements may fail to achieve the compatibility between high emission efficiency and long operational life. In particular, blue light-emitting elements, which generate excitons having high energy, encounter difficulty in prolonging the operational life as compared to green and red light-emitting elements.

The operational life of an organic EL element has often been examined only on the basis of the half-life of luminance. Variations in emission characteristics of the organic EL element (including emission efficiency) under energization indicate physical or chemical variations in components of a thin film in the element. In order to solve such a problem, the present inventors have conducted studies under the assumption that an improvement in durability of the thin film is essential for the organic EL element.

As described above, variations in emission characteristics of the thin film of the organic EL element may be caused by physical or chemical variations in components of the thin film. A conceivable measure to solve such a problem is an improvement in carrier transportation of a luminous material.

For example, NPL 6 discloses a significant variation in emission characteristics of an organic EL element during application of voltage, the element containing a luminous material acting as a strong electron trap. Although not clearly described in NPL6, this variation is probably caused by a local load applied to a portion of a thin film in the organic EL element for the reasons described below. Thus, NPL 6 describes a case where a chemical variation in components of an organic EL element affects the emission properties of the element.

According to NPL 6, the doping concentration of the luminous material is varied to adjust the carrier balance in the organic EL element for a prolonged operational life of the element. Unfortunately, the operational life of the organic EL element is still insufficient for practical use.

PTL 2 discloses a technique for adjustment of the carrier balance in a luminous layer through incorporation of a luminous unit, an electron-donating unit, and an electron withdrawing unit into a polymer material. Unfortunately, this technique cannot be applied to an organic layer composed of a low-molecular-weight material; i.e., the technique is applied only to a limited extent.

PTL 3 discloses a technique for adjustment of the carrier balance in a luminous layer through incorporation of an additive into the layer. PTL 4 discloses a technique for controlling the energy gap between a luminous layer and an adjacent layer to optimize the carrier balance in the entire light-emitting element. Unfortunately, these techniques cannot avoid a poor carrier balance caused by a luminous material.

### PRIOR ART DOCUMENTS

### Patent Documents

PTL 1: WO2012/133188
PTL 2: Japanese Unexamined Patent Application Publication No. 2005-239790
PTL 3: WO 2011/086941
PTL 4: Japanese Unexamined Patent Application Publication No. 2013-232629

### Non-Patent Documents

NPL 1: “Shomei ni Muketa Rinko Yuki EL Gijutsu no Kaihatsu (Development of phosphorescent OLED (organic light emitting diode) technology for lighting)” Oyo Buturi, Vol. 80, No. 4, 2011
NPL 2: H. Uoyama, et al., Nature, 2012, 492, 234-238
NPL 3: Q. Zhang, et al., J. Am. Chem. Soc., 2012, 134, 14706-14709
NPL 4: Yuki EL Toronkai Dai-10-Kai Reikai Yokoshu (Proceedings of Japan OLED Forum, 10th Meeting), pp. 11-12, 2010
NPL 5: H. Nakanotani, et al., Nature Communication, 2014, 5, 4016-4022
NPL 6: H. Nakanotani, et al., Sci. rep., 2013, 3, 2127

### SUMMARY OF THE INVENTION

### Problems to be Solved by the Invention

The present invention has been attained in consideration of the problems and circumstances described above. An object of the present invention is to provide an organic electroluminescent element including a highly durable film and capable of stable operation over a long period of time. Another object of the present invention is to provide a display device and a lighting device, each of the devices including the organic electroluminescent element. Still another object of the present invention is to provide a luminous composition.

including a compound having an electron donor moiety

### Means for Solving the Problem

The present inventors, who have conducted studies to solve the problems described above, have developed an organic electroluminescent element including an organic layer containing a compound having an electron donor moiety and an electron acceptor moiety in the molecule. The inventors have found that the organic layer exhibits highly improved durability depending on the relationship between the energy levels of the highest energy occupied molecular orbitals (HOMOs) of the whole molecule and these moieties and the energy levels of the lowest energy unoccupied molecular orbitals (LUMOs) of the whole molecule and these moieties, these energy levels being determined by molecular orbital calculation. The present invention has been accomplished on the basis of this finding.

The present invention to solve the problems described above is characterized by the following aspects:

1. An organic electroluminescent element including:

an organic layer including a compound having an electron donor moiety and an electron acceptor moiety in a single molecule, the compound satisfying the following expression: (ΔE_{H}+ΔE_{L})≧2.0 eV where ΔE_{H} represents a difference in energy level between a highest energy occupied molecular orbital spreading over the electron donor moiety and a highest energy occupied molecular orbital spreading over the electron acceptor moiety, and ΔE_{L} represents a difference in energy level between a lowest energy unoccupied molecular orbital spreading over the electron donor moiety and a lowest energy unoccupied molecular orbital spreading over the electron acceptor moiety, these energy levels being determined by molecular orbital calculation, wherein

a highest energy occupied molecular orbital of the compound has an energy level of −5.2 eV or more determined by the molecular orbital calculation, and

a lowest energy unoccupied molecular orbital of the compound has an energy level of −1.2 eV or less determined by the molecular orbital calculation.

2. The organic electroluminescent element according to item 1, wherein the compound emits thermally activated delayed fluorescence.

3. The organic electroluminescent element according to item 1 or 2, wherein the compound has a structure including a conjugated plane having at least 18 π-electrons.

4. The organic electroluminescent element according to any one of items 1 to 3, wherein the compound has a condensed ring structure composed of two or more 5-membered rings.

5. The organic electroluminescent element according to any one of items 1 to 4, wherein the compound has a structure represented by Formula (1):

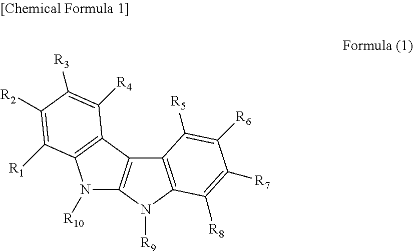

where R₁ to R₁₀, which are optionally identical to or different from one another, each represent a hydrogen atom, an alkyl group having 1 to 10 carbon atoms, an aryl or heteroaryl group having 6 to 30 carbon atoms; at least one of R₁ to R₁₀ represents an electron withdrawing aryl or heteroaryl group; and R₁ to R₁₀ each optionally have an substituent.

6. The organic electroluminescent element according to item 5, wherein the compound has a structure represented by Formula (2):

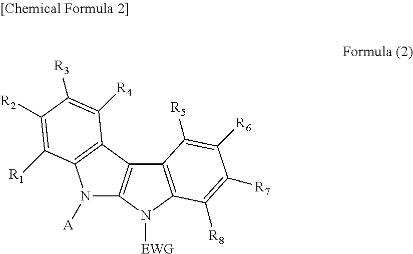

where R₁ to R₈, which are optionally identical to or different from one another, each represent a hydrogen atom, an alkyl group having 1 to 10 carbon atoms, or an aryl or heteroaryl group having 6 to 30 carbon atoms; A represents an alkyl group having 1 to 10 carbon atoms or an aryl or heteroaryl group having 6 to 30 carbon atoms, and A is optionally substituted by an alkyl group having 1 to 10 carbon atoms or an aryl or heteroaryl group having 6 to 12 carbon atoms, or optionally forms a ring with any substituent; EWG represents an electron withdrawing aryl or heteroaryl group; and R₁ to R₈, A, and EWG each optionally have a substituent.

7. The organic electroluminescent element according to item 6, wherein the compound has a structure represented by Formula (3):

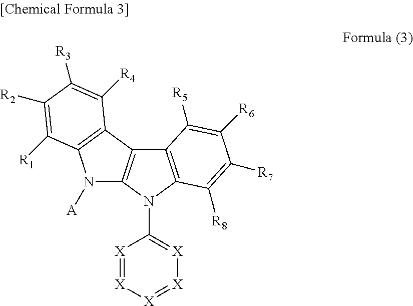

where R₁ to R₈, which are optionally identical to or different from one another, each represent a hydrogen atom, an alkyl group having 1 to 10 carbon atoms, or an aryl or heteroaryl group having 6 to 30 carbon atoms; A represents an alkyl group having 1 to 10 carbon atoms or an aryl or heteroaryl group having 6 to 30 carbon atoms, and A is optionally substituted by an alkyl group having 1 to 10 carbon atoms or an aryl or heteroaryl group having 6 to 12 carbon atoms, or optionally forms a ring with any substituent; X represents a carbon or nitrogen atom and is optionally substituted by an alkyl group having 1 to 10 carbon atoms or an aryl or heteroaryl group having 6 to 50 carbon atoms; the atoms represented by X are optionally identical to or different from one another; and R₁ to R₈, A, and X each optionally have a substituent.

8. A display device including the organic electroluminescent element according to any one of items 1 to 7.

9. A lighting device including the organic electroluminescent element according to any one of items 1 to 7.

10. A luminous composition including:

a compound having an electron donor moiety and an electron acceptor moiety in a single molecule, the compound satisfying the following expression: (ΔE_{H}+ΔE_{L})≧2.0 eV where ΔE_{H} represents a difference in energy level between a highest energy occupied molecular orbital spreading over the electron donor moiety and a highest energy occupied molecular orbital spreading over the electron acceptor moiety, and ΔE_{L} represents a difference in energy level between a lowest energy unoccupied molecular orbital spreading over the electron donor moiety and a lowest energy unoccupied molecular orbital spreading over the electron acceptor moiety, these energy levels being determined by molecular orbital calculation, wherein

a highest energy occupied molecular orbital of the compound has an energy level of −5.2 eV or more determined by the molecular orbital calculation, and

a lowest energy unoccupied molecular orbital of the compound has an energy level of −1.2 eV or less determined by the molecular orbital calculation.

### Effects of the Invention

The present invention can provide an organic electroluminescent element including a highly durable film and capable of stable operation over a long period of time. The present invention can also provide a display device and a lighting device, each of the devices including the organic electroluminescent element. The present invention can also provide a luminous composition.

An improvement in operational life is a significant challenge for traditional organic EL elements. The degradation of the emission efficiency of an organic EL element from the original level is caused by variations in physical properties of a thin charge-transporting film between electrodes and a variation in the state of components of the film under energization. In particular, such a variation in the luminous layer adversely affects the emission efficiency of the organic EL element.

The aforementioned variation is likely to occur in a blue light-emitting material in the excited state because the blue light-emitting material has a higher energy level than a red or green light-emitting material. Thus, design of an electrically stable luminous layer greatly contributes to a prolonged service life of an organic EL element that emits blue light.

As used herein, the term “blue light” refers to light having an x value of 0.15 or less and a y value of 0.3 or less in the CIE chromaticity diagram. Light with these values corresponds to light having a wavelength of about 460 nm in a bright line spectrum. A wavelength of 460 nm corresponds to an energy level of 2.7 eV. Thus, blue light emission requires a luminous material having a first excited singlet energy level of 2.7 eV or more.

The present inventors have found that the use of a compound satisfying specific parameters significantly improves the carrier balance in a luminous layer, leading to significant improvements in the durability and operational life of the resultant organic electroluminescent element.

### BRIEF DESCRIPTION OF DRAWINGS

FIG. 1A is a schematic illustration of an energy diagram of a common fluorescent compound and a typical TADF compound.

FIG. 1B is a schematic illustration of an energy diagram in the presence of an assist dopant.

FIG. 1C is a schematic illustration of an energy diagram of a host compound according to the present invention.

FIG. 2 is a schematic illustration of the molecular orbitals of a donor molecule and an acceptor molecule.

FIG. 3 is a schematic illustration of the relationship between the molecular orbital of a compound according to the present invention and the molecular orbitals of the donor molecule and the acceptor molecule.

FIG. 4 is a schematic illustration of the molecular orbitals of a donor moiety and an acceptor moiety of exemplary compound D32.

FIG. 5 is a schematic illustration of transportation of electric charges through the HOMOs of the donor moiety and the LUMOs of the acceptor moiety.

FIG. 6 is a schematic illustration of transportation of electric charges through the HOMOs of the donor moiety and the LUMOs of the acceptor moiety.

FIG. 7 is a schematic illustration of recombination of positive and negative charges passed through the entire molecule and generation of excitons.

FIG. 8 is a schematic illustration of interruption of transportation of electric charges due to recombination of the electric charges.

FIG. 9 is a schematic illustration of the abundance of orbitals containing localized positive charges.

FIG. 10 is a schematic illustration of the abundance of orbitals containing localized negative charges.

FIG. 11 is a graph illustrating the M-plot of electron transporting layers determined by impedance spectroscopy.

FIG. 12 is a graph illustrating the relationship between the ETL thickness and resistance of an organic EL element.

FIG. 13 is a schematic illustration of an equivalent circuit model of an organic EL element.

FIG. 14 is a graph illustrating the relationship between the resistance and voltage of layers of an initial organic EL element determined by impedance spectroscopy.

FIG. 15 is a graph illustrating the relationship between the resistance and voltage of layers of a degraded organic EL element determined by impedance spectroscopy.

FIG. 16 is a schematic illustration of a display device including an organic EL element.

FIG. 17 is a schematic illustration of an active matrix display device.

FIG. 18 is a schematic illustration of a pixel circuit.

FIG. 19 is a schematic illustration of a passive matrix display device.

FIG. 20 is a schematic illustration of a lighting device.

FIG. 21 is a schematic illustration of a lighting device.

### EMBODIMENTS FOR CARRYING OUT THE INVENTION

The organic electroluminescent element of the present invention includes an organic layer containing a compound having an electron donor moiety and an electron acceptor moiety in the single molecule. The compound satisfies the following expression: (ΔE_{H}+ΔE_{L})≧2.0 eV where ΔE_{H} represents a difference in energy level between the highest energy occupied molecular orbital spreading over the electron donor moiety and the highest energy occupied molecular orbital spreading over the electron acceptor moiety, and ΔE_{L} represents a difference in energy level between the lowest energy unoccupied molecular orbital spreading over the electron donor moiety and the lowest energy unoccupied molecular orbitals spreading over the electron acceptor moiety, these energy levels being determined by molecular orbital calculation. The highest energy occupied molecular orbital of the compound has an energy level of −5.2 eV or more determined by the molecular orbital calculation, and the lowest energy unoccupied molecular orbital of the compound has an energy level of −1.2 eV or less determined by the molecular orbital calculation. These technical characteristics are common in claims 1 to 10 of the present invention.

In an embodiment of the present invention, the compound preferably emits thermally activated delayed fluorescence in view of achievement of the advantageous effects of the present invention.

The compound preferably has a structure including a conjugated plane having at least 18 π-electrons in view of a strong interaction between molecules of the compound and surrounding molecules and advantageous carrier hopping.

The compound preferably has a condensed ring structure composed of two or more 5-membered rings for further enhancing the advantageous effects of the present invention.

In the present invention, the compound preferably has a structure represented by Formula (1). Since the indoloindole structure has a high electron-donating ability, the sum (ΔE_{H}+ΔE_{L}) increases, resulting in further enhancement of the advantageous effects of the invention.

In the present invention, the compound preferably has a structure represented by Formula (2). The electron withdrawing group directly bonded to a nitrogen atom of the indoloindole structure strongly withdraws electrons from the indoloindole structure, leading to an increase in the sum (ΔE_{H}+ΔE_{L}), resulting in further enhancement of the advantageous effects of the invention.

In the present invention, the compound preferably has a structure represented by Formula (3). The heteroatom-containing electron withdrawing group directly bonded to the amidine moiety of the indoloindole structure enhances intramolecular orbital separation, leading to an increase in the sum (ΔE_{H}+ΔE_{L}), resulting in further enhancement of the advantageous effects of the invention.

The organic electroluminescent element of the present invention is suitable for use in a display device. The display device including the organic electroluminescent element exhibits improved operational life.

The organic electroluminescent element of the present invention is suitable for use in a lighting device. The lighting device including the organic electroluminescent element exhibits improved operational life.

The luminous composition of the present invention includes a compound having an electron donor moiety and an electron acceptor moiety in the single molecule. The compound satisfies the following expression: (ΔE_{H}+ΔE_{L})≧2.0 eV where ΔE_{H} represents the difference in energy level between the highest energy occupied molecular orbital spreading over the electron donor moiety and the highest energy occupied molecular orbital spreading over the electron acceptor moiety, and ΔE_{L} represents the difference in energy level between the lowest energy unoccupied molecular orbital spreading over the electron donor moiety and the lowest energy unoccupied molecular orbital spreading over the electron acceptor moiety, the energy levels being determined by molecular orbital calculation. The highest energy occupied molecular orbital of the compound has an energy level of −5.2 eV or more determined by the molecular orbital calculation, and the lowest energy unoccupied molecular orbital of the compound has an energy level of −1.2 eV or less determined by the molecular orbital calculation.

The present invention, the contexture thereof, and embodiments and aspects for implementing the present invention will now be described in detail. As used herein, the term to between two numerical values indicates that the numeric values before and after the term are inclusive as the lower limit value and the upper limit value, respectively.

Now will be described emission modes of an organic EL element and luminous materials, which relate to the technical concept of the present invention.

<Emission Mode of Organic EL Element>

Organic EL elements emit light based on either the following two emission modes: “phosphorescence,” which occurs during transfer of excitons from the triplet excited state to the ground state, and “fluorescence,” which occurs during transfer of excitons from the singlet excited state to the ground state.

In the case of electrical excitation of an organic EL element, triplet excitons are generated at a probability of 75%, and singlet excitons are generated at a probability of 25%. Thus, a phosphorescent mode exhibits emission efficiency higher than that of a fluorescent mode, and is effective for reducing power consumption.

A fluorescent mode has been proposed which involves a triplet-triplet annihilation (TTA) mechanism (also called “triplet-triplet fusion (TTF)”) wherein emission efficiency is improved by generating singlet excitons from triplet excitons, which are generated at a probability of 75% and are generally thermally deactivated (i.e., non-radiative deactivation of the exciton energy).

Adachi, et al. have recently reported that a reduced energy gap between the singlet excited state and the triplet excited state causes reverse intersystem crossing from the triplet excited state (which has a lower energy level) to the singlet excited state depending on the Joule heat during emission and/or the temperature around a luminous element, resulting in fluorescence at substantially 100% (this phenomenon may be referred to as “thermally activated delayed fluorescence (TADF)”). They have also reported a fluorescent substance that achieves this phenomenon (refer to, for example, NPL 1).

<Phosphorescent Material>

In theory, phosphorescence has emission efficiency three times higher than that of fluorescence as described above. Unfortunately, energy deactivation from the triplet excited state to the singlet ground state (i.e., phosphorescence) is a forbidden transition and the intersystem crossing from the singlet excited state to the triplet excited state is also a forbidden transition; hence, the rate constant of such a transition is generally small, in other words, the transition is less likely to occur. Thus, the lifetime of excitons is on the order of milliseconds to seconds, and intended emission is difficult to achieve.

In the case of emission of a complex containing a heavy metal, such as iridium or platinum, the rate constant of the aforementioned forbidden transition increases by three or more orders of magnitude by the heavy atom effect of the central metal, and a phosphorescent quantum yield of 100% may be achieved depending on the selection of a ligand.

Unfortunately, such ideal emission requires the use of a rare metal (noble metal), such as a platinum group metal (e.g., iridium, palladium, or platinum), and the use of large amounts of rare metals may cause industrial problems on the reserves and price of the metals.

<Fluorescent Material>

Unlike the phosphorescent material, the fluorescent material is not necessarily a heavy metal complex, and may be an organic compound composed of combination of common elements, such as carbon, oxygen, nitrogen, and hydrogen. Alternatively, the fluorescent material may be substantially any substance; for example, a non-metal element, such as phosphorus, sulfur, or silicon, or a complex of a typical metal, such as aluminum or zinc.

<Delayed Fluorescent Material>

### [Excited Triplet-Triplet Annihilation (TTA) Delayed Fluorescent Material]

An emission mode utilizing delayed fluorescence has been developed for solving the problems involved in a fluorescent material. The TTA mode, which is based on collision between triplet excitons, is described by the formula shown below. In detail, the TTA mode is advantageous in that a portion of triplet excitons, the energy of which would otherwise be converted into only heat by non-radiative deactivation, undergo reverse intersystem crossing, to generate singlet excitons that can contribute to luminescence. In the organic EL element, the TTA mode can achieve an external quantum efficiency twice that achieved in a traditional fluorescent element.

T*+T*→*S*+S Formula:

where T* represents a triplet exciton, S* represents a singlet exciton, and S represents a molecule in the ground state.

Unfortunately, the TTA mode fails to achieve 100% internal quantum efficiency in principle because two triplet excitons generate only one singlet exciton that contributes to luminescence as illustrated in the aforementioned formula.

[Thermally Activated Delayed Fluorescent (TADF) Material]

The TADF mode, which is another highly efficient fluorescent mode, can solve problems involved in the TTA mode.

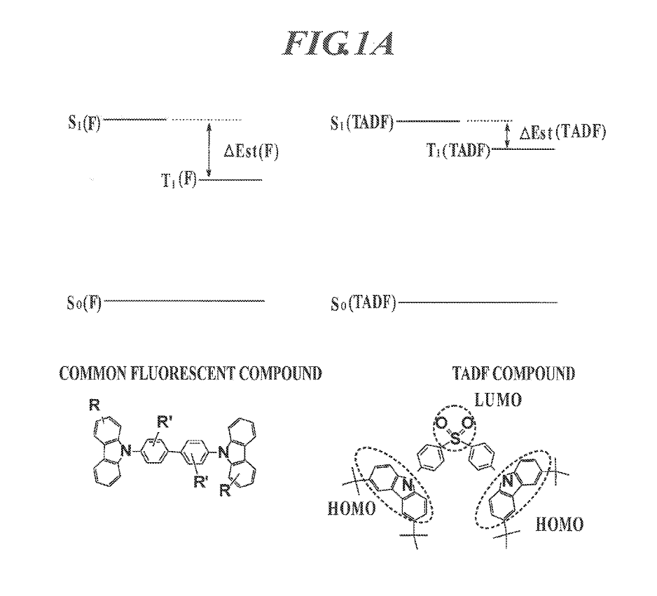

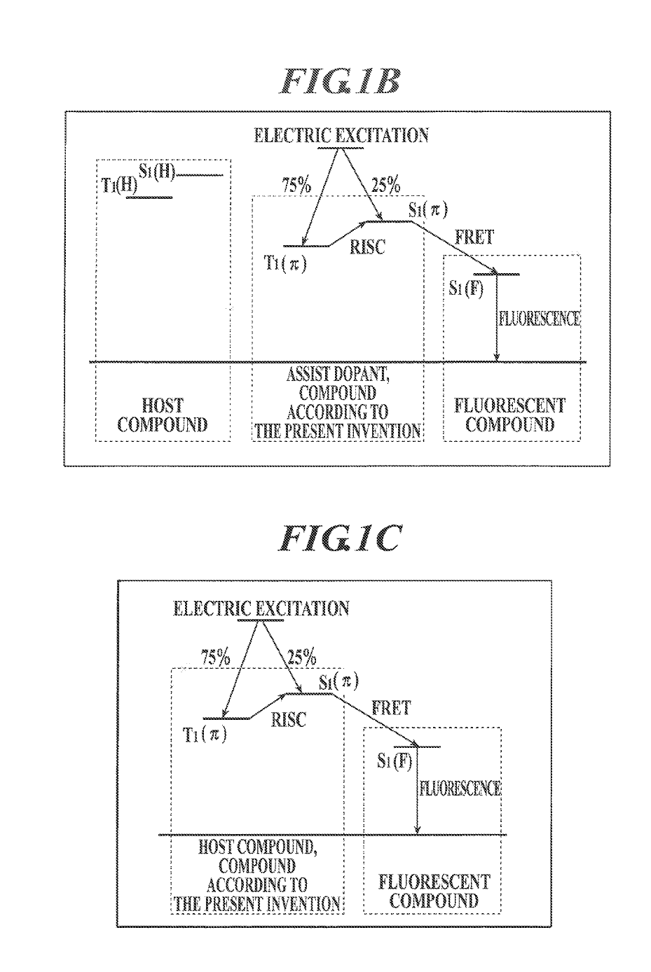

As described above, an advantage of the fluorescent material is boundless molecular design. Some molecularly designed compounds exhibit a very small difference between excited triplet energy level and excited singlet energy level (hereinafter the difference will be referred to as “ΔEst”) (see FIG. 1A).

Such a compound, although having no heavy atom in the molecule, undergoes reverse intersystem crossing from the triplet excited state to the singlet excited state because of small ΔEst. Since the rate constant of deactivation from the singlet excited state to the ground state (i.e., fluorescence) is very large, the transfer of triplet excitons to the ground state via the singlet excited state with emission of fluorescence is kinetically more advantageous than the transfer of the triplet excitons to the ground state with thermal deactivation (non-radiative deactivation). Thus, the TADF mode can ideally achieve 100% fluorescence.

<Requirements for Design of TADF Molecule>

In recent years, TADF molecules have been increasingly studied because they are more advantageous than fluorescent materials or phosphorescent materials in terms of production cost and theoretical maximum quantum efficiency as described above. TADF molecules, however, have their own problems.

The design of a TADF molecule requires a reduction in difference (ΔEst) between the singlet energy level and triplet energy level of the molecule. Although intersystem crossing is generally forbidden between the lowest excited singlet state and the lowest excited triplet state, a reduction in difference between the singlet energy level and the triplet energy level can override this general law, resulting in achievement of the intersystem crossing.

A small ΔEst sufficient for TADF requires the spatial separation of the HOMO and the LUMO in the molecule. The clear spatial separation of the HOMO and the LUMO requires incorporation of an electron donor moiety and an electron acceptor moiety in the single molecule (refer to NPL 2).

<HOMO-LUMO Separation and ΔEst)

As described above, the spatial separation of the HOMO and the LUMO in the molecule is required for TADF because the spatial overlap between these orbitals affects the difference in energy level between the excited singlet state and the exited triplet state; i.e., a small overlap between the orbitals involving electron transition leads to a small difference (ΔEst) between the singlet energy level and the triplet energy level. The reason for this is disclosed in Chihaya Adachi, et al., Adv. Mater. 2009, 21, 4802-4806, or “Mirai Zairyo o Soshutsusuru π-Denshikei no Kagaku (Science of π-Electron Systems for Creation of Future Materials)” edited by The chemical Society of Japan, Chapter 12, pp. 127-137, Kagaku-Dojin Publishing Co., Inc., Mar. 30, 2013.

<Carrier Transportation>

In an organic EL element, carriers are transported between organic molecules by a hopping mechanism. For example, holes are transported through the interaction between the HOMOs of molecules, and electrons are transported through the interaction of the LUMOs of molecules. Thus, a molecule having spatially separated HOMO and LUMO is advantageous for carrier hopping.

From this viewpoint, a TADF molecule with the spatially separated HOMO and LUMO should be advantageous for carrier transportation. Unfortunately, a traditional TADF molecule poses a problem of carrier transportation from a viewpoint different from that described above.

If a thin film of an organic EL element contains a molecule that is very stable in the form of anion radical, the molecule receives an electron under energization to form an anion radical, and the anion radical remains as it is without transmission of an electron to another adjacent molecule.

Thus, the presence of such a molecule reduces electron mobility from the cathode to the anode. In contrast, the presence of a molecule that is very stable in the form of cation radical in the thin film reduces hole mobility from the anode to the cathode.

In an organic EL element, electrons are generally injected from the cathode into an organic layer and then into a luminous layer through a thin charge transporting film (e.g., an electron transporting layer). If the material contained in the luminous layer is very stable in the form of anion radical; i.e., the material exhibits very high electron-trapping ability, transportation of electrons is substantially stopped at the interface between the luminous layer and the layer adjacent to the cathode. Thus, holes injected from the anode are recombined with electrons locally at the interface between the luminous layer and the layer adjacent to the cathode.

The aforementioned phenomenon generates excitons locally at the interface between the luminous layer and the layer adjacent to the cathode. This local generation of excitons causes various adverse effects on the emission properties of the organic EL element. In detail, localization of excitons at the interface between the luminous layer and the adjacent layer lead to quenching caused by the interaction between excitons, resulting in a reduction in emission efficiency.

Examples of the quenching phenomenon include singlet-triplet annihilation and triplet-triplet annihilation. In the case of a fluorescent material, singlet-triplet annihilation may cause a reduction in emission efficiency, whereas in the case of a phosphorescent material or a delayed fluorescent material, both singlet-triplet annihilation and triplet-triplet annihilation may cause a reduction in emission efficiency.

The aforementioned interfacial localization of excitons significantly adversely affects the operational life of the organic EL element. For example, the interfacial generation of high-energy excitons at high density is likely to cause reaction between the excitons and molecules near the interface, resulting in degradation and modification of the molecules.

Generation of carrier traps at the interface indicates the high-level presence of excitons and anion radicals or cation radicals near the excitons. The molecules near the interface may further be degraded and modified through the interaction between the excitons and the radicals, which have a higher reactivity than common molecules, or through the interaction between the excitons.

For the above reasons, the local generation of excitons at the interface adversely affects the operational life of the organic EL element. Under application of a high current for high-luminance emission, this adverse effect becomes more significant because of an increase in density of radicals generated by the carrier traps or excitons generated through bonding between the radicals and carriers.

In general, the aforementioned phenomenon less affects a fluorescent material that emits light from the singlet excited state because excitons involved in emission have a very short lifetime (on the order of nanoseconds) and are less likely to interact with surrounding molecules.

In the case of a phosphorescent material or a delayed fluorescent material, triplet excitons involved in emission generally have a lifetime on the order of microseconds to milliseconds and are more likely to interact with surrounding molecules.

Thus, the aforementioned local generation of excitons in a phosphorescent material or a delayed fluorescent material significantly leads to low emission efficiency and a short operational life.

In general, a TADF compound is stable in the form of any of cation radical and anion radical (i.e., bipolar properties) because the compound has an electron donor moiety and an electron acceptor moiety in the molecule and the HOMO and the LUMO are separated from each other.

The aforementioned orbital separation in a traditional TADF compound is achieved by combination of a weak electron donor moiety and a strong electron acceptor moiety.

Thus, the traditional TADF compound is much more stable in the form of anion radical than in the form of cation radical. This feature causes a problem when the compound is used as a material for an organic EL element.

The aforementioned problem can be solved to some extent through modification of the layer configuration. For example, the use of a host having a low HOMO level in combination of a dopant having a low HOMO level can prevent carrier trapping in the dopant for adjustment of the position of emission.

In such a case, the configuration of layers adjacent to the luminous layer must be modified in accordance with the HOMO level of the host. Unfortunately, the use of adjacent layers having low HOMO levels leads to a large difference in energy level between these layers and the electrodes, resulting in an increase in driving voltage.

Thus, it is preferred that the performance of the organic EL element be enhanced by fundamentally solving these problems through improvements in the physical properties of the dopant.

The aforementioned problems can be avoided through improvements in the carrier balance and the stability of a thin film. The compound according to the present invention does not inhibit the carrier transportation; thus the compound can provide a stable thin film for an organic EL element.

The above-described effective carrier transportation precludes localization of active species generated through energization in the luminous layer, resulting in a significant improvement in the operational life of the luminous element. The carrier transportation is effective for any light-emitting dopant, and is particularly effective for a blue light-emitting dopant.

A blue light-emitting material, which has a high energy level of excitons generated through energization, probably has a higher reactivity with surrounding host or dopant molecules than a green or red light-emitting dopant. The dispersion of generated excitons exhibits a significant effect in a system involving a blue light-emitting material.

Emission of light of 460 nm requires an excitation energy level of about 2.7 eV or more. Thus, the difference in energy level between the HOMO and the LUMO is preferably 2.7 eV or more for emission of blue light.

An organic EL element containing a low-molecular-weight compound as a dopant generally involves mixing of the dopant with a host for emission of light. In this case, carrier hopping is achieved by the interaction between the electron orbital of the dopant and that of the host.

Thus, the dopant preferably has a structure including a conjugated plane having at least 18 π-electrons for effective interaction between the dopant and the host.

As used herein, the term “conjugated plane” refers to a plane formed by an extended π-electron conjugated system.

As used herein, the term “conjugated plane having at least 18 π-electrons” refers to a conjugated plane over which at least 18 π-electrons are distributed. More preferably, the conjugated plane is rigidly secured by a condensed ring structure.

Although a large π-electron conjugated plane is significant for carrier hopping, an excessive increase in area of the plane leads to strong π-π interaction and cohesion of dopant molecules. Since the excessive cohesion of dopant molecules results in localization of excitons, the π-electron conjugated plane preferably has an appropriate area.

The compound preferably has a condensed ring structure composed of two or more 5-membered rings in view of the advantageous effects of the present invention. A five-membered cyclic compound containing a heteroatom (e.g., nitrogen or oxygen), such as pyrrole or furan, has a lone pair on the heteroatom, and the lone pair participates in the conjugated system. Thus, such a five-membered cyclic compound has an electron-rich ring, rather than a heterocyclic compound (e.g., pyridine) in which the electrons on the heteroatom does not participate in the conjugated system. The use of such a five-membered cyclic compound is preferred for enhancing the electron-donating ability of the ring. The condensed ring structure composed of two or more 5-membered rings is more preferred for enhancing the advantageous effects of the present invention because the structure exhibits higher electron-donating ability.

<Electron Donor Moiety and Electron Acceptor Moiety>

The present invention is characterized in that the compound serving as a luminous material (dopant) has both an electron donor moiety and an electron acceptor moiety.

In the compound used in the present invention, the electron donor moiety (hereinafter may be referred to simply as “donor moiety”) has high electron-donating ability and the electron acceptor moiety (hereinafter may be referred to simply as “acceptor moiety”) has high electron withdrawing ability.

Examples of the donor moiety of the compound used in the present invention include aryl, carbazolyl, arylamino, pyrrolyl, indolyl, indoloindolyl, indolocarbazolyl, phenacyl, phenoxazyl, and imidazolyl groups substituted by, for example, a substituted or unsubstituted alkoxy or amino group. The donor moiety is also preferably a group having a negative substituent constant (σ-p) determined by the Hammett equation.

Examples of the acceptor moiety of the compound used in the present invention include aryl, imidazolyl, benzimidazolyl, triazolyl, tetrazolyl, quinolyl, quinoxalyl, cinnolyl, quinazolyl, pyrimidyl, triazino, pyridyl, pyrazyl, pyridazyl, azacarbazolyl, heptazino, hexaazatriphenylene, benzofuranyl, azabenzofuranyl, dibenzofuranyl, benzodifuranyl, azadibenzofuranyl, thiazolyl, benzothiazolyl, oxazolyl, oxadiazolyl, benzoxazolyl, benzothiophenyl, azabenzothiophenyl, dibenzothiophenyl, and azadibenzothiophenyl groups substituted by, for example, a substituted or unsubstituted cyano, sulfinyl, sulfonyl, nitro, or acyl group. The acceptor moiety is also preferably a sulfur-containing heterocyclic compound, such as dibenzothiophene-s,s-dioxide, in which sulfur atom is oxidized. The acceptor moiety is also preferably a group having a positive substituent constant (σ-p) determined by the Hammett equation.

The electron donor and the electron acceptor are relatively balanced in the molecule and should not be limited to the aforementioned examples.

<ΔE_{H} and ΔE_{L}>

In the present invention, the values ΔE_{H} and ΔE_{L} are defined as indices for the energy levels of the donor moiety and the acceptor moiety in the molecule.

The parameters ΔE_{H} and ΔE_{L} used in the present invention are substantially as disclosed in K. Masui, et al., Org. Electron., 2012, 13, 985-991. The definition of these parameters in the present invention will now be described in detail.

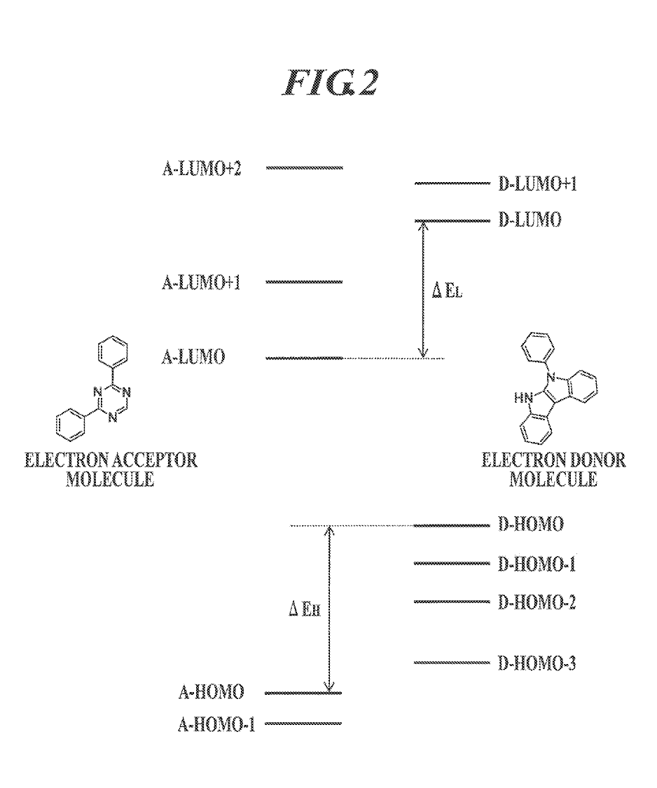

The concept of ΔE_{H} and ΔE_{L} will be detailed with reference to FIGS. 2 to 10.

In the following description, the highest occupied molecular orbital of a compound will be referred to as “HOMO”, and occupied molecular orbitals of the compound having energy levels lower than that of the HOMO will be referred to as “HOMO-1”, “HOMO-2”, . . . and “HOMO-n” in sequence.

The lowest unoccupied molecular orbital of the compound will be referred to as “LUMO”, and unoccupied molecular orbitals of the compound having energy levels higher than that of the LUMO will be referred to as “LUMO+1”, “LUMO+2”, . . . and “LUMO+n” in sequence.

For the sake of convenience, the donor moiety and the acceptor moiety of the compound according to the present invention will be described in the form of a donor molecule and an acceptor molecule, respectively. FIG. 2 illustrates the molecular orbitals of the donor molecule and the acceptor molecule.

In this case, the energy level of LUMO of the donor moiety (donor molecule) is higher than that of LUMO of the acceptor moiety (acceptor molecule), and the energy level of HOMO of the donor moiety is higher than that of HOMO of the acceptor moiety.

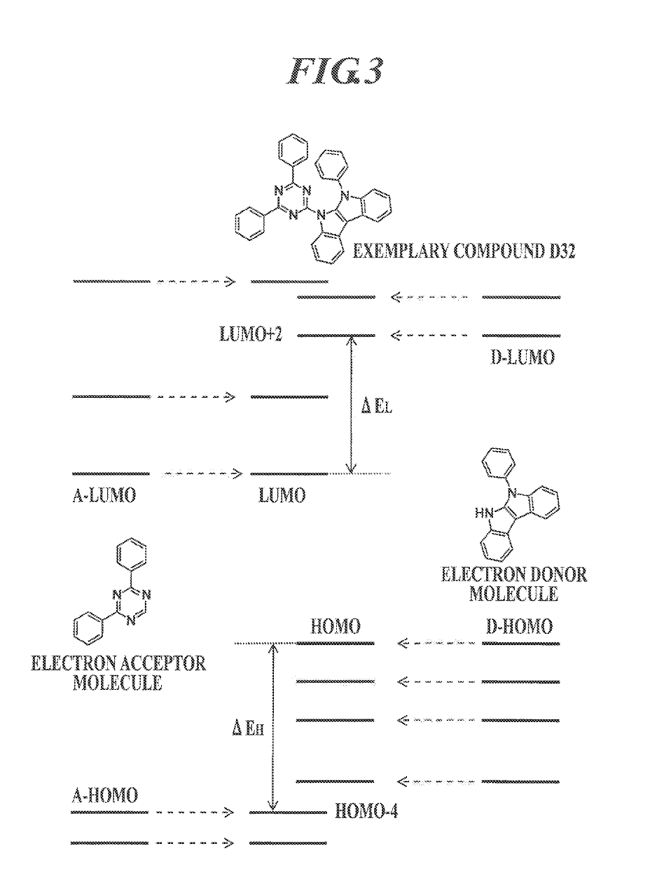

FIG. 3 schematically illustrates the relationship between the molecular orbitals of the compound according to the present invention and the molecular orbitals of the donor and acceptor molecules. As illustrated in FIG. 3, the orbitals of the donor moiety and the orbitals of the acceptor moiety are combined into orbitals of a single molecule. In detail, LUMO of the compound according to the present invention spreads over the acceptor moiety, and HOMO of the compound spreads over the donor moiety. Thus, LUMO of the compound according to the present invention corresponds to that of the acceptor molecule, and HOMO of the compound corresponds to that of the donor molecule.

Now will be described orbitals having energy levels higher than that of LUMO (e.g., LUMO+1 and LUMO+2) determined by molecular orbital calculation.

In the case of the compound illustrated in FIG. 3 (exemplary compound D32), LUMO and LUMO+1 spread over the acceptor moiety, whereas LUMO+2 spreads over the donor moiety.

As illustrated in this figure, LUMO of the donor molecule corresponds to LUMO+2 of the compound according to the present invention (exemplary compound D32).

Thus, LUMO+2 of exemplary compound D32 is derived from the donor moiety.

Orbitals having energy levels lower than that of HOMO will be described. In the case of exemplary compound D32 illustrated in FIG. 3, HOMO-1 to HOMO-3 spread over the donor moiety.

In contrast, HOMO-4 spreads over the acceptor moiety. As illustrated in this figure, HOMO of the acceptor molecule corresponds to HOMO-4 of the compound according to the present invention (exemplary compound D32).

Thus, HOMO-4 of exemplary compound D32 is derived from the acceptor moiety.

The compound according to the present invention (exemplary compound D32) is divided into a donor molecule and an acceptor molecule. In the present invention, ΔE_{L} represents the difference in energy level between LUMO, which corresponds to A-LUMO (i.e., the LUMO of the acceptor molecule), and LUMO+2, which corresponds to D-LUMO (i.e., the LUMO Of the donor molecule).

In the present invention, ΔE_{H} represents the difference in energy level between HOMO, which corresponds to D-HOMO (i.e., the HOMO of the donor molecule), and HOMO-4, which corresponds to A-HOMO (i.e., the HOMO of the acceptor molecule).

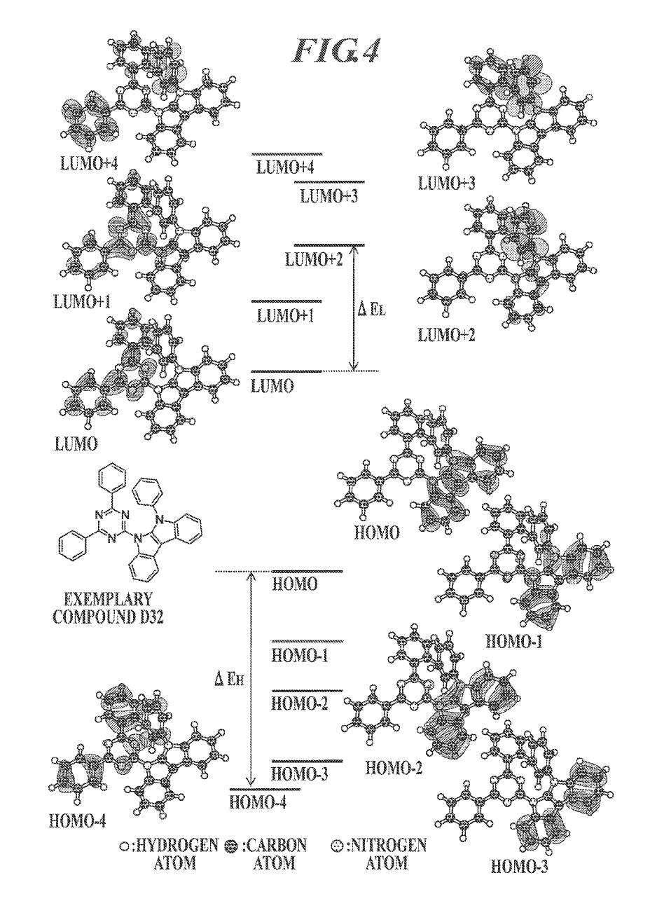

FIG. 4 illustrates molecular orbital images of exemplary compound D32. In exemplary compound D32, different molecular orbitals spread over the donor moiety and the acceptor moiety.

As illustrated in this figure, the highest energy occupied molecular orbital spreading over the donor moiety corresponds to HOMO, and the lowest energy unoccupied molecular orbital spreading over the donor moiety corresponds to LUMO+2.

The highest energy occupied molecular orbital spreading over the acceptor moiety corresponds to HOMO-4, and the lowest energy unoccupied molecular orbital spreading over the acceptor moiety corresponds to LUMO.

In the compound according to the present invention, ΔE_{H} is the difference in energy level between the highest energy occupied molecular orbital spreading over the acceptor moiety and the HOMO of the entire compound.

In the compound, ΔE_{L} is the difference in energy level between the lowest energy unoccupied molecular orbital spreading over the donor moiety and the LUMO of the entire compound.

The calculation of ΔE_{H} and ΔE_{L} requires determination whether molecular orbitals spread over the donor moiety or the acceptor moiety. The degree of spread of molecular orbitals over these moieties can be determined on the basis of data obtained with Gaussian 09.

In the present invention, ΔE_{L} is calculated by use of the unoccupied molecular orbital which has an energy level higher than LUMO, 50% or more of which spreads over the donor moiety, and which has the lowest energy level. ΔE_{H} is calculated by use of the occupied molecular orbital which has an energy level lower than HOMO, 50% or more of which spreads over the acceptor moiety, and which has the highest energy level.

In the present invention, HOMO/LUMO, ΔE_{H}, and ΔE_{L} are important parameters for effective carrier hopping. In particular, ΔE_{H} and ΔE_{L} are important parameters for securing an intermolecular spatial path of electrons. Energy level matching is required for lowering the barrier for the path as described below in detail.

<Effect of Energy Level of HOMO and LUMO on Carrier Hopping>

Although a traditional TADF compound may cause a problem due to its high electron-trapping ability, a thin charge-transporting film composed only of a TADF compound does not cause hole or electron trapping for the following conceivable reason. If an organic thin film of an organic EL element is composed of a single compound, the energy level of the LUMO of the compound is uniform in the thin film.

In general, a dopant used in an organic EL element is dispersed in a host. If the energy level of the LUMO of the dopant is significantly lower than that of the LUMO of the host, electrons transferred to the LUMO of the dopant are less likely to be transferred to the LUMO of the host, resulting in very low electron mobility.

If a thin charge-transporting film is composed of a single compound, the energy level of the HOMO of the compound is uniform in the thin film, resulting in no hole trapping. If the energy level of the HOMO of the dopant is much higher than that of the HOMO of the host, holes are less likely to be transferred from the dopant to the host.

Thus, appropriate matching of the energy level of the HOMO and/or LUMO of the host with that of the HOMO and/or LUMO of the dopant reduces the energy barrier during migration of holes or electrons in the thin film, resulting in effective carrier hopping in the luminous layer.

<Effect of ΔE_{H} and ΔE_{L} on Transportation of Electrons and Holes>

As described above, appropriate matching is required between the energy level of the HOMO/LUMO of the host and that of the HOMO/LUMO of the dopant.

ΔE_{H} and ΔE_{L} are important parameters for securing a spatial path for carrier hopping.

In view of smooth transfer of electric charges, it is preferred that electrons and holes linearly pass through the LUMOs and HOMOs of molecules, respectively. If the HOMOs and the LUMOs are combined together without being spatially separated from each other, holes and electrons pass through the combined space, leading to recombination of electric charges. Thus, the LUMOs and the HOMOs are preferably separated spatially from each other.

The recombination of electric charges, which is essential for generation of excitons, refers to slow migration of holes or electrons. Molecules having the same structure are oriented with one another to some extent during formation of a thin film.

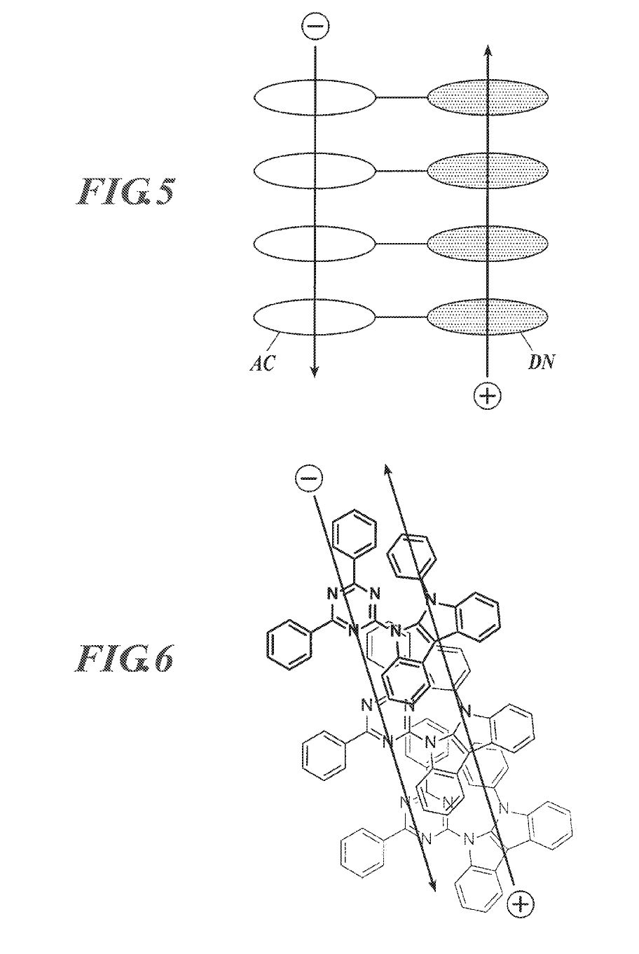

For example, molecules having many aromatic rings are likely to be oriented in a certain direction through n-n interaction (π-stacking). Thus, electric charges are preferably transported through the HOMOs of donor moieties (DNs) and the LUMOs of acceptor moieties (ACs) of oriented molecules as illustrated in FIGS. 5 and 6.

The aforementioned concept is particularly important because a material used for an organic EL element generally has an aromatic ring structure. As illustrated in FIGS. 5 and 6, the HOMO of a molecule interacts with the HOMO of an adjacent molecule through π-stacking, to form a tunnel suitable for transportation of holes. Similarly, the LUMO of a molecule interacts with the LUMO of an adjacent molecule to form a tunnel suitable for transportation of electrons.

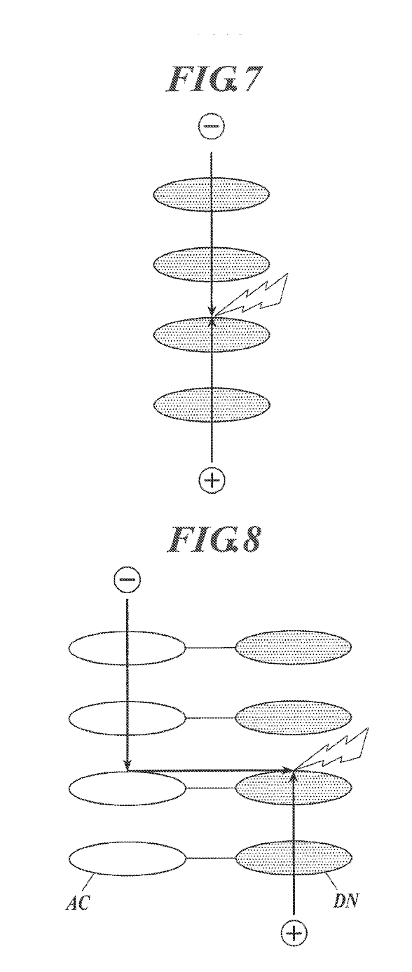

If the HOMOs and LUMOs of molecules are not spatially separated from each other as illustrated in FIG. 7, holes (hereinafter may be referred to as “positive charges”) and electrons (hereinafter may be referred to as “negative charges”) pass through the entire molecules, leading to recombination of electric charges (holes and electrons) and generation of excitons.

Thus, no spatial separation of the HOMOs and the LUMOs causes recombination of electric charges and generation of excitons, resulting in failure to form a tunnel for transportation of electric charges.

If the HOMOs and the LUMOs are spatially separated from each other but electrons and holes are not localized in the LUMOs and the HOMOs, respectively, as illustrated in FIG. 8, excitons are generated through recombination of electric charges, resulting in failure to form a tunnel for transportation of electric charges.

As used herein, the expression “no localization of holes in the HOMOs” indicates that molecules donate electrons to adjacent molecules to form cation radicals (corresponding to holes for carrier hopping) and the resultant positive charges (holes) are delocalized over the entire molecules and the LUMOs.

As used herein, the expression “no localization of electrons in the LUMOs” indicates that molecules accept electrons from adjacent molecules to form anion radicals (corresponding to electrons for carrier hopping) and the resultant negative charges (electrons) are delocalized over the entire molecules and the HOMOs.

Delocalization of positive charges (holes) or negative charges over the entire molecules facilitates generation of excitons without formation of the aforementioned tunnel. This phenomenon is undesired in view of smooth migration of electric charges.

In the present invention, ΔE_{H} is a parameter indicating the degree of localization of positive charges (holes) in the HOMOs of molecules in the form of cation radicals, and ΔE_{L} is a parameter indicating the degree of localization of negative charges (electrons) in the LUMOs of molecules in the form of anion radicals.

As described below with reference to the drawings, an increase in ΔE_{H} facilitates localization of positive charges in HOMOs (or the same spaces as HOMOs), and an increase in ΔE_{L} facilitates localization of negative charges in LUMOs (or the same spaces as LUMOs).

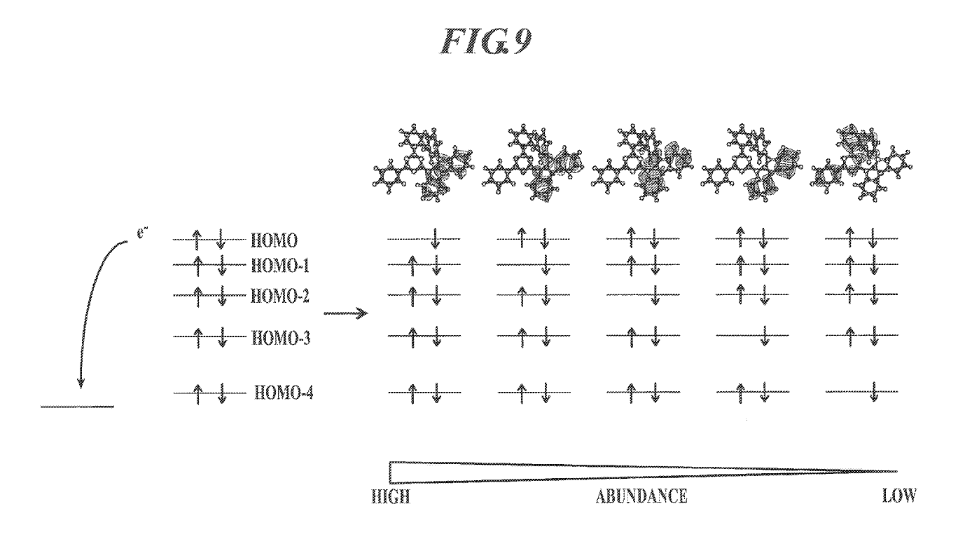

The expression “generation of cation radical” refers to generation of a positive charge (hole) on a molecule through transfer of one electron from any occupied orbital of the molecule. The cation radical is probably generated through transfer of one electron from HOMO of the molecule and the resultant positive charge is localized in HOMO. From the viewpoint of probability theory, the cation radical (positive charge) may be localized in HOMO-1 or HOMO-2 rather than in HOMO. FIG. 9 illustrates the abundance of orbitals containing localized positive charges for the case of exemplary compound D32.

The “generation of cation radical” corresponds to the generation and transfer of holes.

As described above, hole hopping preferably occurs between the HOMOs of two molecules. This hole hopping refers to the transfer of a positive charge (hole) localized on the donor moiety of a molecule to that of an adjacent molecule.

The localization of the positive charge in an orbital different from HOMO through the transfer of the positive charge (hole) by the interaction between the HOMOs of the molecules may inhibit effective hole transfer through the aforementioned charge-transporting tunnel.

In the case of exemplary compound D32, the localization of the cation radical (positive charge) in HOMO, HOMO-1, HOMO-2, or HOMO-3 corresponds to the localization of the positive charge over the donor moiety (i.e., in the same space as HOMO). In contrast, the localization of the positive charge in HOMO-4 corresponds to the localization of the positive charge over the acceptor moiety (i.e., in the same space as LUMO).

The transfer of an electron from an orbital having a level lower than that of HOMO requires an energy higher than that required for the transfer of an electron from HOMO. Thus, in the molecule in the form of radical, the probability of transfer of an electron from an orbital having a level lower than that of HOMO (i.e., the probability of localization of a positive charge in the orbital) is lower than the probability of transfer of an electron from HOMO (i.e., the probability of localization of a positive charge in HOMO).

An increase in ΔE_{H} leads to a reduction in the probability of the presence of a cation radical generated through transfer of an electron on the acceptor moiety (i.e., localization of the positive charge in LUMO). Thus, the positive charge is dominantly localized over the donor moiety.

A very small difference in energy level between HOMO and HOMO-1 accordingly leads to an increase in the probability of the presence of a molecule in the form of radical generated through localization of an electron in HOMO-1. The same shall apply to the case of an occupied orbital having an energy level lower than that of HOMO-2 or HOMO-3.

ΔE_{L} will be described as in ΔE_{H}.

The expression “generation of anion radical” refers to generation of a negative charge (electron) on a molecule through transfer of one electron to any unoccupied orbital of the molecule. The anion radical is probably generated through transfer of one electron to LUMO of the molecule and the resultant negative charge is localized in LUMO. From the viewpoint of probability theory, the anion radical (negative charge) may be localized in LUMO+1 or LUMO+2 rather than in LUMO. FIG. 10 illustrates the abundance of orbitals containing localized negative charges for the case of exemplary compound D32. The “generation of anion radical” corresponds to the generation and transfer of free electrons.

As described above, electron hopping preferably occurs between the LUMOs of two molecules. This electron hopping refers to the transfer of a negative charge (electron) localized on the acceptor moiety of a molecule to that of an adjacent molecule.

The localization of the negative charge in an orbital different from LUMO through the transfer of the negative charge (electron) by the interaction between the LUMOs of the molecules may inhibit effective electron transfer through the aforementioned charge-transporting tunnel.

In the case of exemplary compound D32, the localization of the anion radical (negative charge) in LUMO or LUMO+1 corresponds to the localization of the negative charge over the acceptor moiety (i.e., in the same space as LUMO). In contrast, the localization of the negative charge in LUMO+2 corresponds to the localization of the negative charge over the donor moiety (i.e., in the same space as HOMO).

The transfer of an electron to an orbital having a level higher than that of LUMO requires an energy higher than that required for the transfer of an electron to LUMO. Thus, in the molecule in the form of radical, the probability of transfer of an electron to an orbital having a level higher than that of LUMO (i.e., the probability of localization of a negative charge in the orbital) is lower than the probability of transfer of an electron to LUMO (i.e., the probability of localization of a negative charge in LUMO).

An increase in ΔE_{L} leads to a reduction in the probability of the presence of an anion radical generated through transfer of an electron on the donor moiety (i.e., localization of the negative charge in HOMO). Thus, the negative charge (electron) is dominantly localized over the acceptor moiety.

A very small difference in energy level between LUMO and LUMO+1 accordingly leads to an increase in the probability of the presence of a molecule in the form of radical generated through localization of an electron in LUMO+1. The same shall apply to the case of an unoccupied orbital having an energy level higher than that of LUMO+1 or LUMO+2.

Thus, it is preferred that ΔE_{L} and ΔE_{H} each have a certain level or more for effective carrier hopping through a charge-transporting tunnel. The present invention should satisfy the following relation: ΔE_{L}+ΔE_{H}≧2.0 eV.

As described above, the probability of localization of positive charges (holes) in HOMO or localization of negative charges (electrons) in LUMO depends on ΔE_{H} or ΔE_{L}. An increase in either ΔE_{H} or ΔE_{L} may fail to achieve satisfactory results. A large value of ΔE_{H} and substantially zero of ΔE_{L} are advantageous for hole transportation but disadvantageous for electron transportation, resulting in low carrier transportability.

In contrast, a large value of ΔE_{L} and substantially zero of ΔE_{H} are advantageous for electron transportation but disadvantageous for hole transportation, resulting in low carrier transportability.

In the present invention, ΔE_{H} is preferably 1.3 eV or more, and ΔE_{L} is preferably 0.7 eV or more.

A large ΔE_{H} leads to low probability of localization of positive charges in orbitals having a level lower than that of HOMO, and a large ΔE_{L} leads to low probability of localization of negative charges in orbitals having a level higher than that of LUMO, for the following probable reasons.

A large ΔE_{H} leads to localization of the hopping site of positive charges in a group of orbitals derived from the donor moiety of the molecule, resulting in smooth carrier hopping. In contrast, a small ΔE_{H} leads to delocalization of the hopping site of positive charges over a group of orbitals derived from the donor and acceptor moieties of the molecule, resulting in inhibition of carrier hopping.

Although not fully elucidated, the aforementioned phenomenon is probably attributed to, for example, hole mobility and electron mobility. If hole mobility is lower than electron mobility, molecules remain in the form of hole-transporting cation radicals for a period of time longer than that during which the molecules remain in the form of electron-transporting anion radicals. Thus, the localization of positive charges (holes) over the acceptor moiety during transportation of the positive charges increases the probability of inhibition of carrier transportation, and the localization of negative charges (electrons) over the donor moiety during transportation of the negative charges increases the probability of inhibition of carrier transportation. Hence, ΔE_{H} greater than ΔE_{L} probably leads to efficient charge transportation.

In the present invention, the HOMO energy of a dopant compound is calculated by B3LYP (functional)/6-31G(d) (basis function) with Gaussian 09 (Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford Conn., 2010). The HOMO energy is preferably −5.2 eV or higher, more preferably −5.0 eV or higher because the luminous layer of the organic EL element is generally composed of a luminous material containing the dopant dispersed in a host material.

A common host material used for the organic electroluminescent device, such as 4,4′-bis(9H-carbazol-9-yl)biphenyl (CBP), 1,3-bis(carbazol-9-yl)benzene (mCP), or 3,3-di(9H-carbazol-9-yl)biphenyl (mCBP), has a HOMO energy of about −5.4 to −5.2 eV as determined by the aforementioned calculation.

For effective hole transportation from the host to the dopant, the HOMO energy of the dopant is preferably higher than that of the host. More preferably, the HOMO energy of the dopant is higher by 0.2 eV or more than that of the host.

The dopant compound used in the present invention has a LUMO energy of preferably −1.2 eV or lower, more preferably −1.4 eV or lower, as calculated with Gaussian 09 (B3LYP (functional)/6-31G(d) (basis function)) because the luminous layer of the organic EL element is generally composed of a luminous material containing the dopant dispersed in a host material.

A common host material used for the organic electroluminescent device, such as CBP, mCP, or mCBP, has a LUMO energy of about −1.2 to −1.0 eV as determined by the aforementioned calculation. For effective electron transportation from the host to the dopant, the LUMO energy of the dopant is preferably equal to or lower than that of the host. More preferably, the LUMO energy of the dopant is higher by 0.2 eV or more than that of the host.

The dopant according to the present invention may have any structure. Any dopant satisfying the aforementioned requirements is suitable for use in the present invention.

<Impedance Spectroscopic Determination of Resistance of Thin Film>

The physical properties of a thin film composed of the compound according to the present invention can be evaluated on the basis of the resistance of the thin film determined by impedance spectroscopy.

Impedance spectroscopy is a technique for analyzing an organic EL element through conversion of a small variation in physical properties of the element into an electric signal and amplification of the signal. This technique can determine the resistance (R) and capacitance (C) of the organic EL element at high sensitivity without damage to the element.

Impedance spectroscopy typically involves analysis of electric properties by Z-plot, M-plot, and ∈-plot. The analytical process is detailed in, for example, “Hakumaku no Hyoka Handobukku (Handbook of Characterization of Thin Film)” (published by Technosystem Co., Ltd., pp. 423 to 425).

Now will be described a technique for impedance spectroscopic determination of the resistance of a specific layer of an organic EL element having, for example, the following configuration: ITO/(hole injecting layer (HIL))/(hole transporting layer (HTL))/(luminous layer (EML))/(electron transporting layer (ETL))/(electron injecting layer (EIL))/Al.

For measurement of the resistance of the electron transporting layer (ETL), for example, organic EL elements including ETLs having different thicknesses are prepared, and the M-plots of the elements are compared, to determine portions corresponding to the ETLs of the plotted curves.

FIG. 11 is a graph illustrating the M-plots of electron transporting layers having different thicknesses (30 nm, 45 nm, and 60 nm).

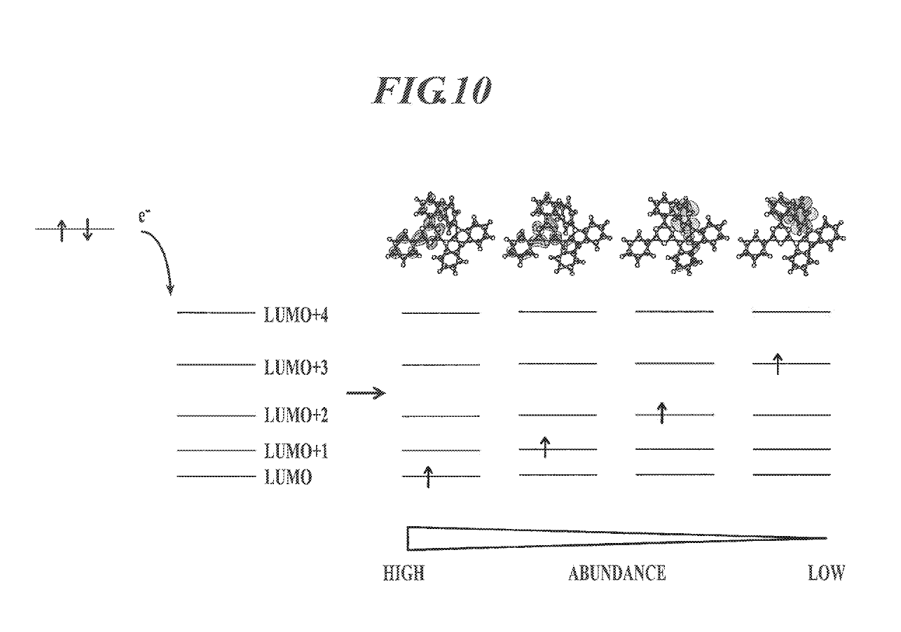

The resistances (R) determined from the M-plots are plotted against the thicknesses of the ETLs (see FIG. 12). The points are substantially on a single straight line, and thus the resistances can be determined at the corresponding thicknesses.

FIG. 12 is a graph illustrating the relationship between the ETL thicknesses and resistances of organic EL elements. As illustrated in FIG. 12 (the relationship between ETL thicknesses and resistances), the points are substantially on a single straight line, and thus the resistances can be determined at the corresponding thicknesses.

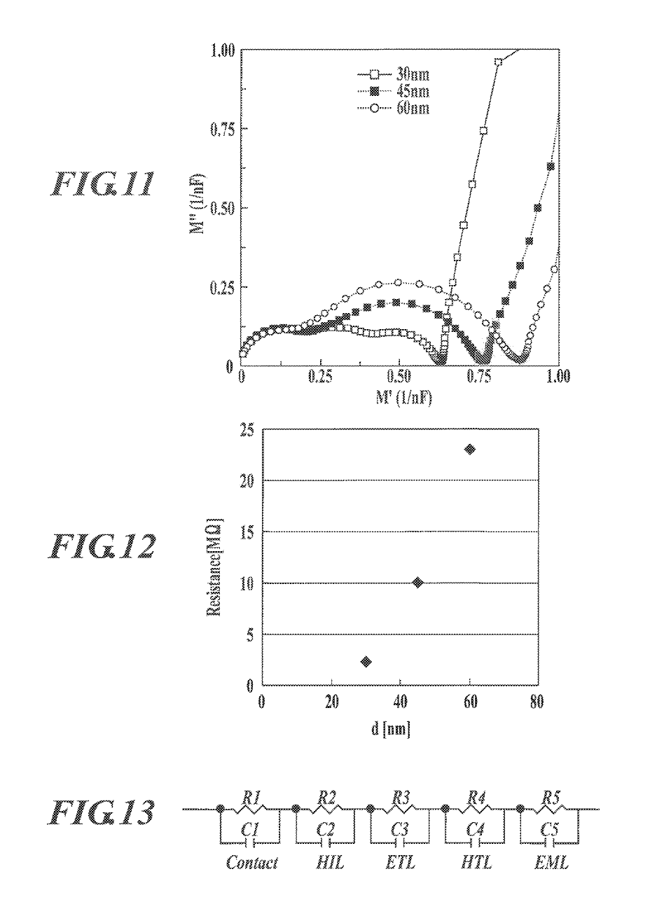

FIG. 14 illustrates the analytical results of the layers of an organic EL element in the form of an equivalent circuit model (FIG. 13), the organic EL element having the following configuration: ITO/HIL/HTL/EML/ETL/EIL/Al. FIG. 14 is a graph illustrating the relationship between the resistances and voltages of the layers.

FIG. 13 illustrates the equivalent circuit model of the organic EL element having the configuration: ITO/HIL/HTL/EML/ETL/EIL/Al.

FIG. 14 illustrates the analytical results of the organic EL element having the configuration of ITO/HIL/HTL/EML/ETL/EIL/Al.

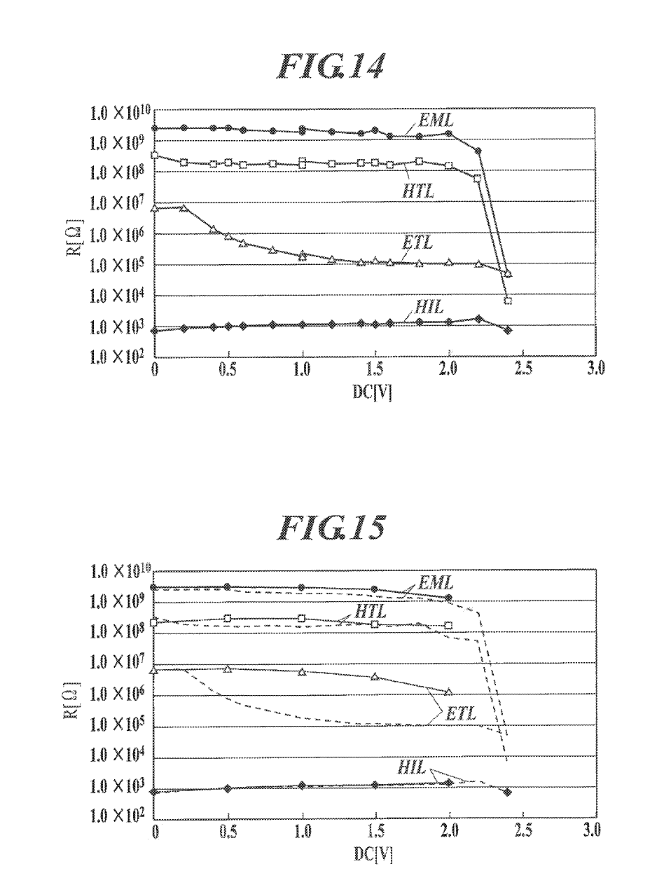

The organic EL element was caused to emit light for a long period of time, and the layers of the degraded organic EL element were analyzed under the same conditions as described above. FIG. 15 illustrates the analytical results before and after the long-term operation. Table 1 illustrates the resistances of the layers at a voltage of 1V. FIG. 15 illustrates the analytical results of the degraded organic EL element.

TABLE 1

| | | | | EML |
|---|---|---|---|---|
| | HIL (Ω) | ETL (Ω) | HTL (Ω) | (Ω) |
| Before | 1.1k | 0.2M | 0.2G | 1.9G |
| driving | | | | |
| After | 1.2k | 5.7M | 0.3G | 2.9G |
| degradation | | | | |

The results demonstrate that the resistance (at a DC voltage of 1 V) of only the ETL significantly increases by a factor of about 30 in the degraded organic EL element.

As described in Examples below, a variation in resistance of the organic EL element by energization can be determined by the aforementioned techniques.

<<Layer Configuration of Organic EL Element>>

The organic electroluminescent (EL) element of the present invention includes an organic layer containing a compound having a donor moiety and an acceptor moiety in the single molecule. The compound satisfies the following expression: (ΔE_{H}+ΔE_{L})≧2.0 eV where ΔE_{H} represents a difference in energy level between the highest energy occupied molecular orbital spreading over the donor moiety and the highest energy occupied molecular orbital spreading over the acceptor moiety, and ΔE_{L} represents a difference in energy level between the lowest energy unoccupied molecular orbital spreading over the donor moiety and the lowest energy unoccupied molecular orbital spreading over the acceptor moiety, these energy levels being determined by molecular orbital calculation. The highest energy occupied molecular orbital of the compound has an energy level of −5.2 eV or more determined by the molecular orbital calculation, and the lowest energy unoccupied molecular orbital of the compound has an energy level of −1.2 eV or less determined by the molecular orbital calculation.

Now will be described the respective layers of the organic EL element, and compounds contained in the layers.

Typical examples of the configuration of the organic EL element of the present invention include, but are not limited to, the following configurations.

(1) Anode/luminous layer/cathode

(2) Anode/luminous layer/electron transporting layer/cathode

(3) Anode/hole transporting layer/luminous layer/cathode

(4) Anode/hole transporting layer/luminous layer/electron transporting layer/cathode

(5) Anode/hole transporting layer/luminous layer/electron transporting layer/electron injecting layer/cathode

(6) Anode/hole injecting layer/hole transporting layer/luminous layer/electron transporting layer/cathode

(7) Anode/hole injecting layer/hole transporting layer/(electron blocking layer)/luminous layer/(hole blocking layer)/electron transporting layer/electron injecting layer/cathode

Among the aforementioned configurations, configuration (7) is preferred, but any other configuration may be used.

The luminous layer according to the present invention is composed of a single layer or a plurality of sublayers. A luminous layer composed of a plurality of luminous sublayers may include a non-luminous intermediate sublayer between the luminous sublayers.

A hole blocking layer (also referred to as “hole barrier layer”) or an electron injecting layer (also referred to as “cathode buffer layer”) may optionally be disposed between the luminous layer and the cathode. An electron blocking layer (also referred to as “electron barrier layer”) or a hole injecting layer (also referred to as “anode buffer layer”) may be disposed between the luminous layer and the anode.

The electron transporting layer according to the present invention, which has a function of transporting electrons, encompasses the electron injecting layer and the hole blocking layer in a broad sense. The electron transporting layer may be composed of a plurality of sublayers.

The hole transporting layer according to the present invention, which has a function of transporting holes, encompasses the hole injecting layer and the electron blocking layer in a broad sense. The hole transporting layer may be composed of a plurality of sublayers.

In the typical configurations described above, any of the layers other than the anode and the cathode may also be referred to as “organic layer.”

(Tandem Structure)

The organic EL element of the present invention may have a tandem structure including a plurality of luminous units each including at least one luminous layer.

A typical tandem structure of the organic EL element is as follows:

Anode/first luminous unit/intermediate layer/second luminous unit/intermediate layer/third luminous unit/cathode

In this structure, the first, second, and third luminous units may be identical to or different from one another. Any two of the luminous units may be identical to each other, and may be different from the remaining one unit.

Two luminous units may be bonded directly to each other, or an intermediate layer may be disposed therebetween. The intermediate layer is generally also called “intermediate electrode,” “intermediate conductive layer,” “charge generating layer,” “electron extraction layer,” “connection layer,” or “intermediate insulating layer.” Any known material can be used for forming an intermediate layer capable of supplying electrons to the adjacent layer toward the anode and supplying holes to the adjacent layer toward the cathode.

Examples of the material used for the intermediate layer include, but are not limited to, conductive inorganic compounds, such as indium tin oxide (ITO), indium zinc oxide (IZO), ZnO₂, TiN, ZrN, HfN, TiOx, VOx, CuI, InN, GaN, CuAlO₂, CuGaO₂, SrCu₂O₂, LaB₆, RuO₂, and Al; two-layer films, such as Au/Bi₂O₃; multi-layer films, such as SnO₂/Ag/SnO₂, ZnO/Ag/ZnO, Bi₂O₃/Au/Bi₂O₃, TiO₂/TiN/TiO₂, and TiO₂/ZrN/TiO₂; fullerene compounds, such as C₆₀; conductive organic substances, such as oligothiophenes; and conductive organic compounds, such as metal phthalocyanines, metal-free phthalocyanines, metal porphyrins, and metal-free porphyrins.

Examples of preferred luminous units include, but are not limited to, the aforementioned typical element configurations (1) to (7) (exclusive of the anode and the cathode).

Specific examples of tandem organic EL elements include, but are not limited to, element configurations and constituent materials disclosed in U.S. Pat. Nos. 6,337,492, 7,420,203, 7,473,923, 6,872,472, 6,107,734, and 6,337,492, International Patent Publication WO2005/009087, Japanese Unexamined Patent Application Publication Nos. 2006-228712, 2006-24791, 2006-49393, 2006-49394, 2006-49396, 2011-96679, and 2005-340187, Japanese Patent Nos. 4711424, 3496681, 3884564, and 4213169, Japanese Unexamined Patent Application Publication Nos. 2010-192719, 2009-076929, 2008-078414, 2007-059848, 2003-272860, and 2003-045676, and International Patent Publication WO2005/094130.

Now will be described individual layers forming the organic EL element of the present invention.

<<Luminous Layer>>

The luminous layer according to the present invention provides a site for recombination of electrons and holes injected from the electrodes or adjacent layers to emit light through generation of excitons. A luminous portion may be located within the luminous layer or at the interface between the luminous layer and the layer adjacent thereto. The luminous layer may have any configuration satisfying the requirements of the present invention.

The luminous layer may have any total thickness. The luminous layer has a total thickness of preferably 2 nm to 5 μm, more preferably 2 to 500 nm, still more preferably 5 to 200 nm, in view of the homogeneity of the layer, inhibition of application of unnecessarily high voltage upon light emission, and an improvement in stability of the color of emitted light against driving current.

The sublayers forming the luminous layer each have a thickness of preferably 2 nm to 1 μm, more preferably 2 to 200 nm, still more preferably 3 to 150 nm.

The luminous layer according to the present invention preferably contains the aforementioned luminous material as a luminous dopant (also referred to as “luminous compound,” “luminous dopant compound,” “dopant compound,” or “dopant”) and the aforementioned host compound (also referred to as “matrix material,” “luminous host compound,” or “host”).

(1) Luminous Dopant

The luminous dopant is preferably a fluorescent dopant (also referred to as “fluorescent compound” or “fluorescent dopant”) or a phosphorescent dopant (also referred as “phosphorescent compound” or “phosphorescent dopant”). In the present invention, at least one luminous layer preferably contains any of the aforementioned luminous materials.

The concentration of the luminous dopant in the luminous layer may be appropriately determined depending on the type of the dopant used and the requirements for the device. The luminous layer may contain the luminous dopant at a uniform concentration across the thickness, or may have any concentration profile of the luminous dopant.

In the present invention, two or more luminous dopants may be used in combination. In detail, dopants having different structures may be used in combination, or a fluorescent dopant may be used in combination with a phosphorescent dopant. Thus, the organic EL element can emit light of any color.

In the present invention, at least one luminous layer preferably contains the luminous compound according to the present invention or any known luminous compound and the compound according to the present invention serving as an assist dopant.

If the luminous layer contains the compound according to the present invention and the luminous compound but does not contain a host compound, the compound according to the present invention may be used as a host compound.

FIG. 1B schematically illustrates the case where the compound according to the present invention serves as an assist dopant, and FIG. 1C schematically illustrates the case where the compound serves as a host compound. Although FIGS. 1B and 1C illustrate the case where electric excitation generates triplet excitons in the compound according to the present invention, the excitons may be generated through energy transfer or electron transfer in the luminous layer or from the interface between the luminous layer and a layer adjacent thereto.

In use of the compound according to the present invention as an assist dopant, the energy levels S₁ and T₁ of the compound according to the present invention should preferably be lower than the energy levels S₁ and T₁ of the host compound and higher than the energy levels S₁ and T₁ of the luminous compound.

In use of the compound according to the present invention as a host, the energy levels S₁ and T₁ of the compound according to the present invention should preferably be higher than the energy levels S₁ and T₁ of the luminous compound.

The compound according to the present invention may be used for assisting the emission of light from a different fluorescent or luminescent compound. In such a case, the luminous layer preferably contains a host compound in an amount of 100% or more by weight relative to the compound according to the present invention, and a fluorescent or phosphorescent compound in an amount of 0.1 to 50% by weight relative to the compound according to the present invention.

The color of light emitted from the organic EL element or compound according to the present invention is determined by applying values obtained with a spectroradiometer CS-1000 (manufactured by Konica Minolta, Inc.) to the CIE chromaticity coordinate shown in FIG. 11.16 on page 108 of “Shinpen Shikisai Kagaku Handobukku (Handbook of Color Science)” (edited by the Color Science Association of Japan, published from University of Tokyo Press, 1985).

In the present invention, one or more luminous layers preferably contain a plurality of luminous dopants that emit light of different colors for emission of white light.

The luminous layers may contain any combination of luminous dopants that emit white light; for example, a combination of blue and orange light-emitting dopants, or a combination of blue, green, and red light-emitting dopants.

For emission of white light from the organic EL element of the present invention, the chromaticity in the CIE 1931 Color Specification System at 1,000 cd/m² preferably falls within a region of x=0.39±0.09 and y=0.38±0.08 during determination of front luminance (viewing angle: 2°) by the aforementioned process.

(1.1) Compound Serving as Luminous Dopant in the Present Invention

The compound serving as a luminous dopant in the present invention is preferably a compound that emits thermally activated delayed fluorescence.

The compound according to the present invention preferably has a structure including a conjugated plane having at least 18 π-electrons. The compound according to the present invention preferably has a condensed ring structure composed of two or more 5-membered rings.

The compound according to the present invention is suitable for use in a luminous composition.

The compound preferably has a structure represented by Formula (1). Examples of the luminous compound according to the present invention include fluorescent compounds, phosphorescent compounds, and delayed fluorescent compounds.

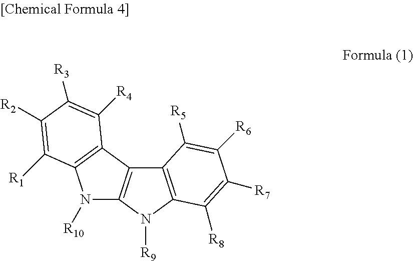

In Formula (1), R₁ to R₁₀, which may be identical to or different from one another, each represent a hydrogen atom, an alkyl group having 1 to 10 carbon atoms, an aryl or heteroaryl group having 6 to 30 carbon atoms; at least one of R₁ to R₁₀ represents an electron withdrawing aryl or heteroaryl group; and R₁ to R₁₀ may each have an substituent.

Examples of the substituent that may be possessed by R₁ to R₁₀ include alkyl groups (e.g., methyl, ethyl, propyl, isopropyl, tert-butyl, pentyl, hexyl, octyl, dodecyl, tridecyl, tetradecyl, and pentadecyl), cycloalkyl groups (e.g., cyclopentyl and cyclohexyl), alkenyl groups (e.g., vinyl and allyl), alkynyl groups (e.g., ethynyl and propargyl), aromatic hydrocarbon groups (also referred to as aromatic hydrocarbon ring groups, aromatic carbocyclic groups, or aryl groups, such as phenyl, p-chlorophenyl, mesityl, tolyl, xylyl, naphthyl, anthryl, azulenyl, acenaphthenyl, fluorenyl, phenanthryl, indenyl, pyrenyl, and biphenylyl), aromatic heterocyclic groups (e.g., pyridyl, pyrimidinyl, furyl, pyrrolyl, imidazolyl, benzimidazolyl, pyrazolyl, pyrazinyl, triazolyl (e.g., 1,2,4-triazol-1-yl or 1,2,3-triazol-1-yl), oxazolyl, benzoxazolyl, thiazolyl, isoxazolyl, isothiazolyl, furazanyl, thienyl, quinolyl, benzofuryl, dibenzofuryl, benzothienyl, dibenzothienyl, indolyl, carbazolyl, carbolinyl, diazacarbazolyl (i.e., a group prepared through replacement of one of the carbon atoms of the carboline ring of the carbolinyl group with a nitrogen atom), quinoxalinyl, pyridazinyl, triazinyl, quinazolinyl, and phthalazinyl), heterocyclic groups (e.g., pyrrolidyl, imidazolidinyl, morpholyl, and oxazolidyl), alkoxy groups (e.g., methoxy, ethoxy, propyloxy, pentyloxy, hexyloxy, octyloxy, and dodecyloxy), cycloalkoxy groups (e.g., cyclopentyloxy and cyclohexyloxy), aryloxy groups (e.g., phenoxy and naphthyloxy), alkylthio groups (e.g., methylthio, ethylthio, propylthio, pentylthio, hexylthio, octylthio, and dodecylthio), cycloalkylthio groups (e.g., cyclopentylthio and cyclohexylthio), arylthio groups (e.g., phenylthio and naphthylthio), alkoxycarbonyl groups (e.g., methyloxycarbonyl, ethyloxycarbonyl, butyloxycarbonyl, octyloxycarbonyl, and dodecyloxycarbonyl), aryloxycarbonyl groups (e.g., phenyloxycarbonyl and naphthyloxycarbonyl), sulfamoyl groups (e.g., aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, and 2-pyridylaminosulfonyl), acyl groups (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, and pyridylcarbonyl), acyloxy groups (e.g., acetyloxy, ethylcarbonyloxy, butylcarbonyloxy, octylcarbonyloxy, dodecylcarbonyloxy, and phenylcarbonyloxy), amido groups (e.g., methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, phenylcarbonylamino, and naphthylcarbonylamino), carbamoyl groups (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, and 2-pyridylaminocarbonyl), ureido groups (e.g., methylureido, ethylureido, pentylureido, cyclohexylureido, octylureido, dodecylureido, phenylureido, naphthylureido, and 2-pyridylaminoureido), sulfinyl groups (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, and 2-pyridylsulfinyl), alkylsulfonyl groups (e.g., methylsulfonyl, ethylsulfonyl, butylsulfonyl, cyclohexylsulfonyl, 2-ethylhexylsulfonyl, and dodecylsulfonyl), arylsulfonyl and heteroarylsulfonyl groups (e.g., phenylsulfonyl, naphthylsulfonyl, and 2-pyridylsulfonyl), amino groups (e.g., amino, ethylamino, dimethylamino, diphenylamino, butylamino, cyclopentylamino, 2-ethylhexylamino, dodecylamino, aniline, naphthylamino, and 2-pyridylamino), halogen atoms (e.g., fluorine, chlorine, and bromine), fluorohydrocarbon groups (e.g., fluoromethyl, trifluoromethyl, pentafluoroethyl, and pentafluorophenyl), cyano groups, nitro groups, hydroxy groups, mercapto groups, and silyl groups (e.g., trimethylsilyl, triisopropylsilyl, triphenylsilyl, and phenyldiethylsilyl), and a phosphono group. Preferred are alkyl groups, aromatic hydrocarbon groups, aromatic heterocyclic groups, alkoxy groups, amino groups, and cyano groups.

Other examples of preferred substituents include rings of indole, indazole, benzothiazole, benzoxazole, benzimidazole, quinolone, isoquinoline, quinazoline, quinoxaline, isoindole, naphthyridine, phthalazine, carbazole, carboline, diazacarbazole (i.e., a ring prepared through replacement of one of the carbon atoms of the carboline ring with a nitrogen atom), acridine, phenanthridine, phenanthroline, phenazine, azadibenzofuran, and azadibenzothiophene. Any of these substituents is also suitable as an electron withdrawing group.

Any of these substituents may further be substituted by the aforementioned substituent. These substituents may be bonded together to form a ring.

The compound according to the present invention preferably has a structure represented by Formula (2).

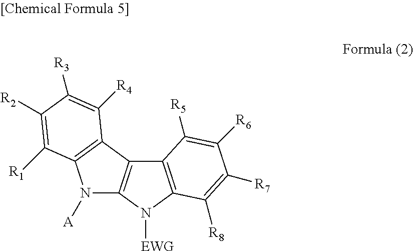

In Formula (2), R₁ to R₈, which may be identical to or different from one another, each represent a hydrogen atom, an alkyl group having 1 to 10 carbon atoms, or an aryl or heteroaryl group having 6 to 30 carbon atoms; A represents an alkyl group having 1 to 10 carbon atoms or an aryl or heteroaryl group having 6 to 30 carbon atoms, and A may be substituted by an alkyl group having 1 to 10 carbon atoms or an aryl or heteroaryl group having 6 to 12 carbon atoms, or may form a ring with any substituent; EWG represents an electron withdrawing aryl or heteroaryl group; and R₁ to R₈, A, and EWG may each have a substituent.

The substituent that may be possessed by R₁ to R₈, A, and EWG may be the same as the substituent that may be possessed by R₁ to R₁₀ in Formula (1).

The compound according to the present invention preferably has a structure represented by Formula (3).

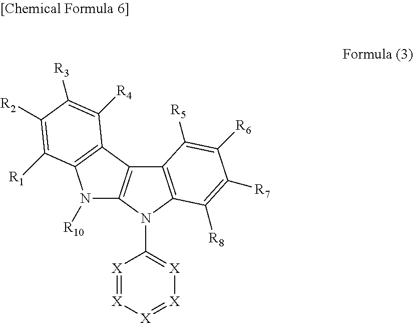

In Formula (3), R₁ to R₈, which may be identical to or different from one another, each represent a hydrogen atom, an alkyl group having 1 to 10 carbon atoms, or an aryl or heteroaryl group having 6 to 30 carbon atoms; A represents an alkyl group having 1 to 10 carbon atoms or an aryl or heteroaryl group having 6 to 30 carbon atoms, and A may be substituted by an alkyl group having 1 to 10 carbon atoms or an aryl or heteroaryl group having 6 to 12 carbon atoms, or may form a ring with any substituent; X represents a carbon or nitrogen atom and may be substituted by an alkyl group having 1 to 10 carbon atoms or an aryl or heteroaryl group having 6 to 50 carbon atoms; the atoms represented by X may be identical to or different from one another; and R₁ to R₈, A, and X may each have a substituent.

The substituent that may be possessed by R₁ to R₈, A, and X may be the same as the substituent that may be possessed by R₁ to R₁₀ in Formula (1).

Examples of preferred compounds used in the present invention include, but are not limited to, the compounds described below. In each of the following compounds, the HOMO has an energy level of −5.2 eV or more, the LUMO has an energy level of −1.2 eV or less, and the sum of ΔE_{H} and ΔE_{L} is 2.0 eV or more. In exemplary compound D32, the HOMO has an energy level of −5.0 eV, the LUMO has an energy level of −2.0 eV, and the sum of ΔE_{H} and ΔE_{L} is 3.3 eV (ΔE_{H}=1.8 eV and ΔE_{L}=1.5 eV).

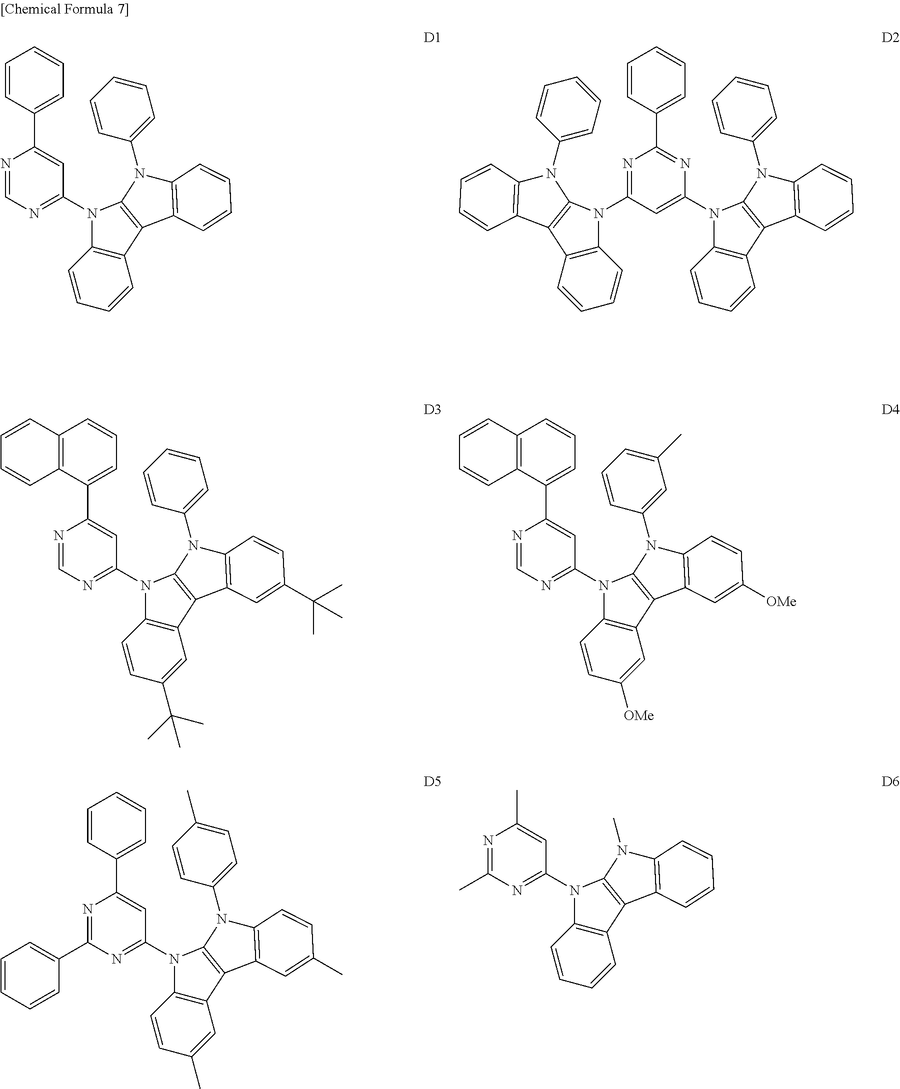

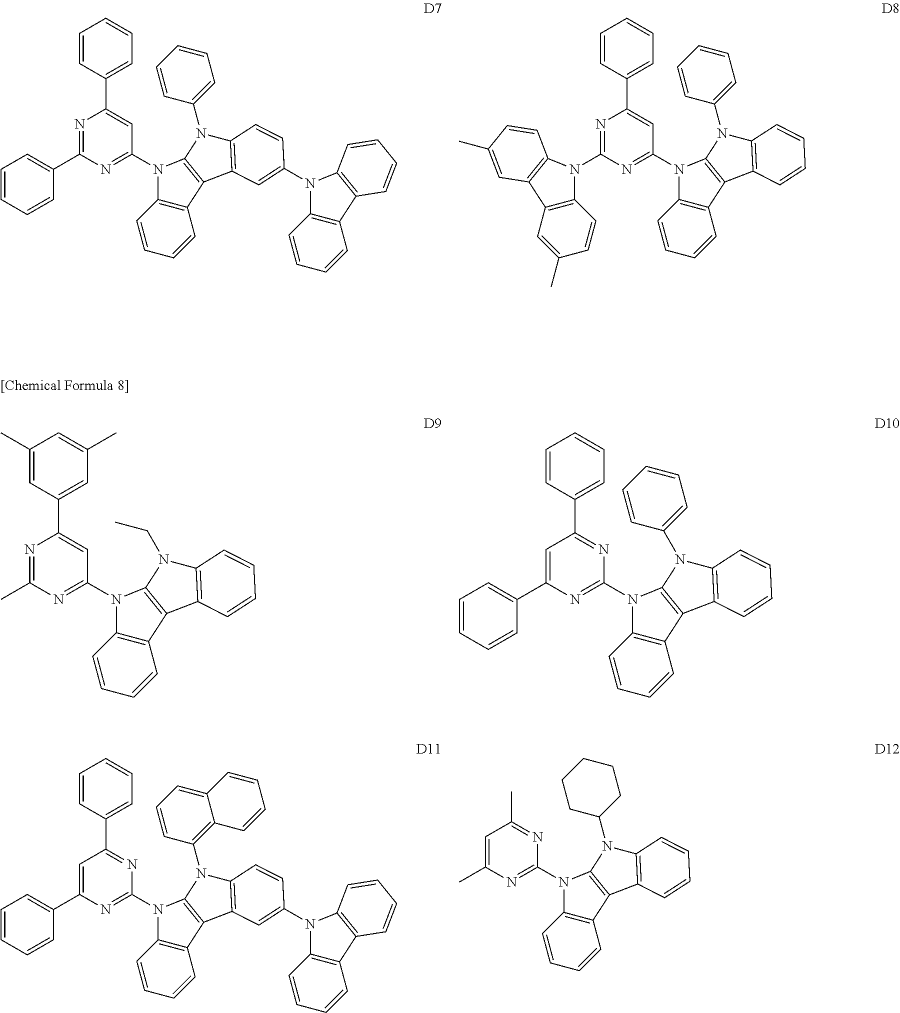 [SMILES: c1ccc(-c2cc(-n3c4ccccc4c4c5cc(-n6c7ccccc7c7ccccc76)ccc5n(-c5ccccc5)c43)nc(-c3ccccc3)n2)cc1 ; Cc1ccc2c(c1)c1cc(C)ccc1n2-c1nc(-c2ccccc2)cc(-n2c3ccccc3c3c4ccccc4n(-c4ccccc4)c32)n1 ; CCn1c2ccccc2c2c3ccccc3n(-c3cc(-c4cc(C)cc(C)c4)nc(C)n3)c21 ; c1ccc(-c2cc(-c3ccccc3)nc(-n3c4ccccc4c4c5ccccc5n(-c5ccccc5)c43)n2)cc1 ; c1ccc(-c2cc(-c3ccccc3)nc(-n3c4ccccc4c4c5cc(-n6c7ccccc7c7ccccc76)ccc5n(-c5cccc6ccccc56)c43)n2)cc1 ; Cc1cc(C)nc(-n2c3ccccc3c3c4ccccc4n(C4CCCCC4)c32)n1]

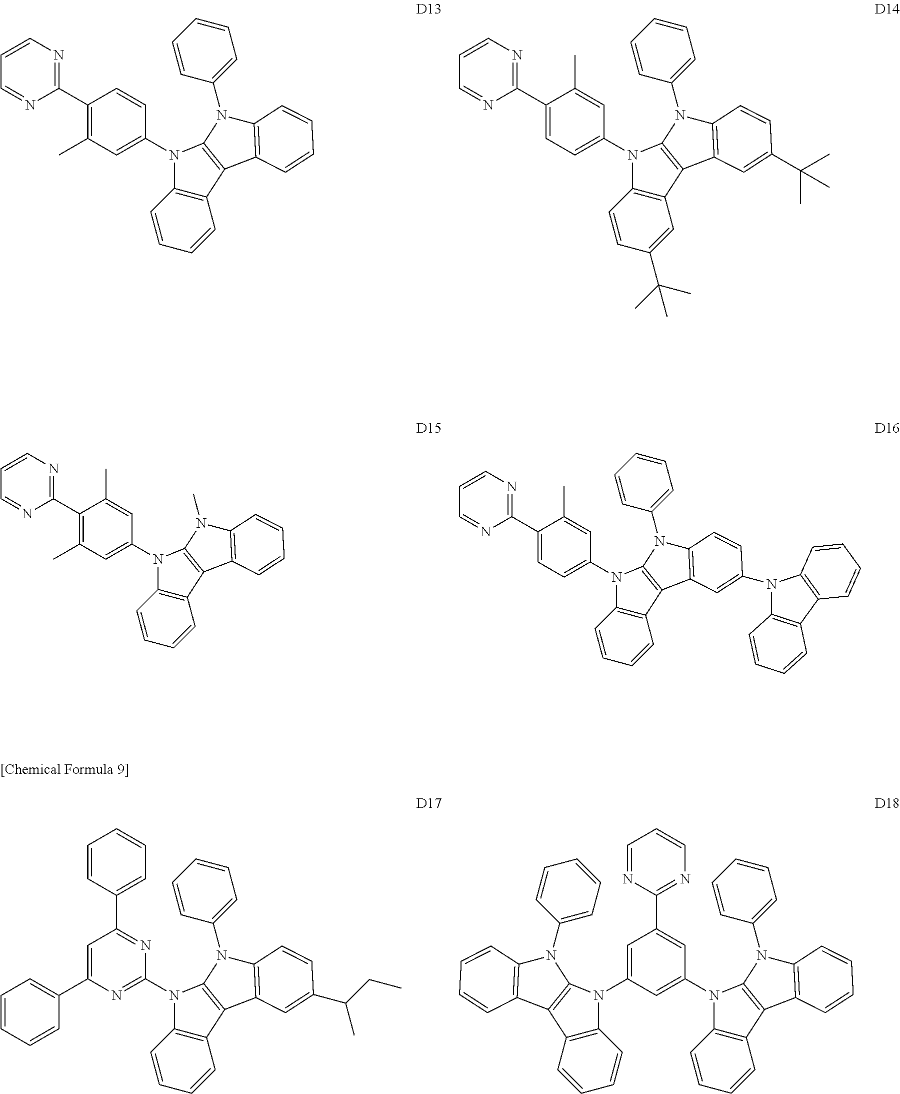 [SMILES: Cc1cc(-n2c3ccccc3c3c4ccccc4n(-c4ccccc4)c32)ccc1-c1ncccn1 ; Cc1cc(-n2c3ccc(C(C)(C)C)cc3c3c4cc(C(C)(C)C)ccc4n(-c4ccccc4)c32)ccc1-c1ncccn1 ; Cc1cc(-n2c3ccccc3c3c4ccccc4n(C)c32)cc(C)c1-c1ncccn1 ; Cc1cc(-n2c3ccccc3c3c4cc(-n5c6ccccc6c6ccccc65)ccc4n(-c4ccccc4)c32)ccc1-c1ncccn1 ; CCC(C)c1ccc2c(c1)c1c3ccccc3n(-c3nc(-c4ccccc4)cc(-c4ccccc4)n3)c1n2-c1ccccc1 ; c1ccc(-n2c3ccccc3c3c4ccccc4n(-c4cc(-c5ncccn5)cc(-n5c6ccccc6c6c7ccccc7n(-c7ccccc7)c65)c4)c32)cc1]

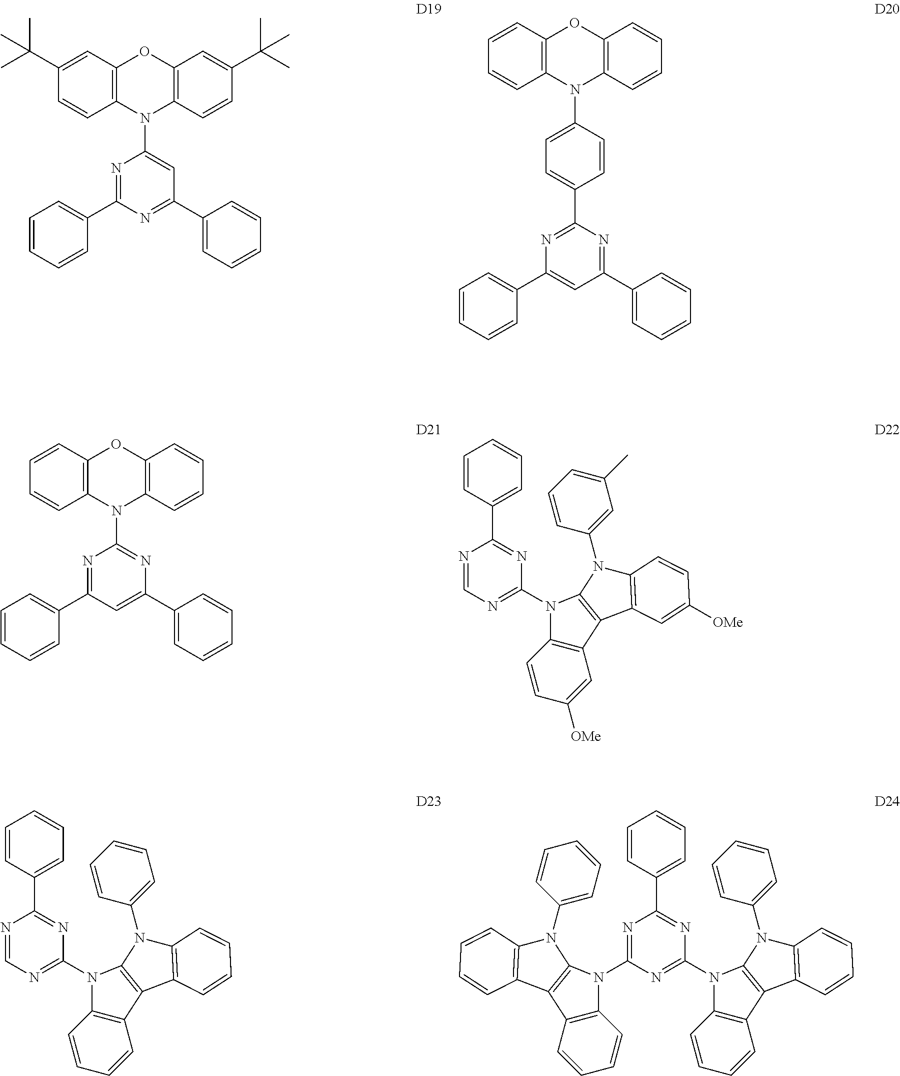 [SMILES: CC(C)(C)c1ccc2c(c1)Oc1cc(C(C)(C)C)ccc1N2c1cc(-c2ccccc2)nc(-c2ccccc2)n1 ; c1ccc(-c2cc(-c3ccccc3)nc(-c3ccc(N4c5ccccc5Oc5ccccc54)cc3)n2)cc1 ; c1ccc(-c2cc(-c3ccccc3)nc(N3c4ccccc4Oc4ccccc43)n2)cc1 ; COc1ccc2c(c1)c1c3cc(OC)ccc3n(-c3ncnc(-c4ccccc4)n3)c1n2-c1cccc(C)c1 ; c1ccc(-c2ncnc(-n3c4ccccc4c4c5ccccc5n(-c5ccccc5)c43)n2)cc1 ; c1ccc(-c2nc(-n3c4ccccc4c4c5ccccc5n(-c5ccccc5)c43)nc(-n3c4ccccc4c4c5ccccc5n(-c5ccccc5)c43)n2)cc1]

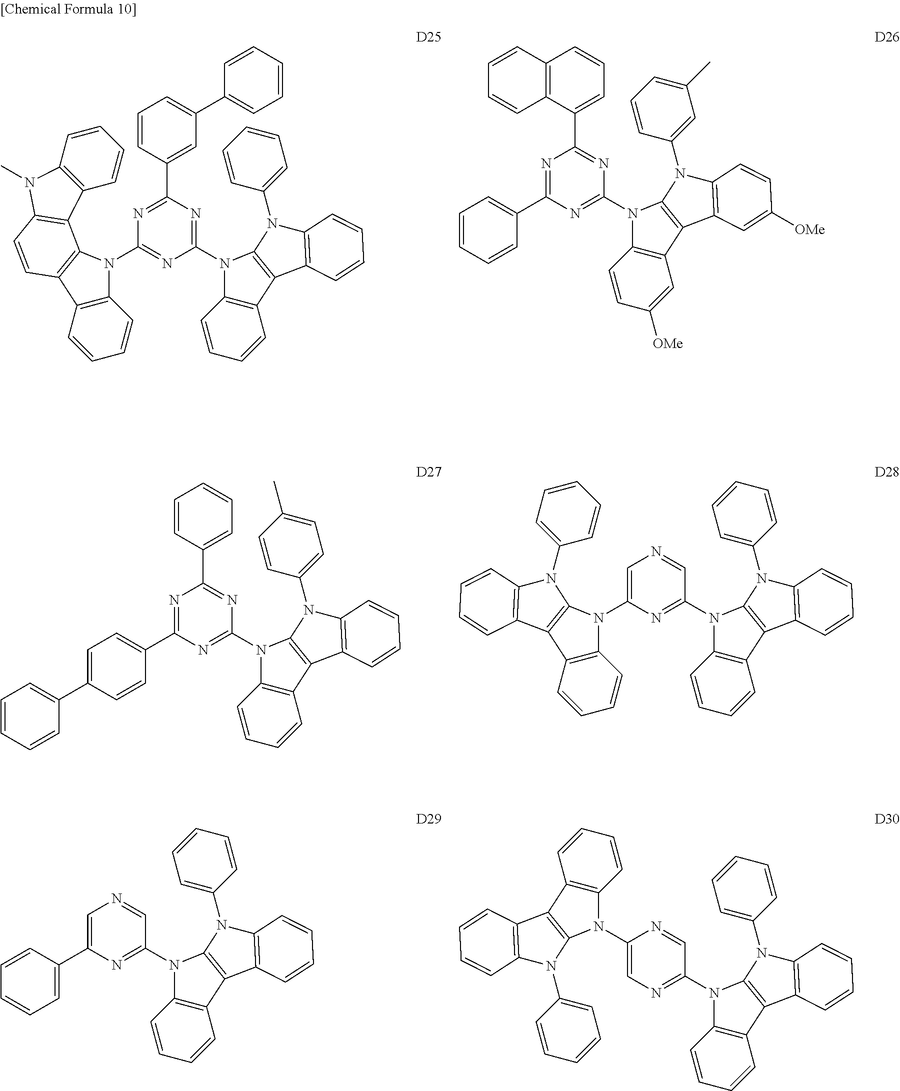

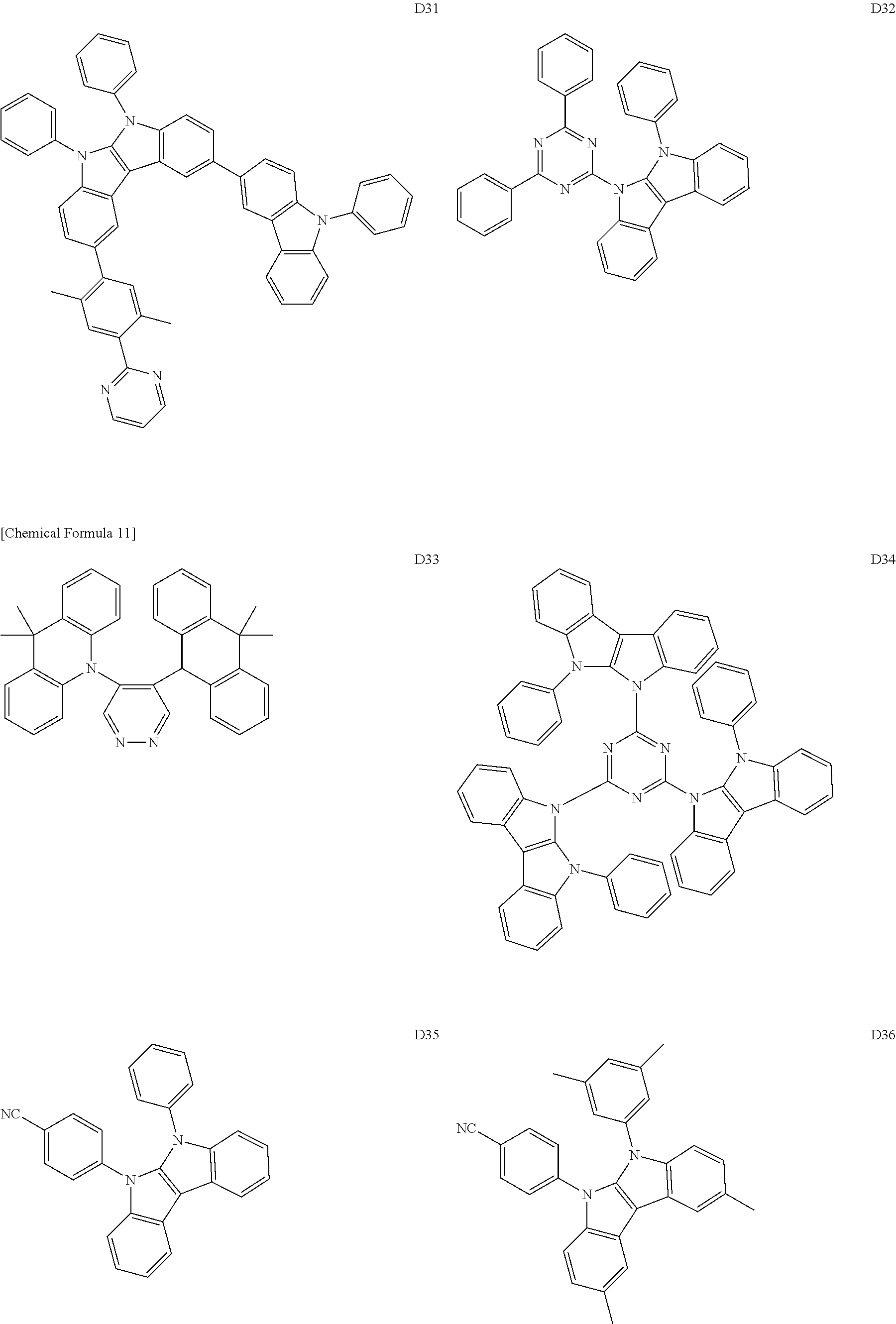

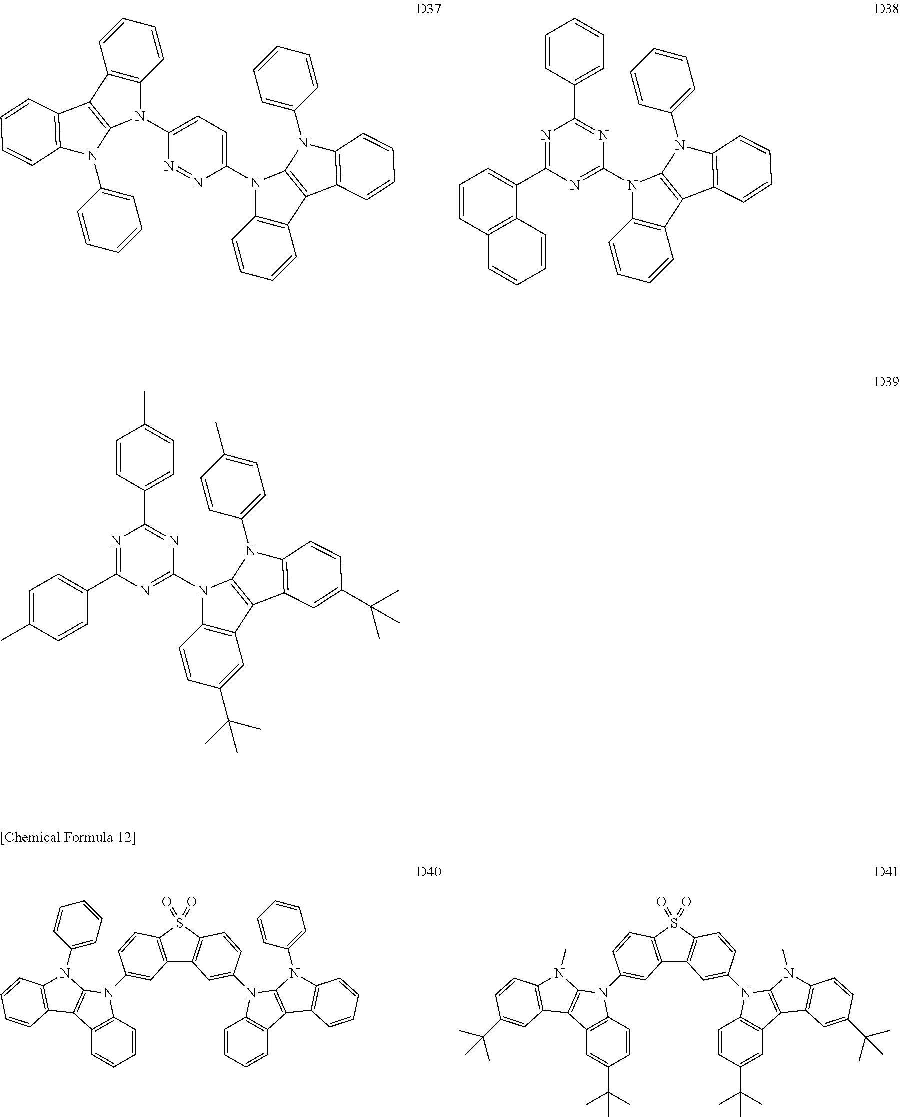 [SMILES: c1ccc(-n2c3ccccc3c3c4ccccc4n(-c4ccc(-n5c6ccccc6c6c7ccccc7n(-c7ccccc7)c65)nn4)c32)cc1 ; c1ccc(-c2nc(-c3cccc4ccccc34)nc(-n3c4ccccc4c4c5ccccc5n(-c5ccccc5)c43)n2)cc1 ; Cc1ccc(-c2nc(-c3ccc(C)cc3)nc(-n3c4ccc(C(C)(C)C)cc4c4c5cc(C(C)(C)C)ccc5n(-c5ccc(C)cc5)c43)n2)cc1 ; O=S1(=O)c2ccc(-n3c4ccccc4c4c5ccccc5n(-c5ccccc5)c43)cc2-c2cc(-n3c4ccccc4c4c5ccccc5n(-c5ccccc5)c43)ccc21 ; Cn1c2ccc(C(C)(C)C)cc2c2c3cc(C(C)(C)C)ccc3n(-c3ccc4c(c3)-c3cc(-n5c6ccc(C(C)(C)C)cc6c6c7cc(C(C)(C)C)ccc7n(C)c65)ccc3S4(=O)=O)c21]

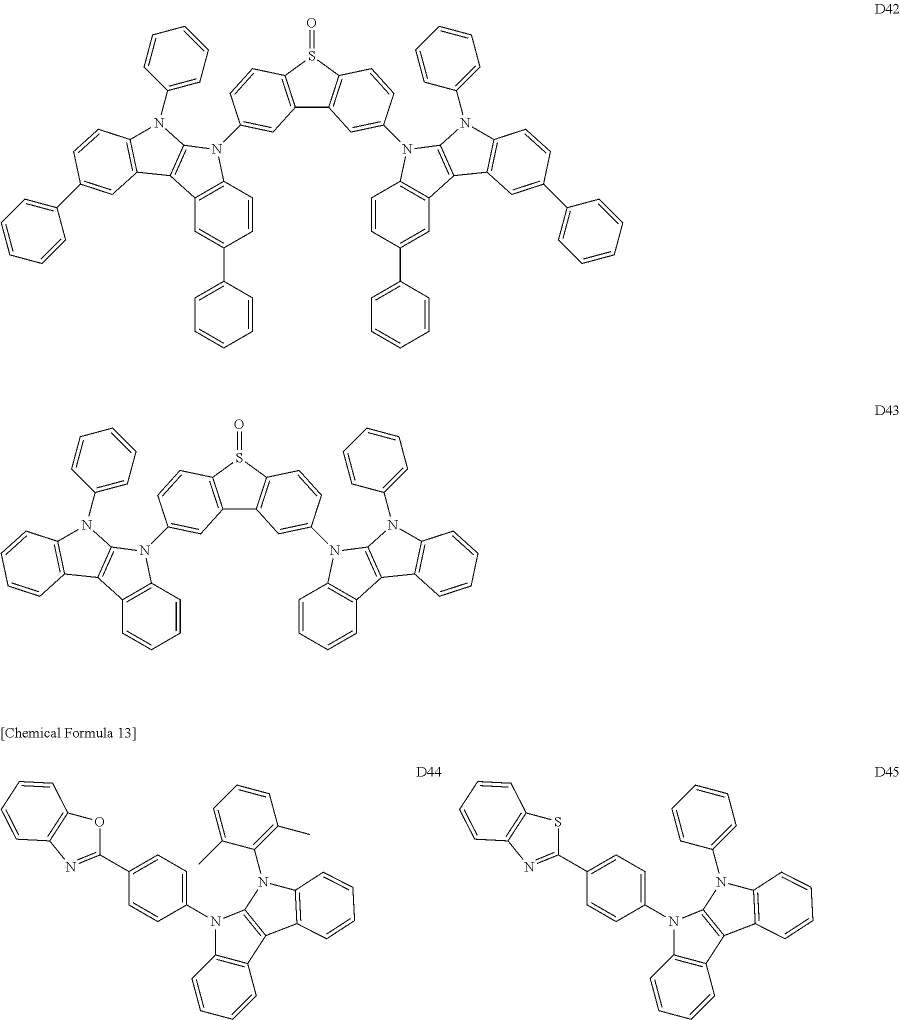 [SMILES: O=S1c2ccc(-n3c4ccc(-c5ccccc5)cc4c4c5cc(-c6ccccc6)ccc5n(-c5ccccc5)c43)cc2-c2cc(-n3c4ccc(-c5ccccc5)cc4c4c5cc(-c6ccccc6)ccc5n(-c5ccccc5)c43)ccc21 ; O=S1c2ccc(-n3c4ccccc4c4c5ccccc5n(-c5ccccc5)c43)cc2-c2cc(-n3c4ccccc4c4c5ccccc5n(-c5ccccc5)c43)ccc21 ; Cc1cccc(C)c1-n1c2ccccc2c2c3ccccc3n(-c3ccc(-c4nc5ccccc5o4)cc3)c21 ; c1ccc(-n2c3ccccc3c3c4ccccc4n(-c4ccc(-c5nc6ccccc6s5)cc4)c32)cc1]

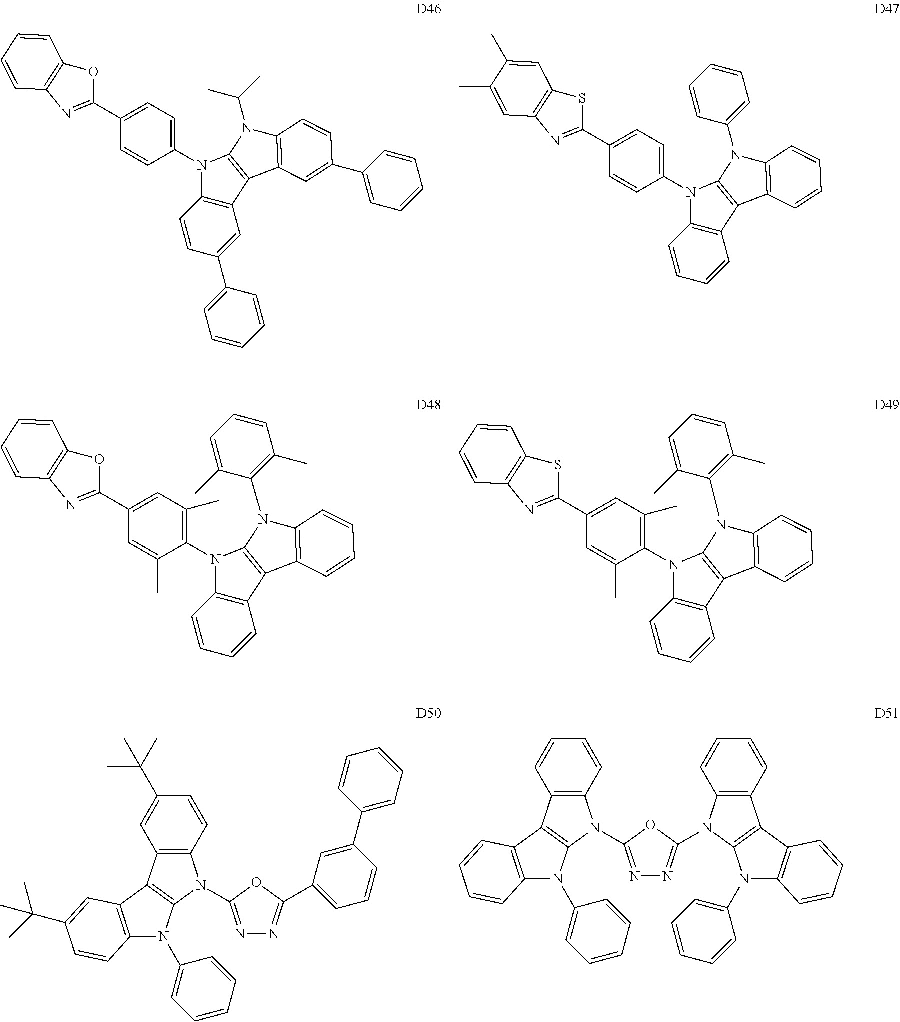 [SMILES: CC(C)n1c2ccc(-c3ccccc3)cc2c2c3cc(-c4ccccc4)ccc3n(-c3ccc(-c4nc5ccccc5o4)cc3)c21 ; Cc1cc2nc(-c3ccc(-n4c5ccccc5c5c6ccccc6n(-c6ccccc6)c54)cc3)sc2cc1C ; Cc1cccc(C)c1-n1c2ccccc2c2c3ccccc3n(-c3c(C)cc(-c4nc5ccccc5o4)cc3C)c21 ; Cc1cccc(C)c1-n1c2ccccc2c2c3ccccc3n(-c3c(C)cc(-c4nc5ccccc5s4)cc3C)c21 ; CC(C)(C)c1ccc2c(c1)c1c3cc(C(C)(C)C)ccc3n(-c3nnc(-c4cccc(-c5ccccc5)c4)o3)c1n2-c1ccccc1 ; c1ccc(-n2c3ccccc3c3c4ccccc4n(-c4nnc(-n5c6ccccc6c6c7ccccc7n(-c7ccccc7)c65)o4)c32)cc1]

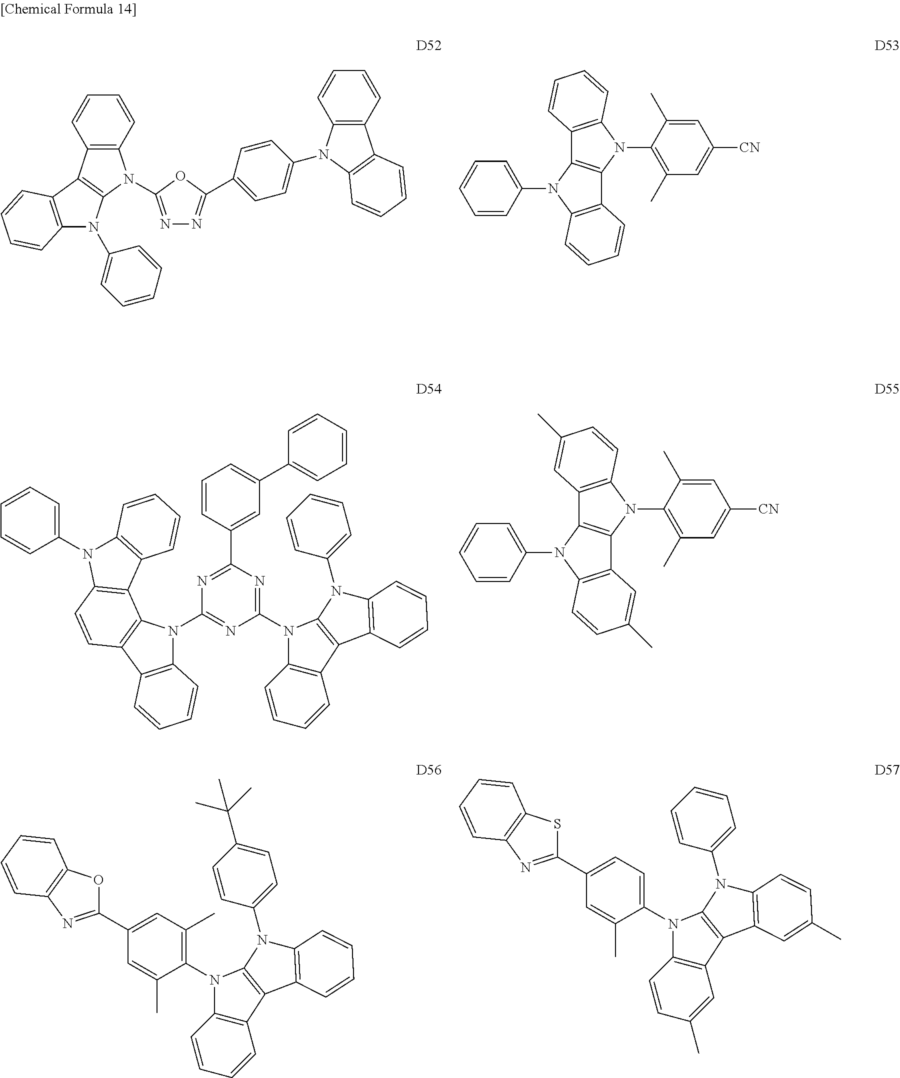 [SMILES: c1ccc(-n2c3ccccc3c3c4ccccc4n(-c4nnc(-c5ccc(-n6c7ccccc7c7ccccc76)cc5)o4)c32)cc1 ; Cc1cc(C#N)cc(C)c1-n1c2ccccc2c2c1c1ccccc1n2-c1ccccc1 ; c1ccc(-c2cccc(-c3nc(-n4c5ccccc5c5ccc6c(c7ccccc7n6-c6ccccc6)c54)nc(-n4c5ccccc5c5c6ccccc6n(-c6ccccc6)c54)n3)c2)cc1 ; Cc1ccc2c(c1)c1c(c3cc(C)ccc3n1-c1ccccc1)n2-c1c(C)cc(C#N)cc1C ; Cc1cc(-c2nc3ccccc3o2)cc(C)c1-n1c2ccccc2c2c3ccccc3n(-c3ccc(C(C)(C)C)cc3)c21 ; Cc1ccc2c(c1)c1c3cc(C)ccc3n(-c3ccc(-c4nc5ccccc5s4)cc3C)c1n2-c1ccccc1]

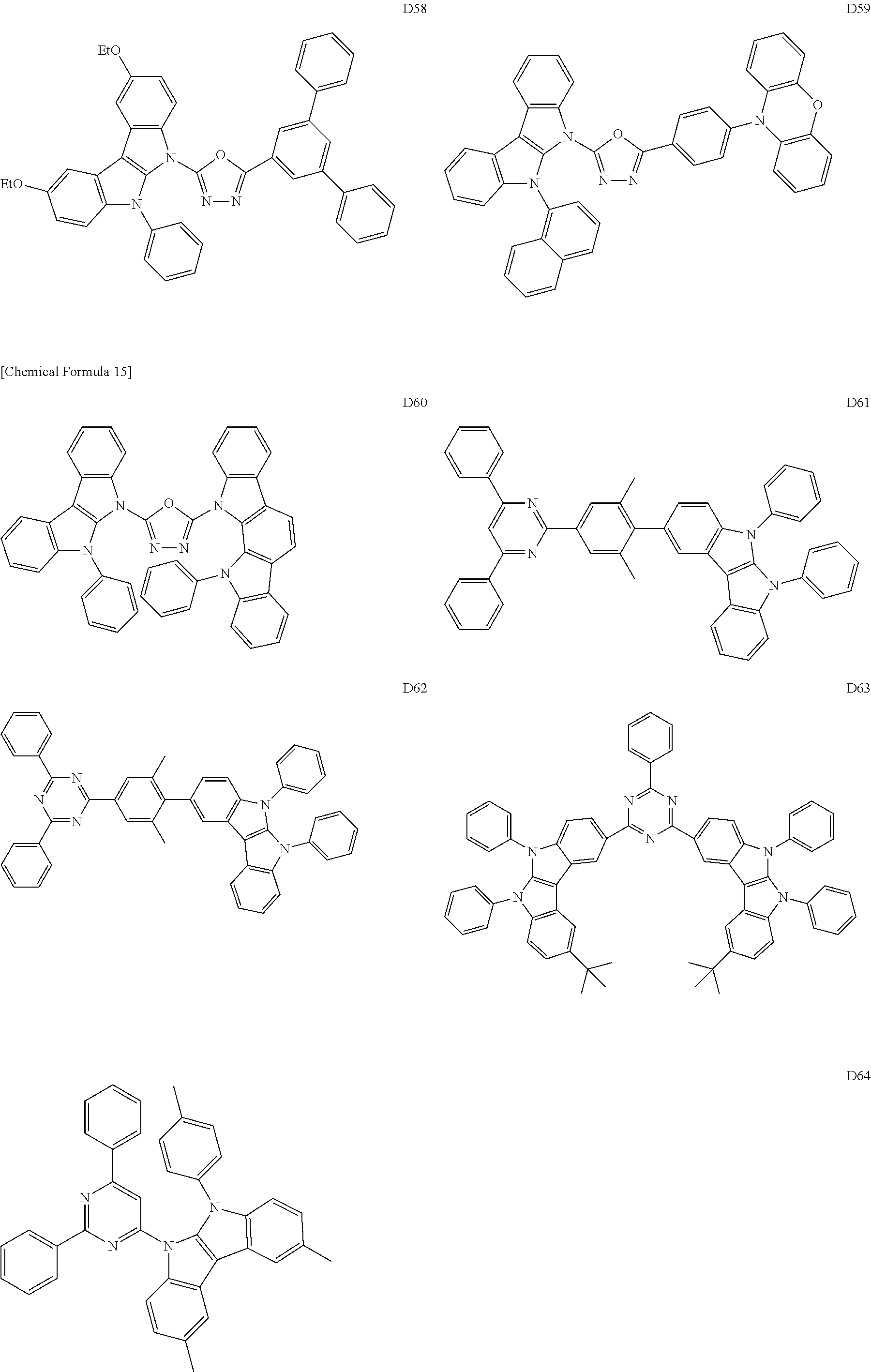

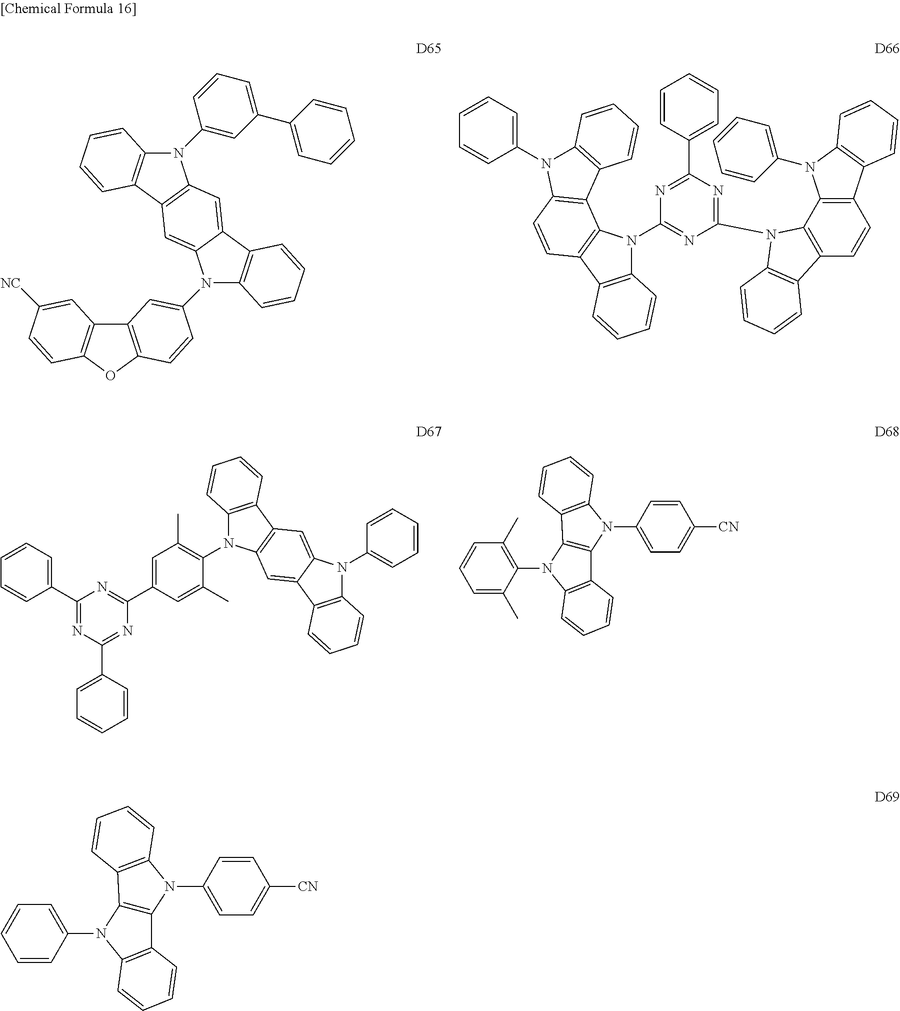

(1.2) Phosphorescent Dopant

The phosphorescent dopant used in the present invention will now be described.

The phosphorescent dopant used in the present invention emits light from the excited triplet state. In detail, the phosphorescent dopant is defined as a compound that emits phosphorescent light at room temperature (25° C.) and has a phosphorescent quantum yield of 0.01 or more at 25° C. The preferred phosphorescent quantum yield is 0.1 or more.

The phosphorescent quantum yield is determined by the method described in page 398 of Bunko II of Jikken Kagaku Koza 7 (Spectroscopy II, Experimental Chemistry 7) (4th Edition, 1992, published by Maruzen Company, Limited). The phosphorescent quantum yield in a solution can be determined with any appropriate solvent. The phosphorescent dopant used in the present invention has a phosphorescent quantum yield of 0.01 or more determined with any appropriate solvent.

The phosphorescent dopant may be appropriately selected from known ones used for the luminous layer of a common organic EL element. Examples of known phosphorescent dopants usable in the present invention include those described in the following publications.

Nature, 395, 151 (1998), Appl. Phys. Lett., 78, 1622 (2001), Adv. Mater. 19, 739 (2007), Chem. Mater., 17, 3532 (2005), Adv. Mater., 17, 1059 (2005), International Patent Publication WO2009/100991, WO2008/101842, and WO2003/040257, U.S. Patent Application Publication Nos. 2006/835469, 2006/0202194, 2007/0087321, and 2005/0244673, Inorg. Chem., 40, 1704 (2001), Chem. Mater., 16, 2480 (2004), Adv. Mater., 16, 2003 (2004), Angew. Chem. lnt. Ed., 2006, 45, 7800, Appl. Phys. Lett., 86, 153505 (2005), Chem. Lett., 34, 592 (2005), Chem. Commun., 2906 (2005), Inorg. Chem., 42, 1248 (2003), International Patent Publication WO2009/050290, WO2002/015645, and WO2009/000673, U.S. Patent Application Publication No. 2002/0034656, U.S. Pat. No. 7,332,232, U.S. Patent Application Publication Nos. 2009/0108737 and 2009/0039776, U.S. Pat. Nos. 6,921,915 and 6,687,266, U.S. Patent Application Publication Nos. 2007/0190359, 2006/0008670, 2009/0165846, and 2008/0015355, U.S. Pat. Nos. 7,250,226 and 7,396,598, U.S. Patent Application Publication Nos. 2006/0263635, 2003/0138657, and 2003/0152802, U.S. Pat. No. 7,090,928, Angew. Chem. Int. Ed., 47, 1 (2008), Chem. Mater., 18, 5119 (2006), Inorg. Chem., 46, 4308 (2007), Organometallics, 23, 3745 (2004), Appl. Phys. Lett., 74, 1361 (1999), International Patent Publication WO2002/002714, WO2006/009024, WO2006/056418, WO2005/019373, WO2005/123873, WO2005/123873, WO2007/004380, and WO2006/082742, U.S. Patent Application Publication Nos. 2006/0251923 and 2005/0260441, U.S. Pat. Nos. 7,393,599, 7,534,505, and 7,445,855, U.S. Patent Application Publication Nos. 2007/0190359 and 2008/0297033, U.S. Pat. No. 7,338,722, U.S. Patent Application Publication No. 2002/0134984, U.S. Pat. No. 7,279,704, U.S. Patent Application Publication Nos. 2006/098120 and 2006/103874, International Patent Publication WO2005/076380, WO2010/032663, WO2008/140115, WO2007/052431, WO2011/134013, WO2011/157339, WO2010/086089, WO2009/113646, WO2012/020327, WO2011/051404, WO2011/004639, and WO2011/073149, U.S. Patent Application Publication Nos. 2012/228583 and 2012/212126, Japanese Unexamined Patent Application Publication No. 2012-069737, Japanese Patent Application No. 2011-181303, and Japanese Unexamined Patent Application Publication Nos. 2009-114086, 2003-81988, 2002-302671, and 2002-363552.

The phosphorescent dopant is preferably an organometallic complex containing Ir as a central metal, more preferably a complex containing at least one coordination mode of metal-carbon bond, metal-nitrogen bond, metal-oxygen bond, and metal-sulfur bond.

(2) Host Compound

In the present invention, the host compound is used for injection and transportation of carriers in the luminous layer. The host compound emits substantially no light in the organic EL element.

The host compound is preferably contained in the luminous layer in an amount of 20 mass % or more.

Host compounds may be used alone or in combination. The combined use of host compounds leads to control of electric charge transfer, resulting in high emission efficiency of the organic EL element.

Now will be described host compounds preferably used in the present invention.

In the present invention, any host compound may be used in combination with the luminous compound. In view of reverse energy transfer, the host compound preferably has an excited singlet energy level higher than that of the luminous compound according to the present invention, and more preferably, the host compound has an excited triplet energy level higher than that of the luminous compound.

In the luminous layer, the host compound transports carriers and generates excitons. Preferably, the host compound is stable in the state of active chemical species (i.e., cationic radical state, anionic radical state, and excited state) and does not undergo any chemical change (e.g., decomposition or addition reaction). More preferably, molecules of the host compound do not migrate in the luminous layer on the order of angstrom during energization.

If the luminous dopant used in combination with the host compound exhibits TADF emission, the TADF material is present in the triplet excited state for a long period of time, and thus appropriate molecular design is required for the host compound for preventing a reduction in T₁. Requirements for the molecular design include an increase in energy level T₁ of the host compound, an increase in energy level T₁ of associated molecules of the host compound, no exciplex formation between the TADF material and the host compound, and no electromer formation from the host compound by electric excitation.

In order to satisfy such requirements, the host compound needs to exhibit high electron hopping mobility and high hole hopping mobility, and to undergo a small change in structure in the triplet excited state. Preferred examples of the host compound satisfying such requirements include, but are not limited to, compounds exhibiting high energy level T₁, such as compounds having structures of carbazole, azacarbazole, dibenzofuran, dibenzothiophene, and azadibenzofuran.

Typical examples of the host compound include compounds having a biaryl and/or a multi-aryl ring structure. As used herein, the term “aryl” refers to both an aromatic hydrocarbon ring and an aromatic heterocyclic ring.

The host compound is more preferably a compound prepared by direct bonding between a carbazole structure and an aromatic heterocyclic compound having a 14-π-electron system and a molecular structure different from the carbazole structure, still more preferably a carbazole derivative having, in the molecule, two or more aromatic heterocyclic rings having a 14-π-electron system. In particular, the carbazole derivative is preferably a compound having two or more conjugated structures each having 14 or more π-electrons for further enhancing the advantageous effects of the present invention.

The host compound used in the present invention is also preferably a compound represented by Formula (I) because the compound represented by Formula (I) has a condensed ring structure (i.e., extending π-electron clouds), high carrier transportability, and high glass transition temperature (Tg). Although a condensed aromatic ring generally has a low excited triplet energy level (T₁), a compound represented by Formula (I) has a high T₁ and is suitable for use in the luminous material having a short emission wavelength (i.e., high T₁ and S₁).

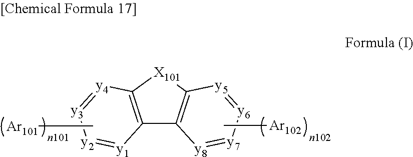

In Formula (I), X₁₀₁ represents NR₁₀₁, an oxygen atom, a sulfur atom, CR₁₀₂R₁₀₃, or SiR₁₀₂R₁₀₃, and y₁ to y₈ each represent CR₁₀₄ or a nitrogen atom.

R₁₀₁ to R₁₀₄ each represent a hydrogen atom or a substituent and may be bonded together to form a ring.

Ar₁₀₁ and Ar₁₀₂ each represent an aromatic ring and may be identical to or different from each other.

In Formula (I), n101 and n102 each represent an integer of 0 to 4. If R₁₀₁ is a hydrogen atom, n101 is 1 to 4.

In Formula (I), R₁₀₁ to R₁₀₄ each represent a hydrogen atom or a substituent. The host compound used in the present invention may have any substituent that does not impede the function of the host compound. For example, the present invention encompasses a compound into which such a substituent is introduced through a synthetic scheme and which exhibits the advantageous effects of the present invention.

Examples of the substituent represented by R₁₀₁ to R₁₀₄ include linear or branched alkyl groups (e.g., methyl, ethyl, propyl, isopropyl, t-butyl, pentyl, hexyl, octyl, dodecyl, tridecyl, tetradecyl, and pentadecyl); alkenyl groups (e.g., vinyl and allyl); alkynyl groups (e.g., ethynyl and propargyl); aromatic hydrocarbon groups (also referred to as aromatic carbocyclic groups or aryl groups, such as groups derived from rings of benzene, biphenyl, naphthalene, azulene, anthracene, phenanthrene, pyrene, chrysene, naphthacene, triphenylene, o-terphenyl, m-terphenyl, p-terphenyl, acenaphthene, coronene, indene, fluorene, fluoranthrene, naphthacene, pentacene, perylene, pentaphene, picene, pyrene, pyranthrene, anthranthrene, and tetralin); aromatic heterocyclic groups (e.g., groups derived from rings of furan, dibenzofuran, thiophene, dibenzothiophene, oxazole, pyrrole, pyridine, pyridazine, pyrimidine, pyrazine, triazine, benzimidazole, oxadiazole, triazole, imidazole, pyrazole, thiazole, indole, indazole, benzimidazole, benzothiazole, benzoxazole, quinoxaline, quinazoline, cinnoline, quinoline, isoquinoline, phthalazine, naphthyridine, carbazole, carboline, and diazacarbazole (one of the carbon atoms forming the carboline ring is replaced with a nitrogen atom in the ring; a carboline ring and a diazacarbazole ring may be collectively referred to as “azacarbazole ring”); non-aromatic hydrocarbon ring groups (e.g., cyclopentyl and cyclohexyl); non-aromatic heterocyclic groups (e.g., pyrrolidyl, imidazolidyl, morpholyl, and oxazolidyl); alkoxy groups (e.g., methoxy, ethoxy, propyloxy, pentyloxy, hexyloxy, octyloxy, and dodecyloxy); cycloalkoxy groups (e.g., cyclopentyloxy and cyclohexyloxy); aryloxy groups (e.g., phenoxy and naphthyloxy); alkylthio groups (e.g., methylthio, ethylthio, propylthio, pentylthio, hexylthio, octylthio, and dodecylthio); cycloalkylthio groups (e.g., cyclopentylthio and cyclohexylthio); arylthio groups (e.g., phenylthio and naphthylthio); alkoxycarbonyl groups (e.g., methyloxycarbonyl, ethyloxycarbonyl, butyloxycarbonyl, octyloxycarbonyl, and dodecyloxycarbonyl); aryloxycarbonyl groups (e.g., phenyloxycarbonyl and naphthyloxycarbonyl); sulfamoyl groups (e.g., aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, and 2-pyridylaminosulfonyl); acyl groups (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, and pyridylcarbonyl); acyloxy groups (e.g., acetyloxy, ethylcarbonyloxy, butylcarbonyloxy, octylcarbonyloxy, dodecylcarbonyloxy, and phenylcarbonyloxy); amido groups (e.g., methylcarbonylamino, ethylcarbonylamino, dimethylcarbonylamino, propylcarbonylamino, pentylcarbonylamino, cyclohexylcarbonylamino, 2-ethyhexylcarbonylamino, octylcarbonylamino, dodecylcarbonylamino, phenylcarbonylamino, and naphthylcarbonylamino); carbamoyl groups (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, and 2-pyridylaminocarbonyl); ureido groups (e.g., methylureido, ethylureido, pentylureido, cyclohexylureido, octylureido, dodecylureido, phenylureido, naphthylureido, and 2-pyridylaminoureido); sulfinyl groups (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, and 2-pyridylsulfinyl); alkylsulfonyl groups (e.g., methylsulfonyl, ethylsulfonyl, butylsulfonyl, cyclohexylsulfonyl, 2-ethylhexylsulfonyl, and dodecylsulfonyl); arylsulfonyl and heteroarylsulfonyl groups (e.g., phenylsulfonyl, naphthylsulfonyl, and 2-pyridylsulfonyl); amino groups (e.g., amino, ethylamino, dimethylamino, butylamino, cyclopentylamino, 2-ethylhexylamino, dodecylamino, anilino, naphthylamino, and 2-pyridylamino); halogen atoms (e.g., fluorine, chlorine, and bromine); fluorohydrocarbon groups (e.g., fluoromethyl, trifluoromethyl, pentafluoromethyl, and pentafluorophenyl); cyano groups; nitro groups; hydroxy groups; thiol groups; silyl groups (e.g., trimethylsilyl, triisopropylsilyl, triphenylsilyl, and phenyldiethylsilyl); and atomic deuterium.

These substituents may further have any of the aforementioned substituents. These substituents may be bonded together to form a ring.

In Formula (I), preferably, at least three of y₁ to y₄ or at least three of y₅ to y₈ are CR₁₀₂, and more preferably, all of y₁ to y₈ are CR₁₀₂. Such a structure exhibits high hole transportability or high electron transportability. Thus, holes and electrons injected from the anode and the cathode are efficiently recombined in the luminous layer, to emit light.

Particularly preferred is a compound represented by Formula (I) wherein X₁₀₁ is NR′, an oxygen atom, or a sulfur atom, the compound having a low energy level of LUMO and exhibiting high electron transportability. The condensed ring formed by X₁₀₁ and y₁ to y₈ is more preferably a carbazole, azacarbazole, dibenzofuran, or azadibenzofuran ring.

The host compound preferably has rigidity. Thus, if X₁₀₁ is NR₁₀₁, R₁₀₁ is preferably an aromatic hydrocarbon group or an aromatic heterocyclic group, which has a π-conjugated structure. R₁₀₁ may further have a substituent represented by R₁₀₁ to R₁₀₃.

In Formula (I), the aromatic ring represented by Ar₁₀₁ or Ar₁₀₂ is an aromatic hydrocarbon or heterocyclic ring. The aromatic ring may be a single ring or a condensed ring. The aromatic ring may be unsubstituted or may have a substituent similar to that represented by R₁₀₁ to R₁₀₄.

In Formula (I), the aromatic hydrocarbon ring represented by Ar₁₀₁ or Ar₁₀₂ may be similar to that exemplified above as a substituent represented by R₁₀₁ to R₁₀₄.

In the partial structure represented by Formula (I), the aromatic heterocyclic ring represented by Ar₁₀₁ or Ar₁₀₂ may be similar to that exemplified above as a substituent represented by R₁₀₁ to R₁₀₄.

In view of the fact that the host compound represented by Formula (I) should have a high T₁, the aromatic ring represented by Ar₁₀₁ or Ar₁₀₂ preferably has a high T₁. Examples of preferred aromatic rings include rings of benzene (including polyphenylene structures composed of a plurality of linked benzene rings (e.g., biphenyl, terphenyl, and quarterphenyl)), fluorene, triphenylene, carbazole, azacarbazole, dibenzofuran, azadibenzofuran, dibenzothiophene, dibenzothiophene, pyridine, pyrazine, indoloindole, indole, benzofuran, benzothiophene, benzimidazole, and triazine. More preferred are rings of benzene, carbazole, azacarbazole, and dibenzofuran.

If Ar₁₀₁ or Ar₁₀₂ is a carbazole ring or an azacarbazole ring, the ring is more preferably bonded at position N (also referred to as “position 9”) or position 3.

If Ar₁₀₁ or Ar₁₀₂ is a dibenzofuran ring, the ring is more preferably bonded at position 2 or 4.

In view of the use of the organic EL element in a vehicle, the host compound preferably has a high Tg under the assumption that the temperature in the vehicle increases to a high level. In a preferred embodiment, the aromatic ring represented by Ar₁₀₁ or Ar₁₀₂ is a condensed ring composed of three or more rings for increasing the Tg of the host compound represented by Formula (I).

Examples of the aromatic hydrocarbon condensed ring composed of three or more rings include rings of naphthacene, anthracene, tetracene, pentacene, hexacene, phenanthrene, pyrene, benzopyrene, benzazulene, chrysene, benzochrysene, acenaphthene, acenaphthylene, triphenylene, coronene, benzocoronene, hexabenzocoronene, fluorene, benzofluorene, fluoranthene, perylene, naphthoperylene, pentabenzoperylene, benzoperylene, pentaphene, picene, pyranthrene, coronene, naphthocoronene, ovalene, and anthranthrene. Each of these rings may further have any of the aforementioned substituents.

Examples of the aromatic heterocyclic ring composed of three or more rings include rings of acridine, benzoquinoline, carbazole, carboline, phenazine, phenanthridine, phenanthroline, carboline, cyclazine, quindoline, tepenidine, quinindoline, triphenodithiazine, triphenodioxazine, phenanthrazine, anthrazine, perimidine, diazacarbazole (any one of the carbon atoms forming the carboline ring is replaced with a nitrogen atom in the ring), phenanthroline, dibenzofuran, dibenzothiophene, naphthofuran, naphthothiophene, benzodifuran, benzodithiophene, naphthodifuran, naphthodithiophene, anthrafuran, anthradifuran, anthrathiophene, anthradithiophene, thianthrene, phenoxathiine, and thiophanthrene (naphthothiophene). Each of these rings may further have a substituent.

In Formula (I), n101 and n102 are each preferably 0 to 2, and n101+n102 is more preferably 1 to 3. If R₁₀₁ is a hydrogen atom and both n101 and n102 are zero, the host compound represented by Formula (I) has a low molecular weight and a low Tg. Thus, if R₁₀₁ is a hydrogen atom, n101 is 1 to 4.

The host compound used in the present invention is preferably a carbazole derivative having a structure represented by Formula (II) because such a compound exhibits particularly high carrier transportability.

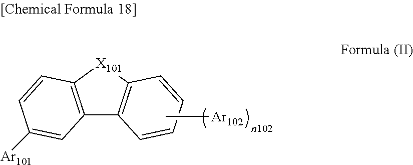

In Formula (II), X₁₀₁, Ar₁₀₁, Ar₁₀₂, and n102 are the same as those defined above in Formula (I).

In Formula (II), n102 is preferably 0 to 2, more preferably 0 or 1.

In Formula (II), the condensed ring including X₁₀₁ may have any substituent that does not impede the function of the host compound used in the present invention, besides Ar₁₀₁ and Ar₁₀₂.

The compound represented by Formula (II) is preferably represented by Formula (III-1), (III-2), or (III-3).

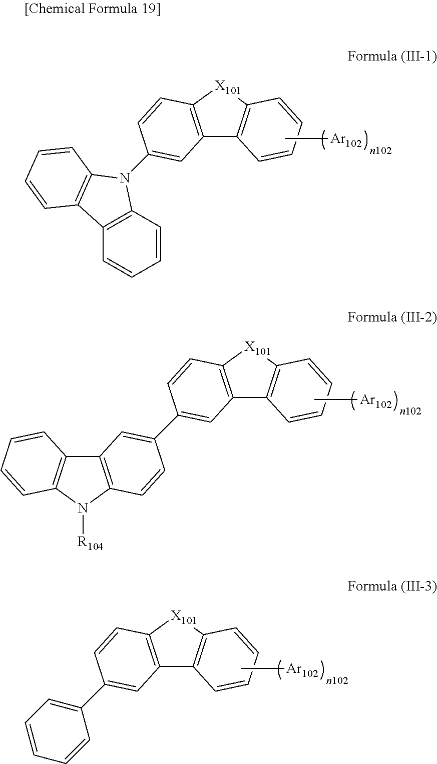

In Formulae (III-1) to (III-3), X₁₀₁, Ar₁₀₂, and n102 are the same as those defined above in Formula (II).

In Formulae (III-1) to (III-3), the condensed ring including X₁₀₁, the carbazole ring, or the benzene ring may further have any substituent that does not impede the function of the host compound used in the present invention.

Examples of the host compounds used in the present invention represented by Formulae (I), (II), and (III-1) to (III-3) and having other structures include, but are not limited to, the following compounds:

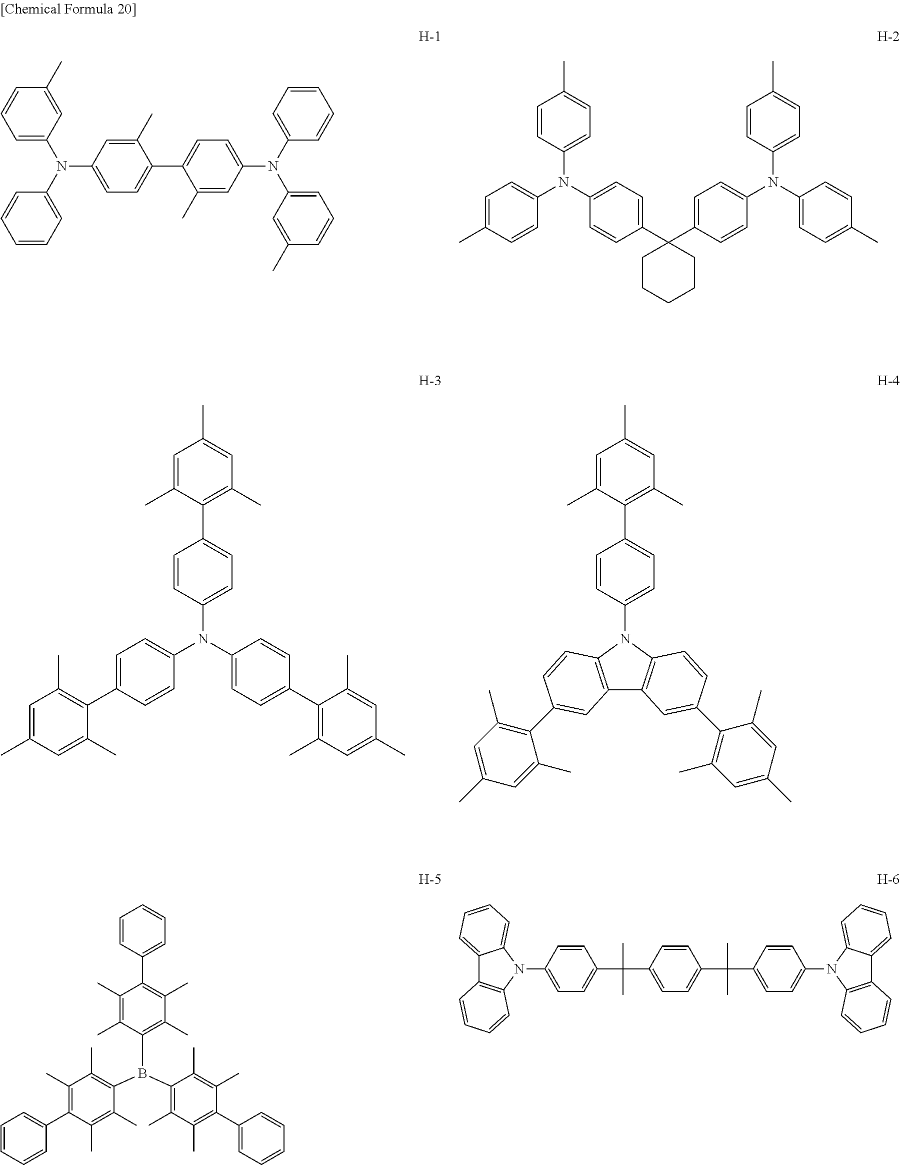

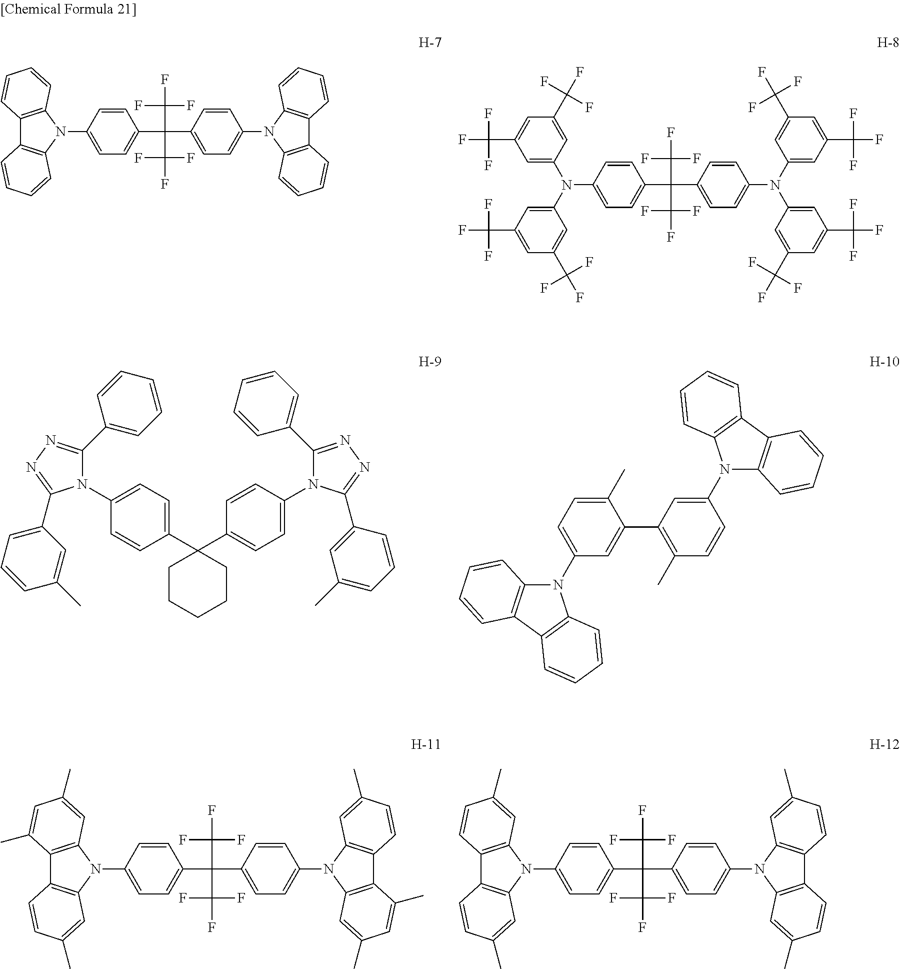

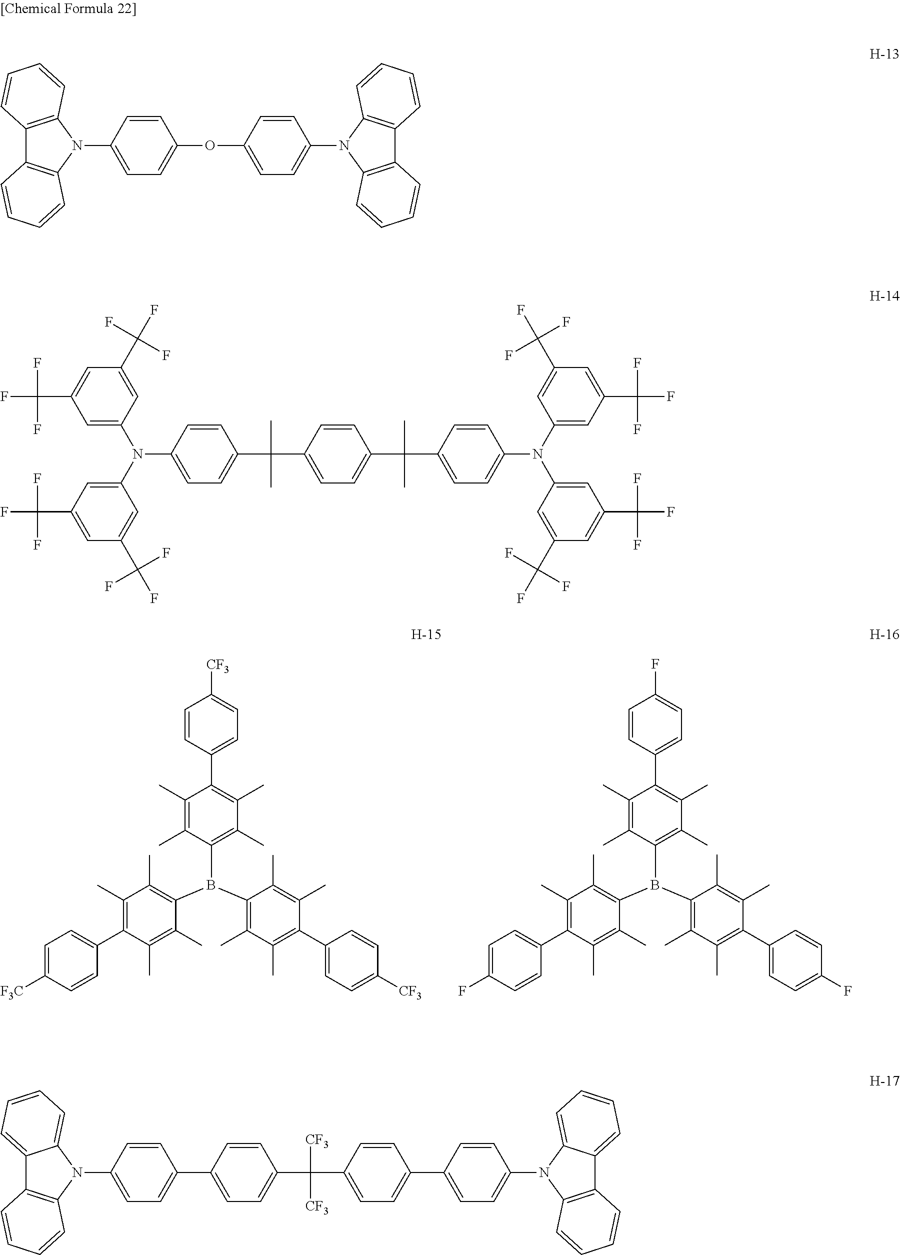

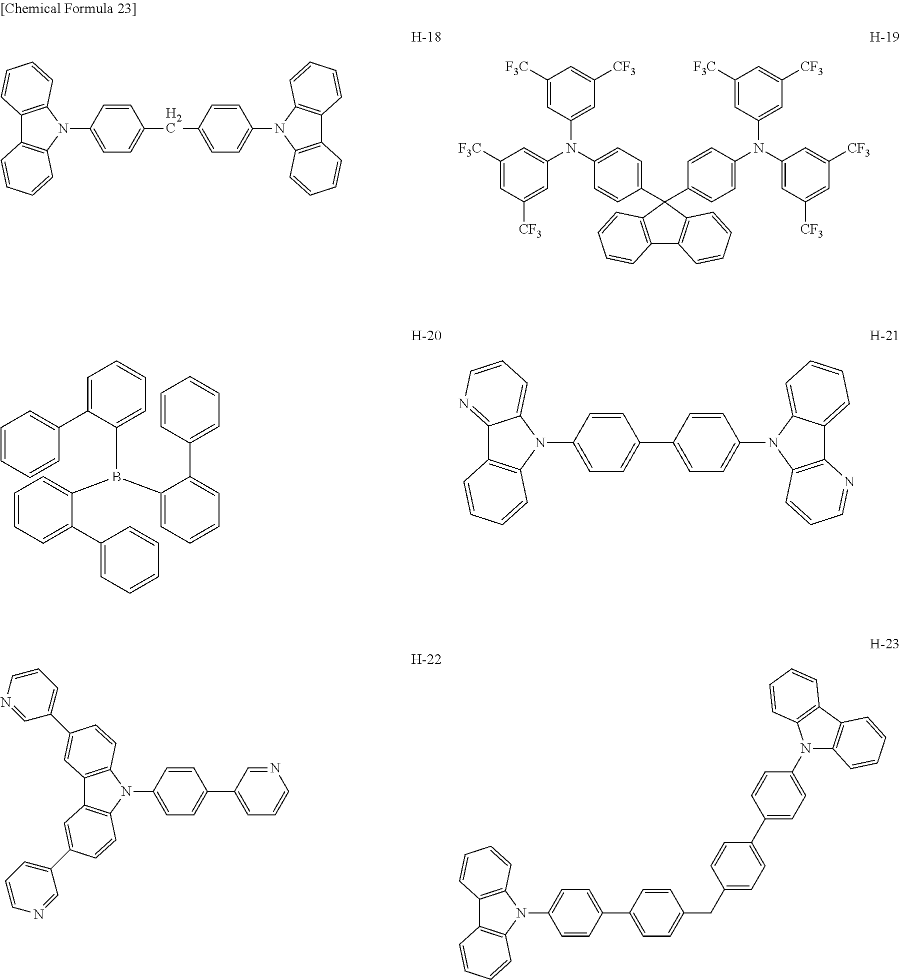

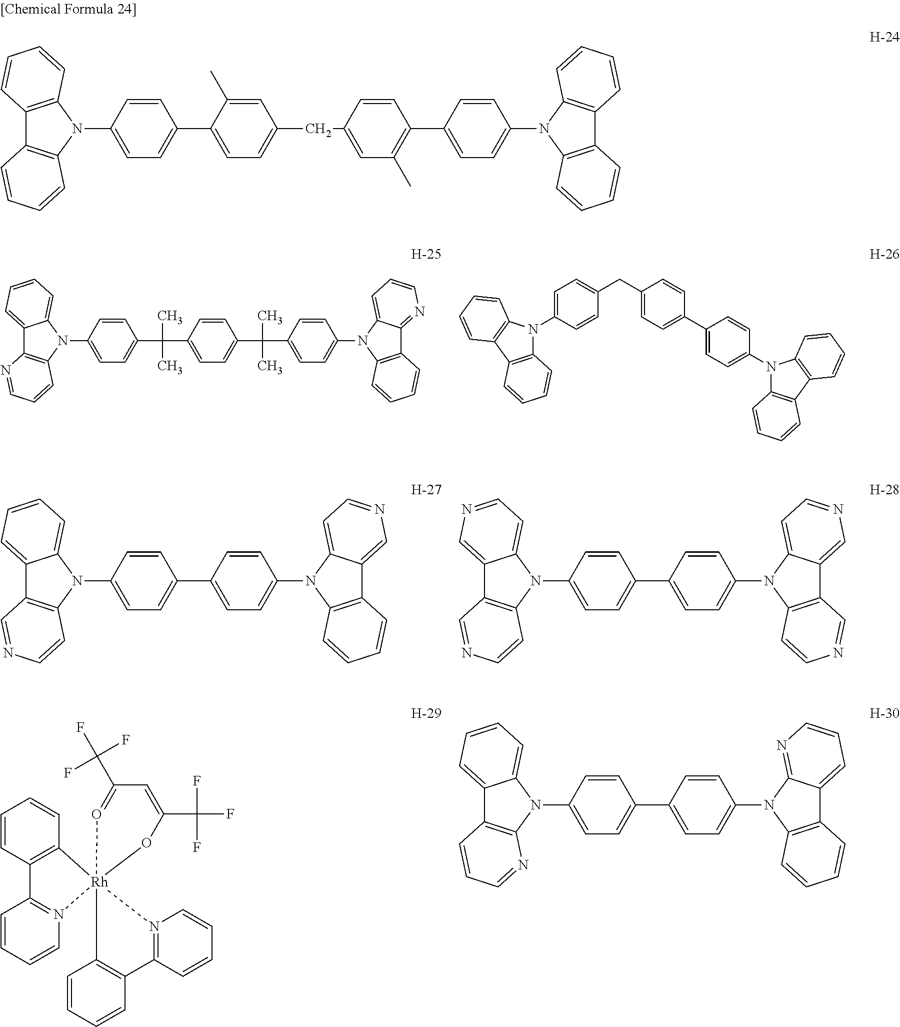

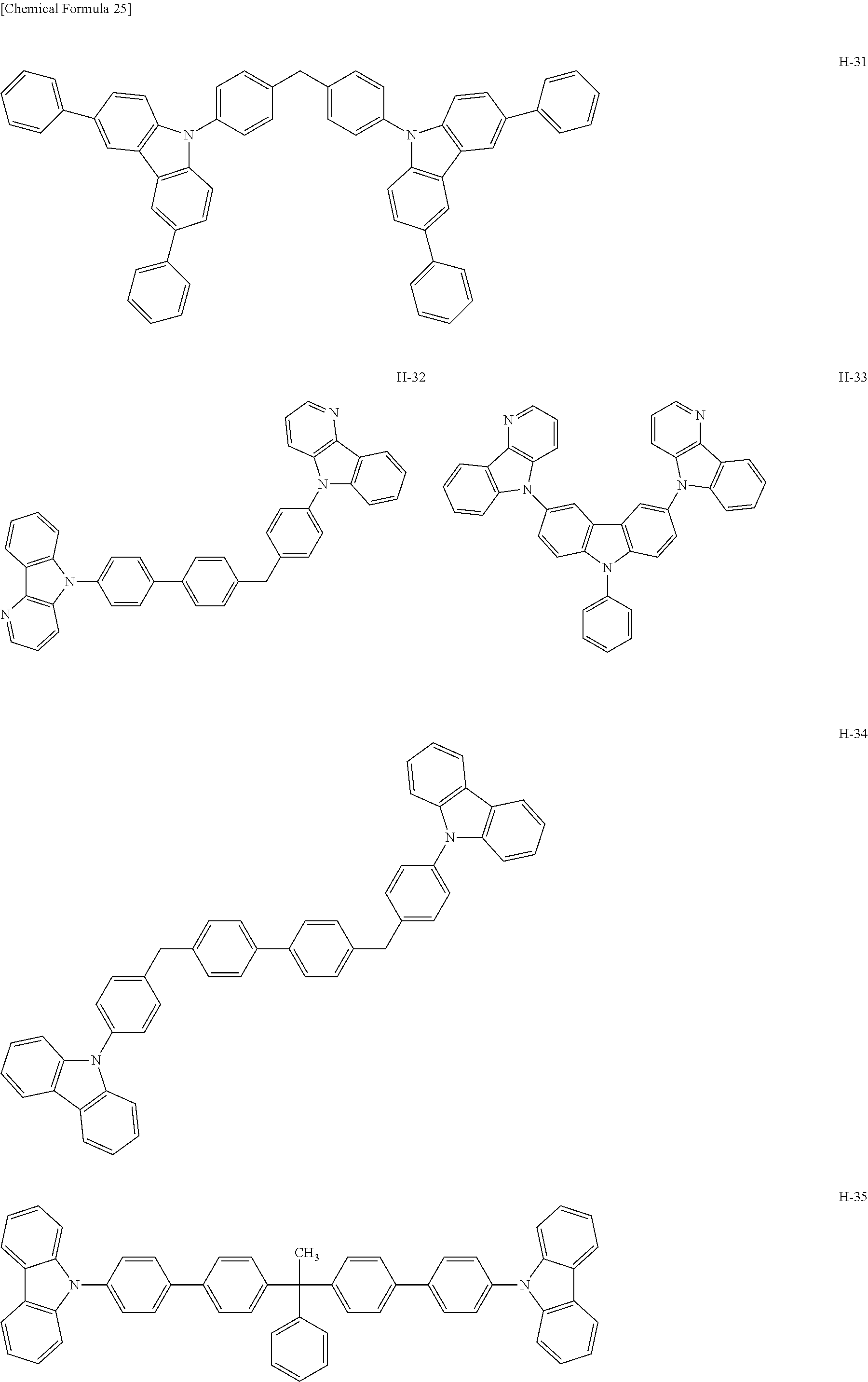

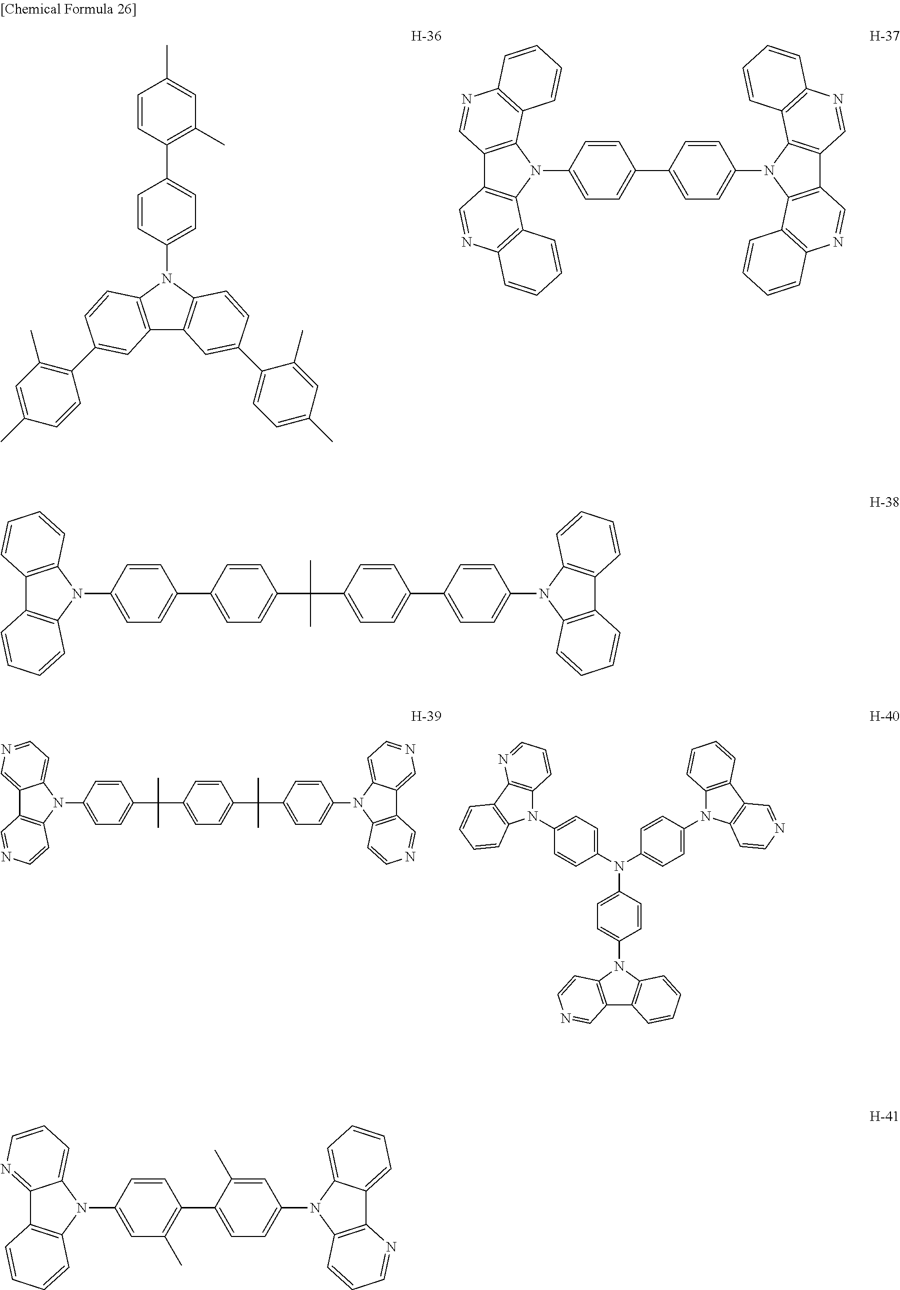

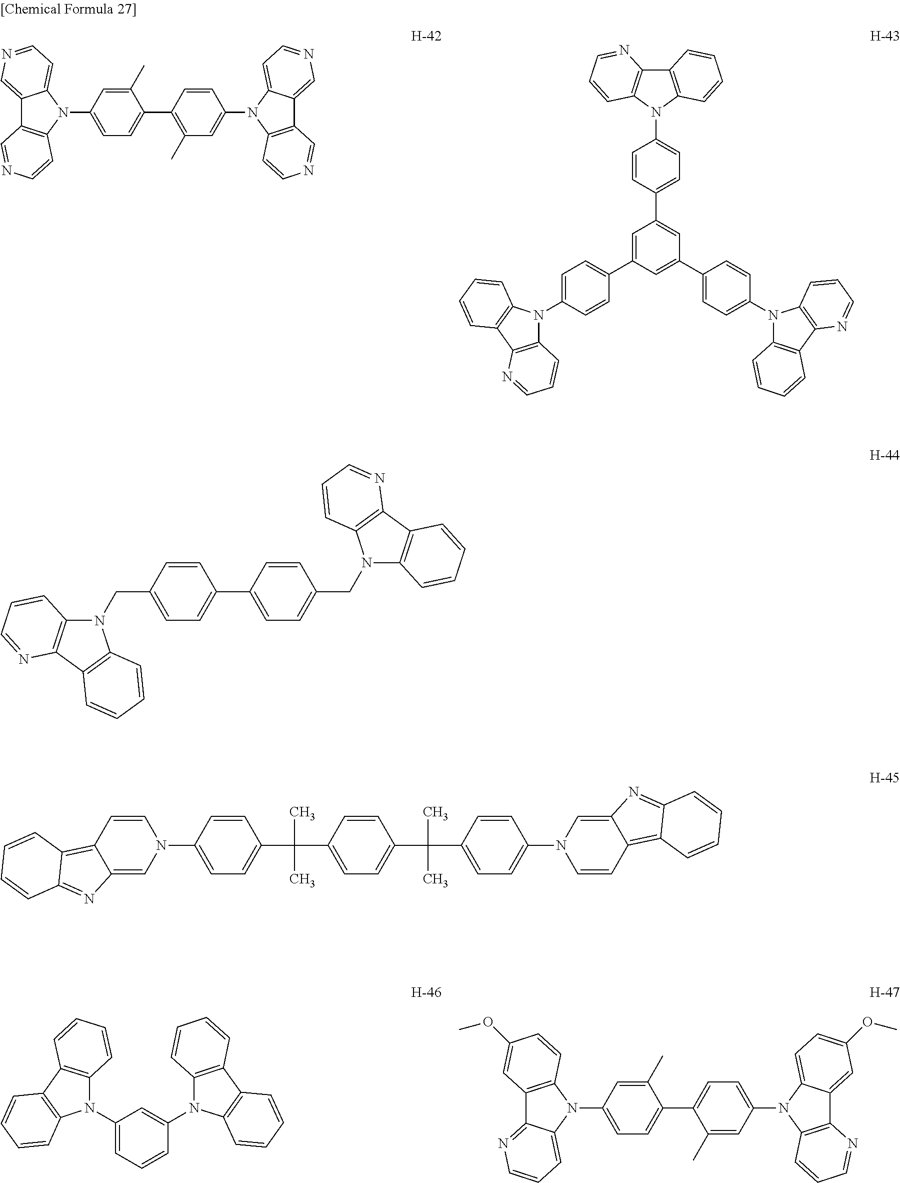

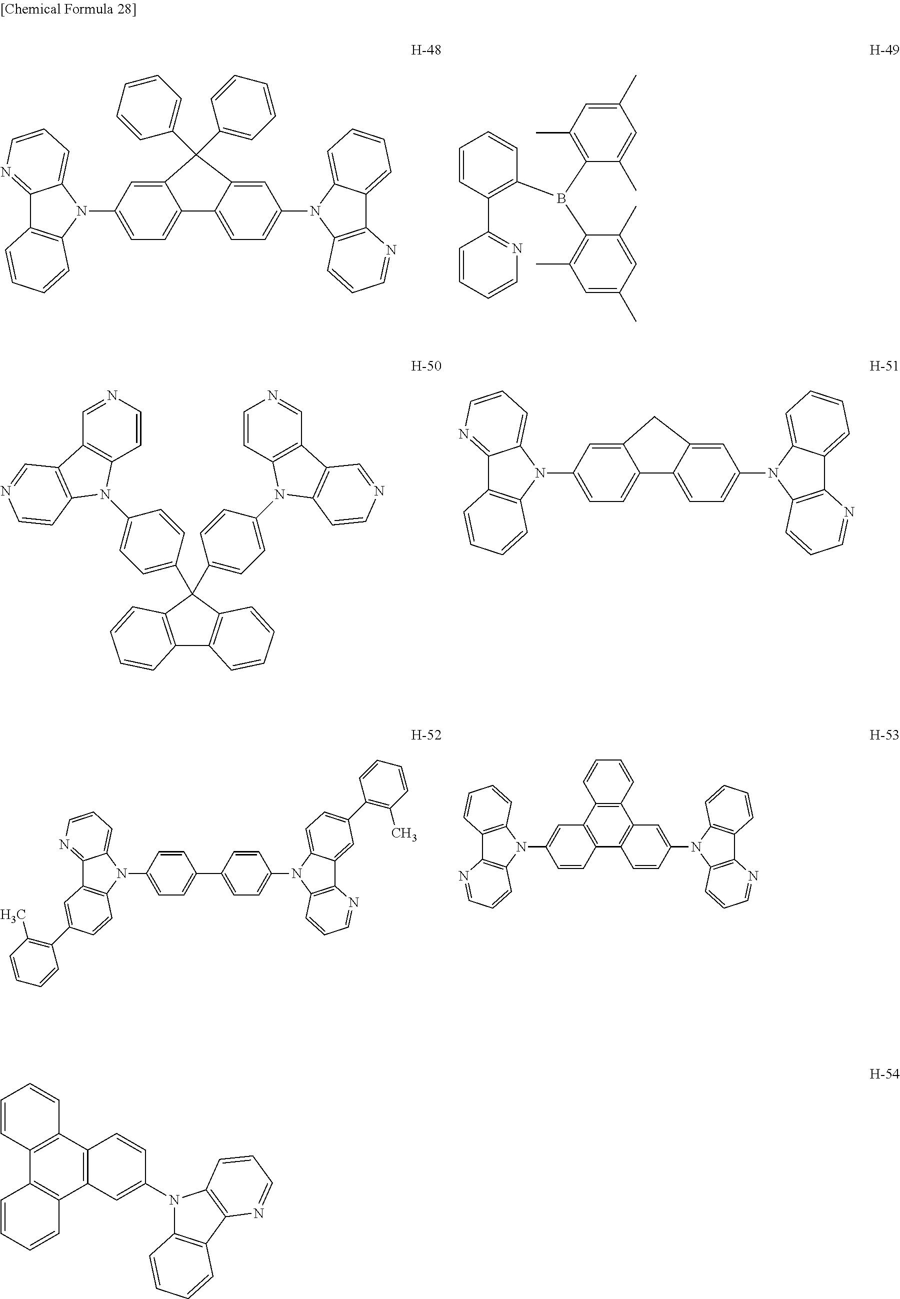

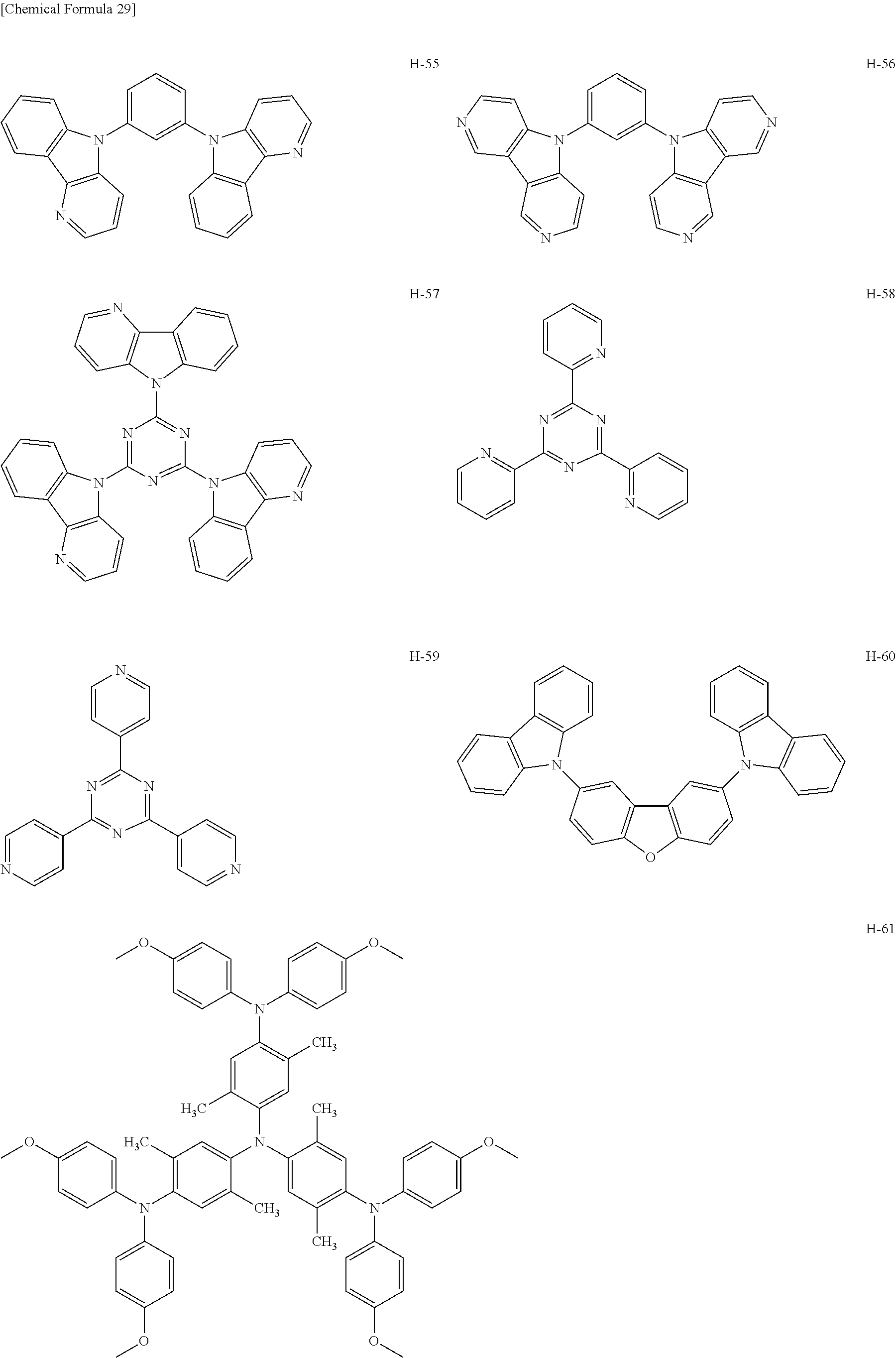

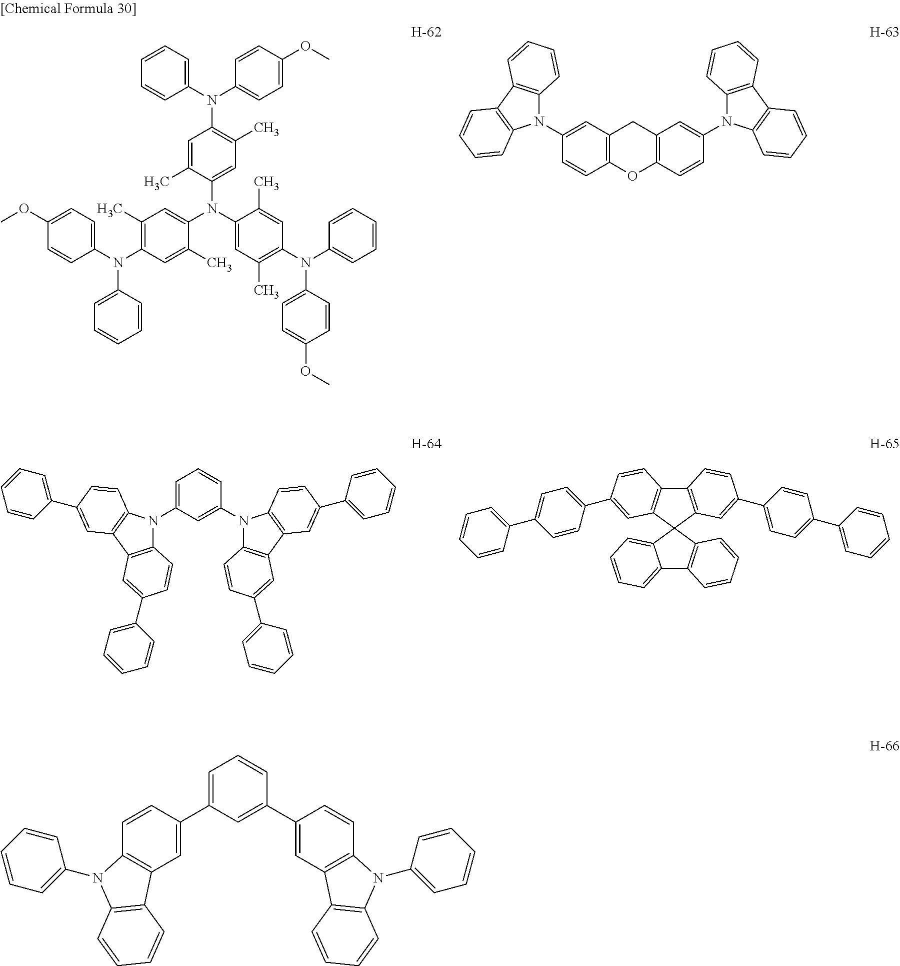

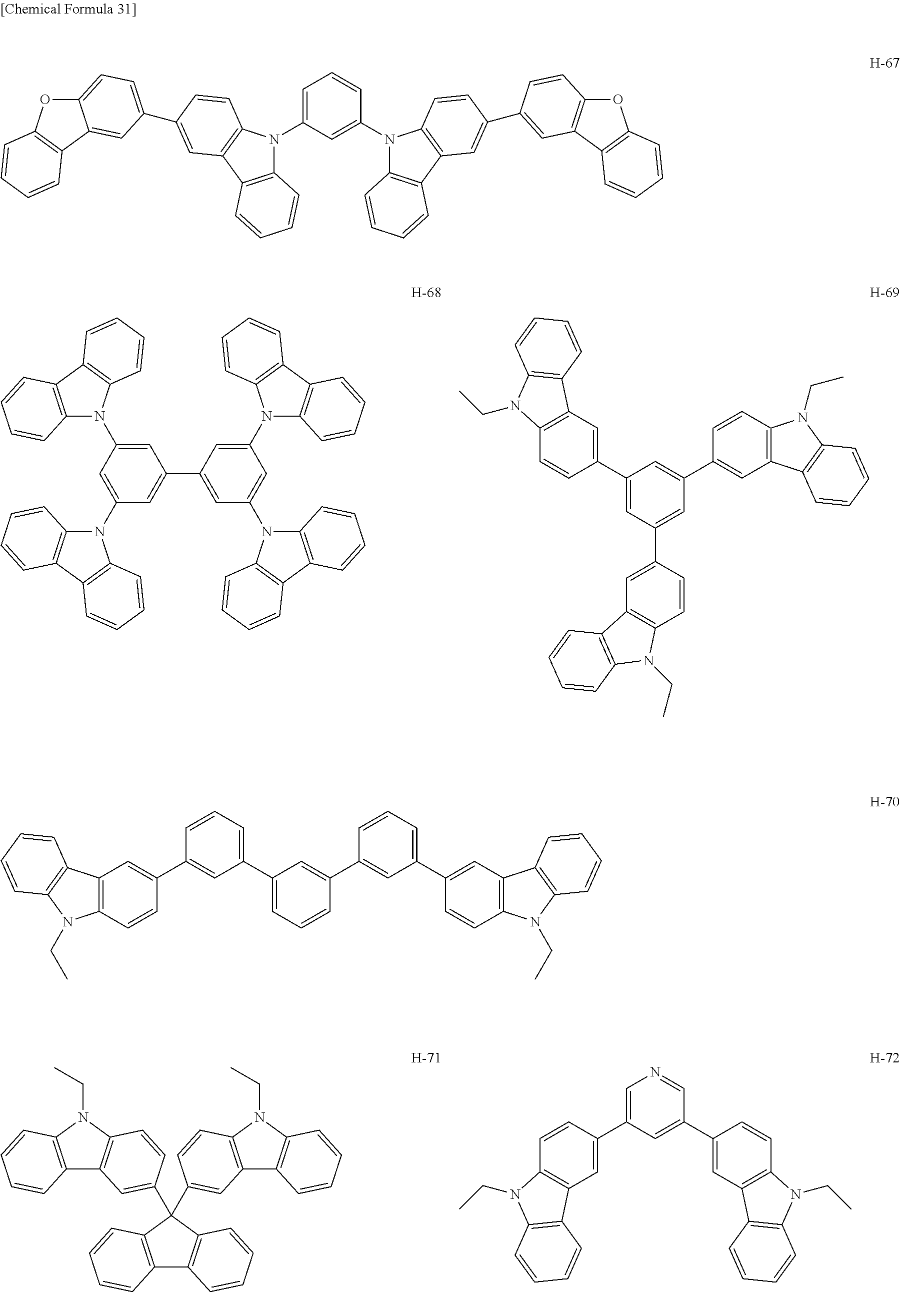

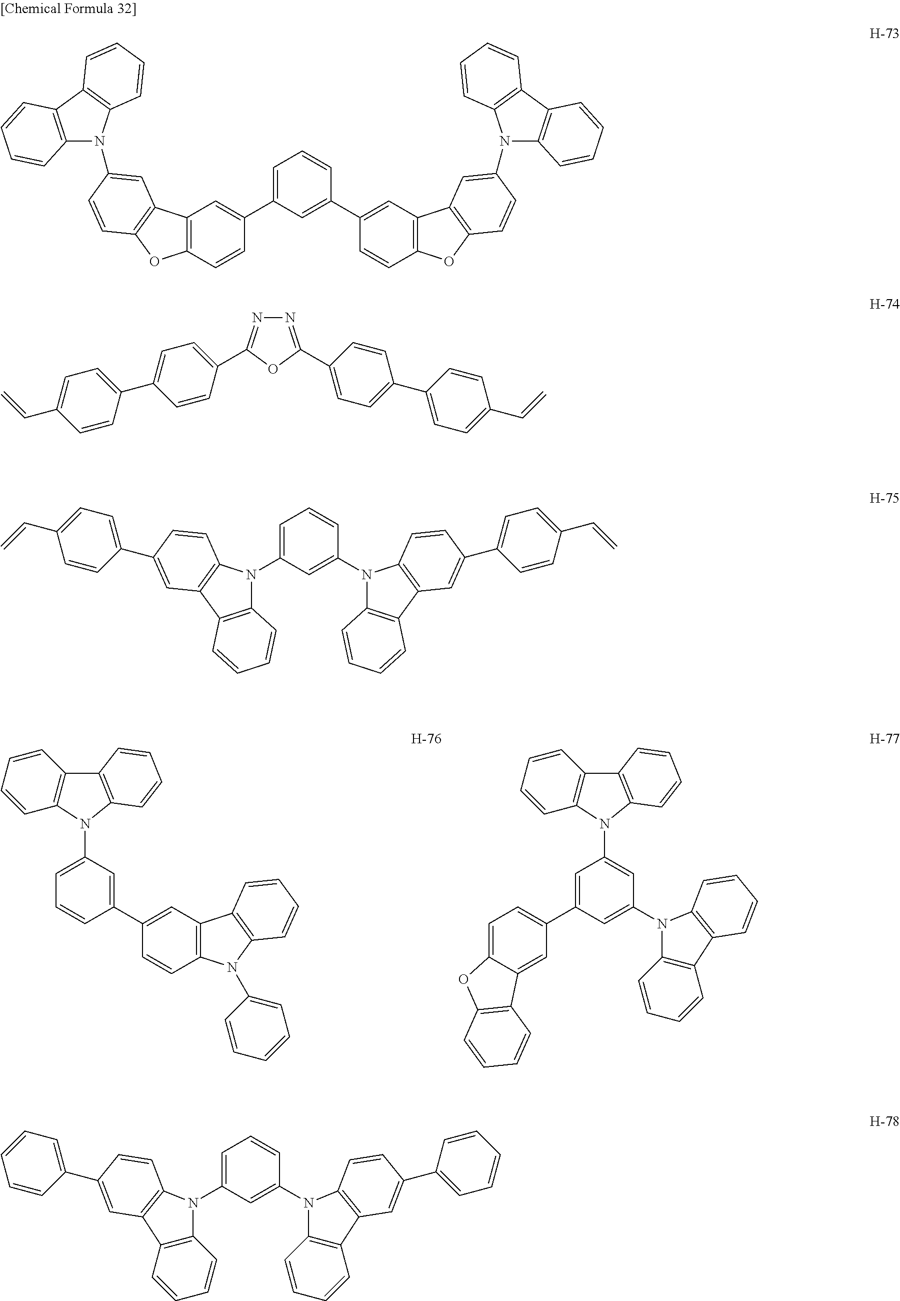

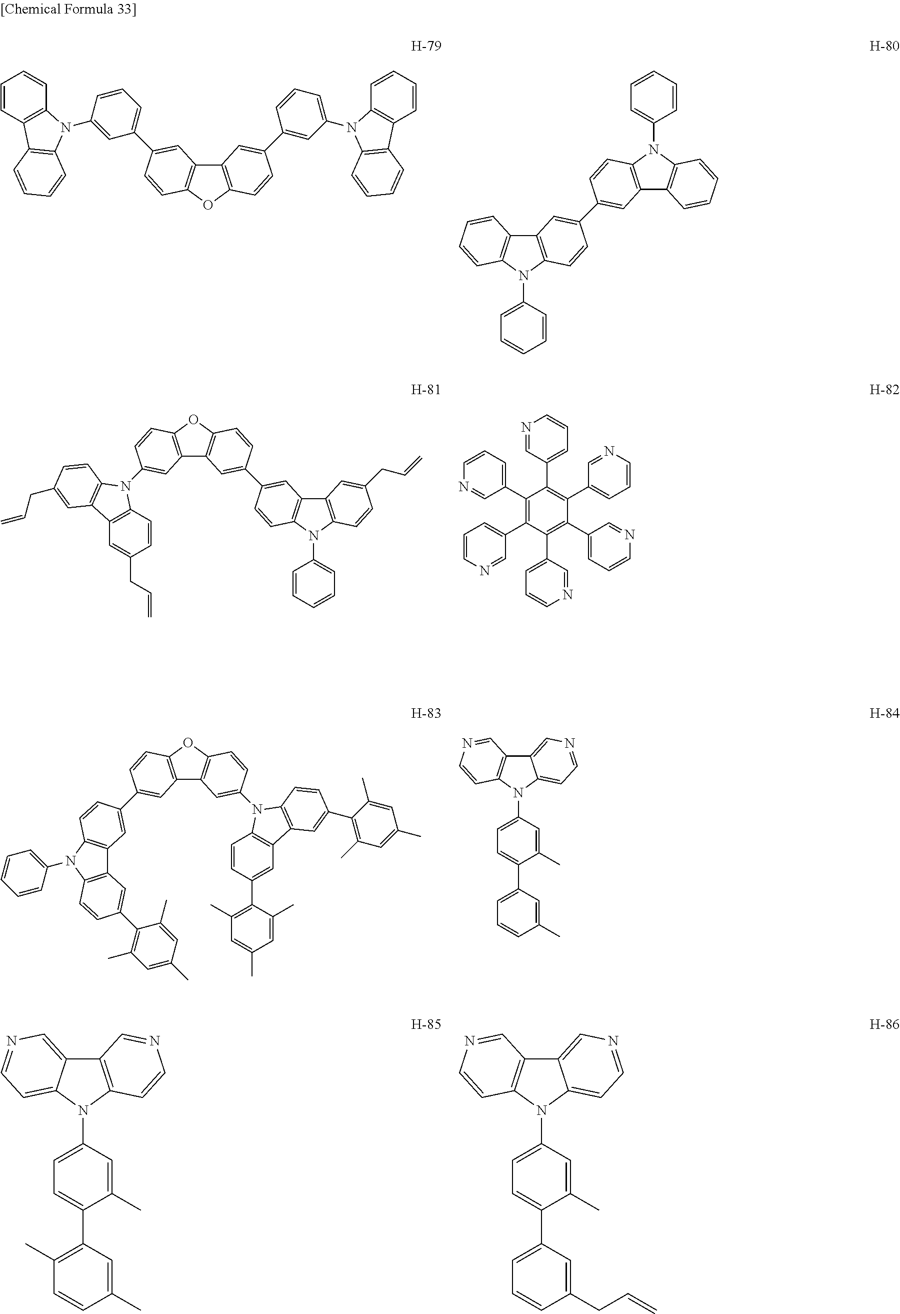

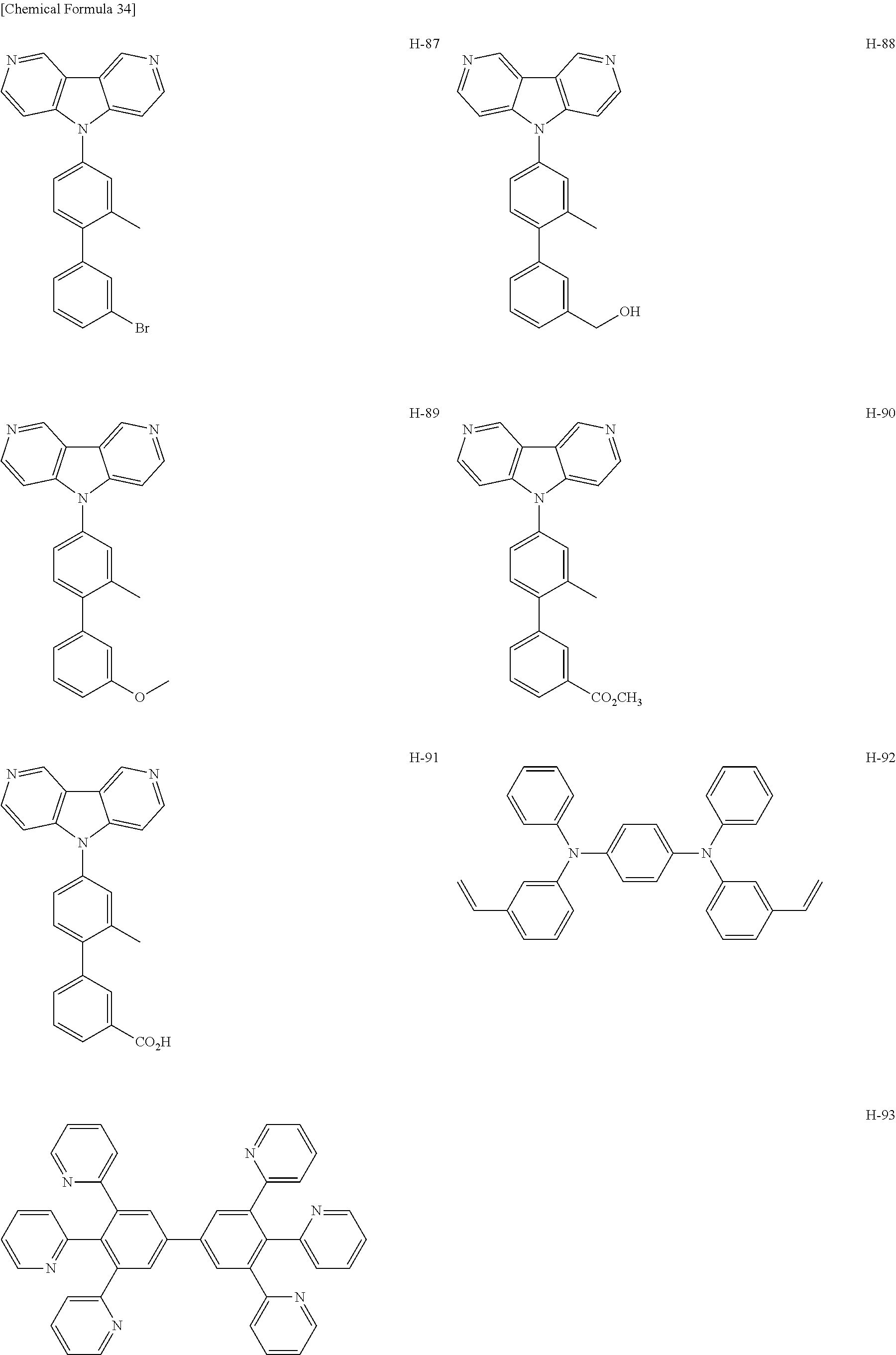

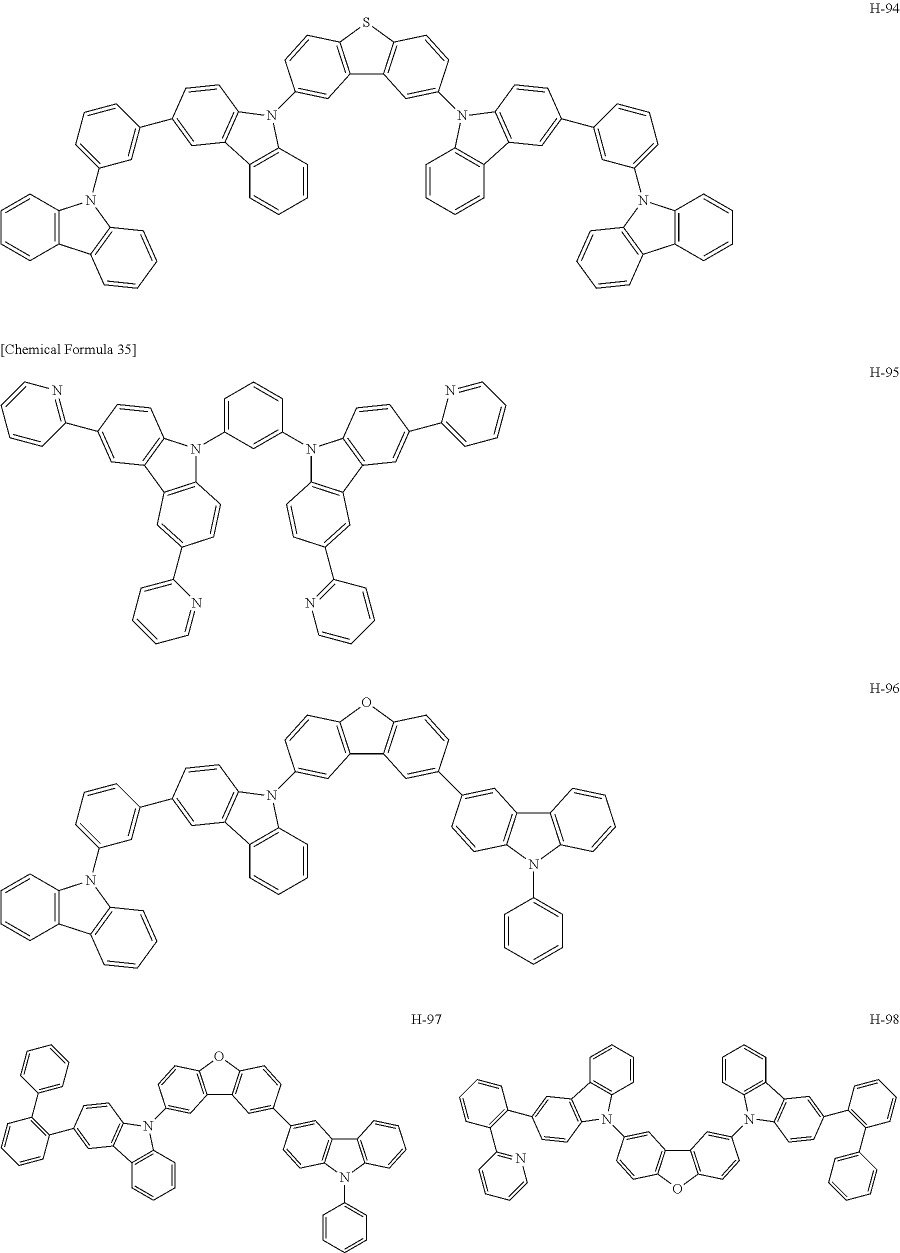

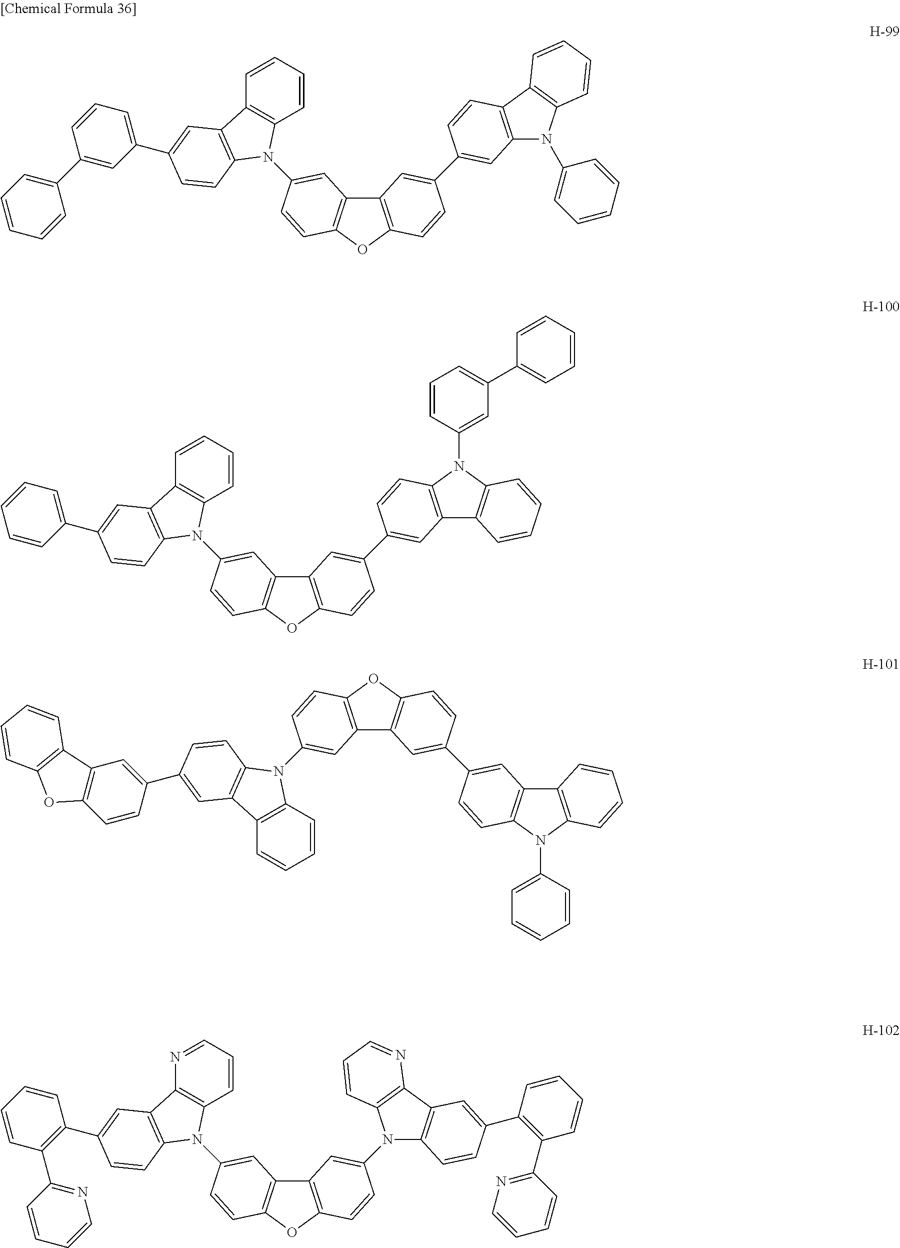 [SMILES: c1ccc(-c2cccc(-c3ccc4c(c3)c3ccccc3n4-c3ccc4oc5ccc(-c6ccc7c8ccccc8n(-c8ccccc8)c7c6)cc5c4c3)c2)cc1 ; c1ccc(-c2cccc(-n3c4ccccc4c4cc(-c5ccc6oc7ccc(-n8c9ccccc9c9cc(-c%10ccccc%10)ccc98)cc7c6c5)ccc43)c2)cc1 ; c1ccc(-n2c3ccccc3c3cc(-c4ccc5oc6ccc(-n7c8ccccc8c8cc(-c9ccc%10oc%11ccccc%11c%10c9)ccc87)cc6c5c4)ccc32)cc1 ; c1ccc(-c2ccccc2-c2ccc3c(c2)c2ncccc2n3-c2ccc3oc4ccc(-n5c6ccc(-c7ccccc7-c7ccccn7)cc6c6ncccc65)cc4c3c2)nc1]

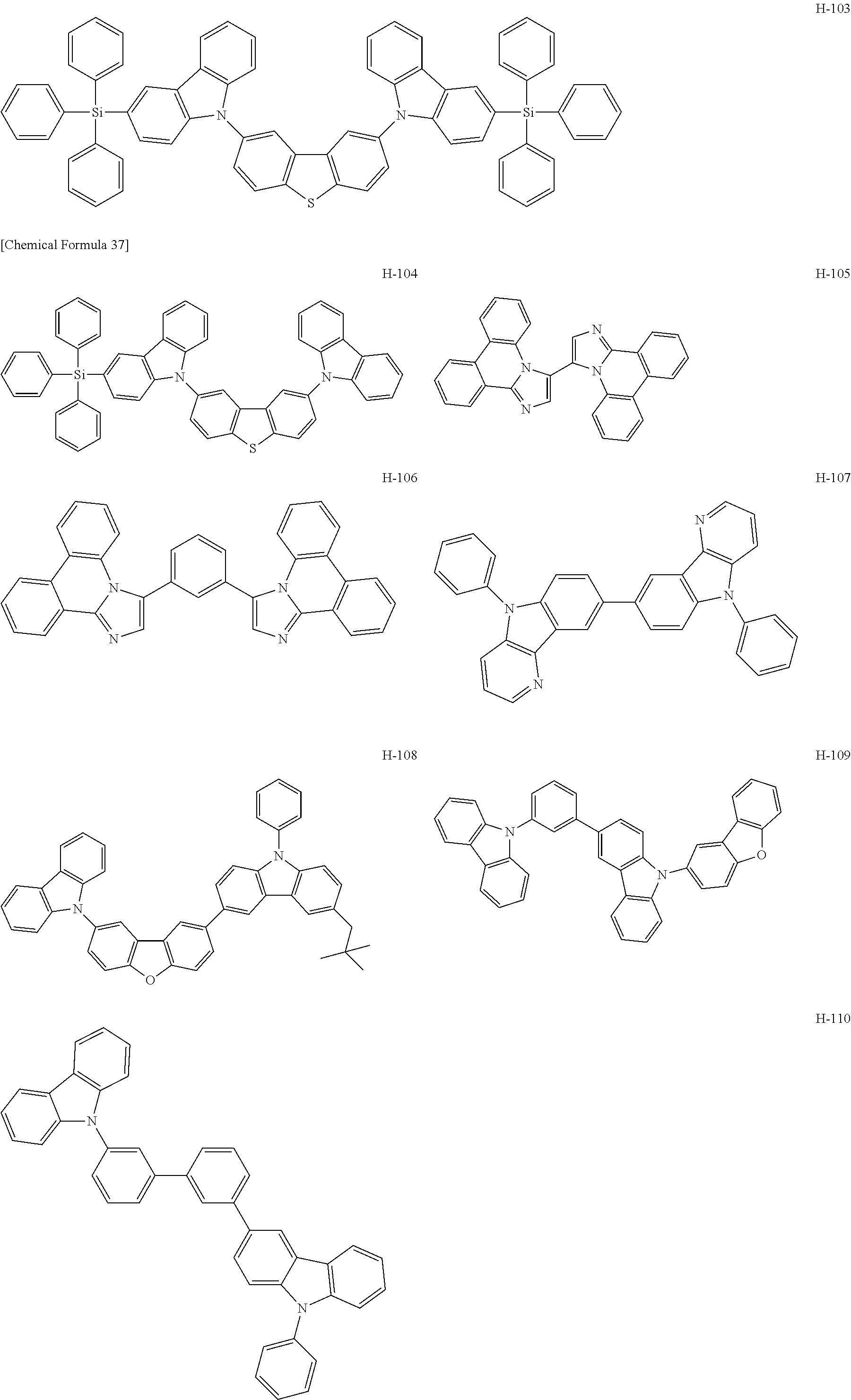

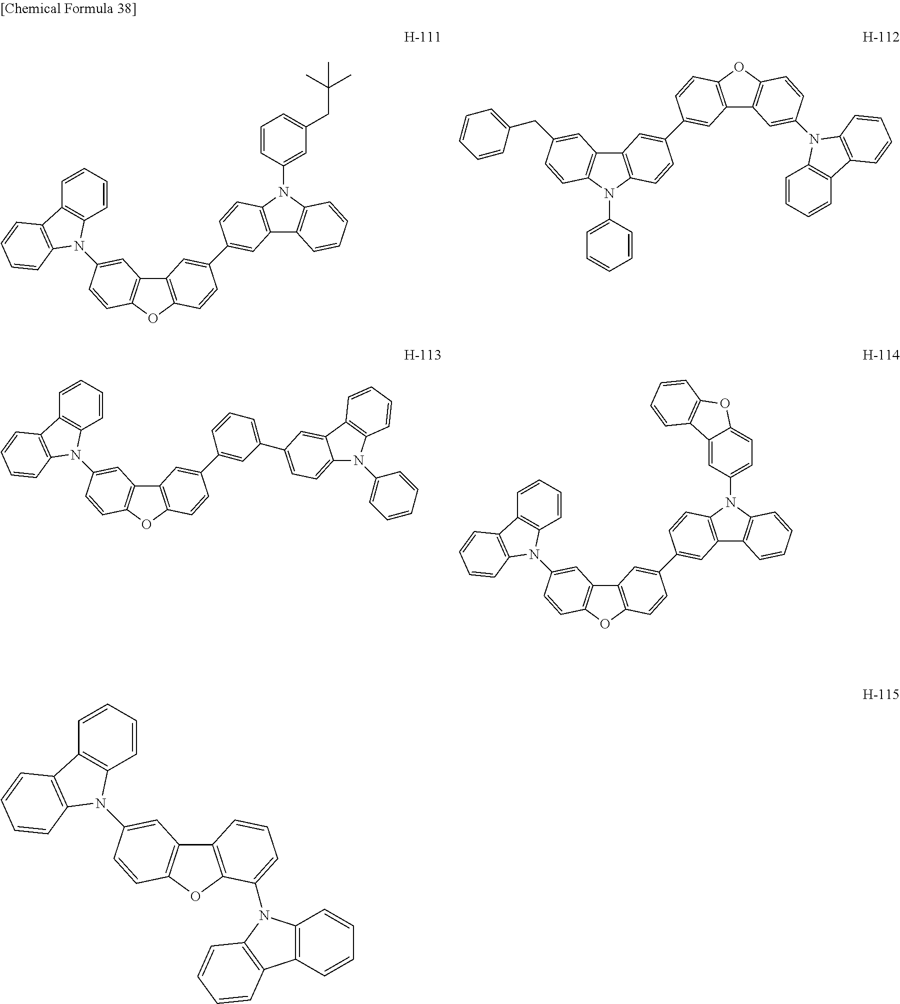 [SMILES: CC(C)(C)Cc1cccc(-n2c3ccccc3c3cc(-c4ccc5oc6ccc(-n7c8ccccc8c8ccccc87)cc6c5c4)ccc32)c1 ; c1ccc(Cc2ccc3c(c2)c2cc(-c4ccc5oc6ccc(-n7c8ccccc8c8ccccc87)cc6c5c4)ccc2n3-c2ccccc2)cc1 ; c1ccc(-n2c3ccccc3c3cc(-c4cccc(-c5ccc6oc7ccc(-n8c9ccccc9c9ccccc98)cc7c6c5)c4)ccc32)cc1 ; c1ccc2c(c1)oc1ccc(-n3c4ccccc4c4cc(-c5ccc6oc7ccc(-n8c9ccccc9c9ccccc98)cc7c6c5)ccc43)cc12 ; c1cc(-n2c3ccccc3c3ccccc32)c2oc3ccc(-n4c5ccccc5c5ccccc54)cc3c2c1]

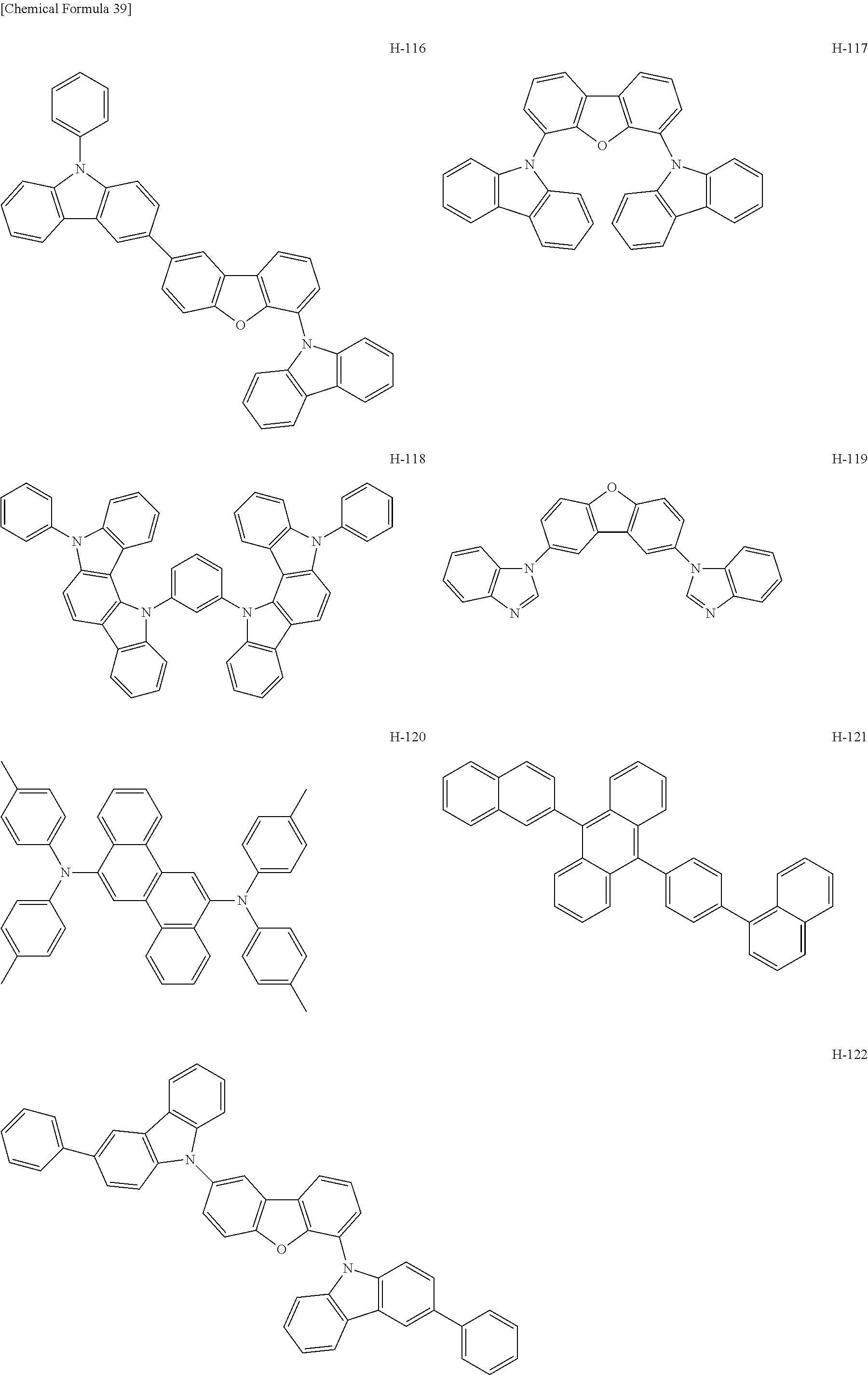

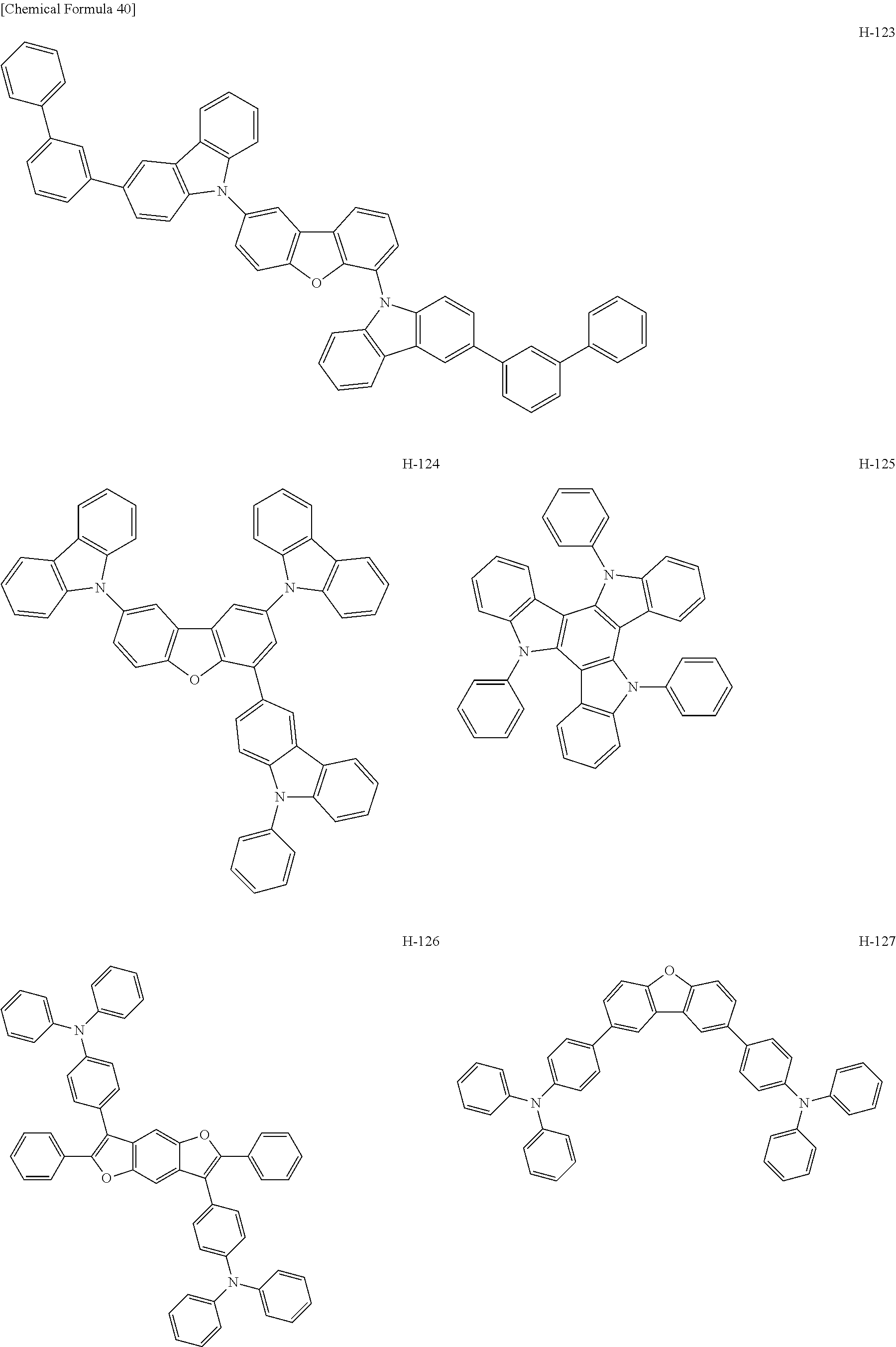 [SMILES: c1ccc(-c2cccc(-c3ccc4c(c3)c3ccccc3n4-c3ccc4oc5c(-n6c7ccccc7c7cc(-c8cccc(-c9ccccc9)c8)ccc76)cccc5c4c3)c2)cc1 ; c1ccc(-n2c3ccccc3c3cc(-c4cc(-n5c6ccccc6c6ccccc65)cc5c4oc4ccc(-n6c7ccccc7c7ccccc76)cc45)ccc32)cc1 ; c1ccc(-n2c3ccccc3c3c2c2c4ccccc4n(-c4ccccc4)c2c2c4ccccc4n(-c4ccccc4)c32)cc1 ; c1ccc(-c2oc3cc4c(-c5ccc(N(c6ccccc6)c6ccccc6)cc5)c(-c5ccccc5)oc4cc3c2-c2ccc(N(c3ccccc3)c3ccccc3)cc2)cc1 ; c1ccc(N(c2ccccc2)c2ccc(-c3ccc4oc5ccc(-c6ccc(N(c7ccccc7)c7ccccc7)cc6)cc5c4c3)cc2)cc1]

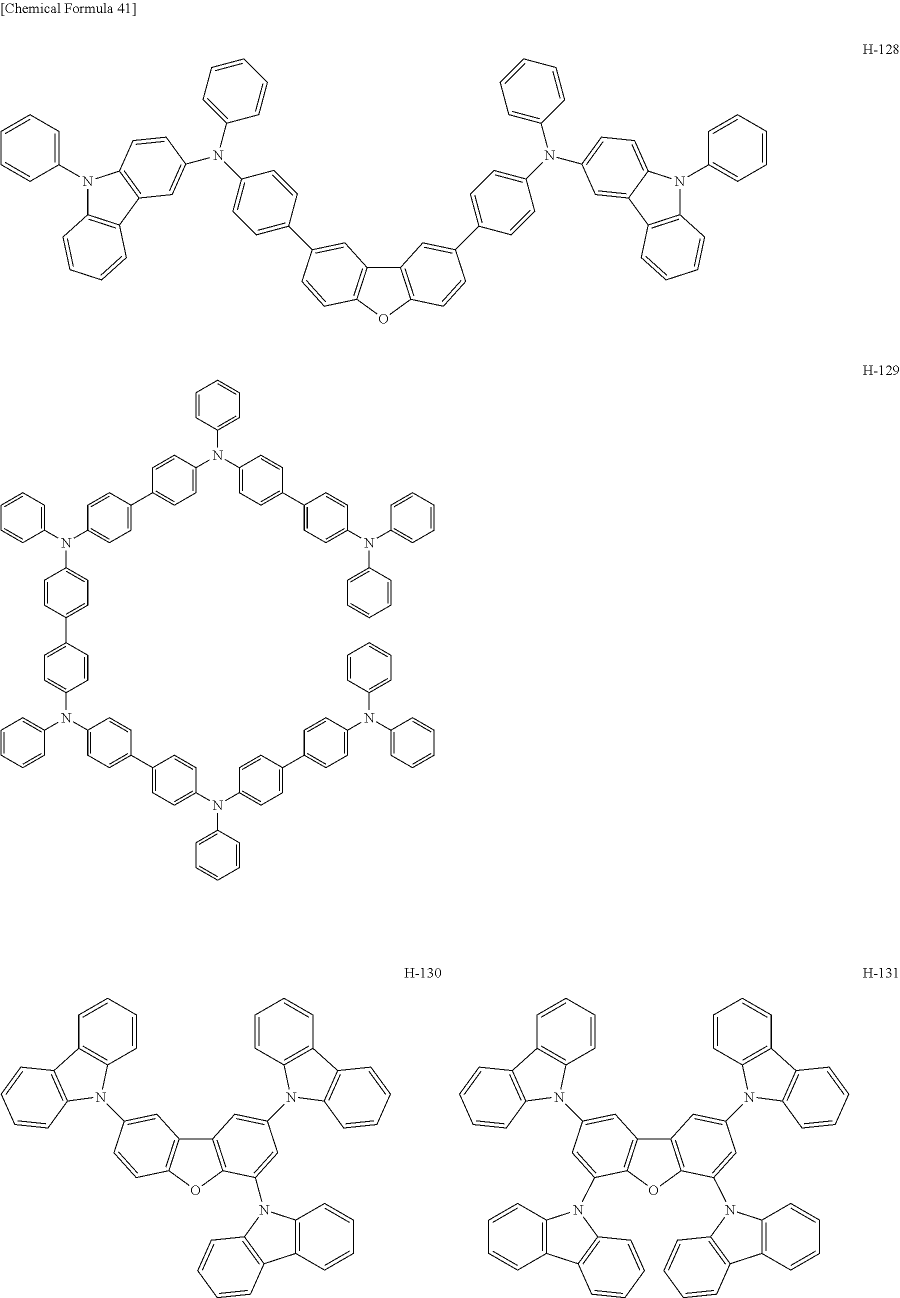

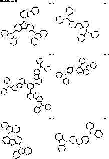

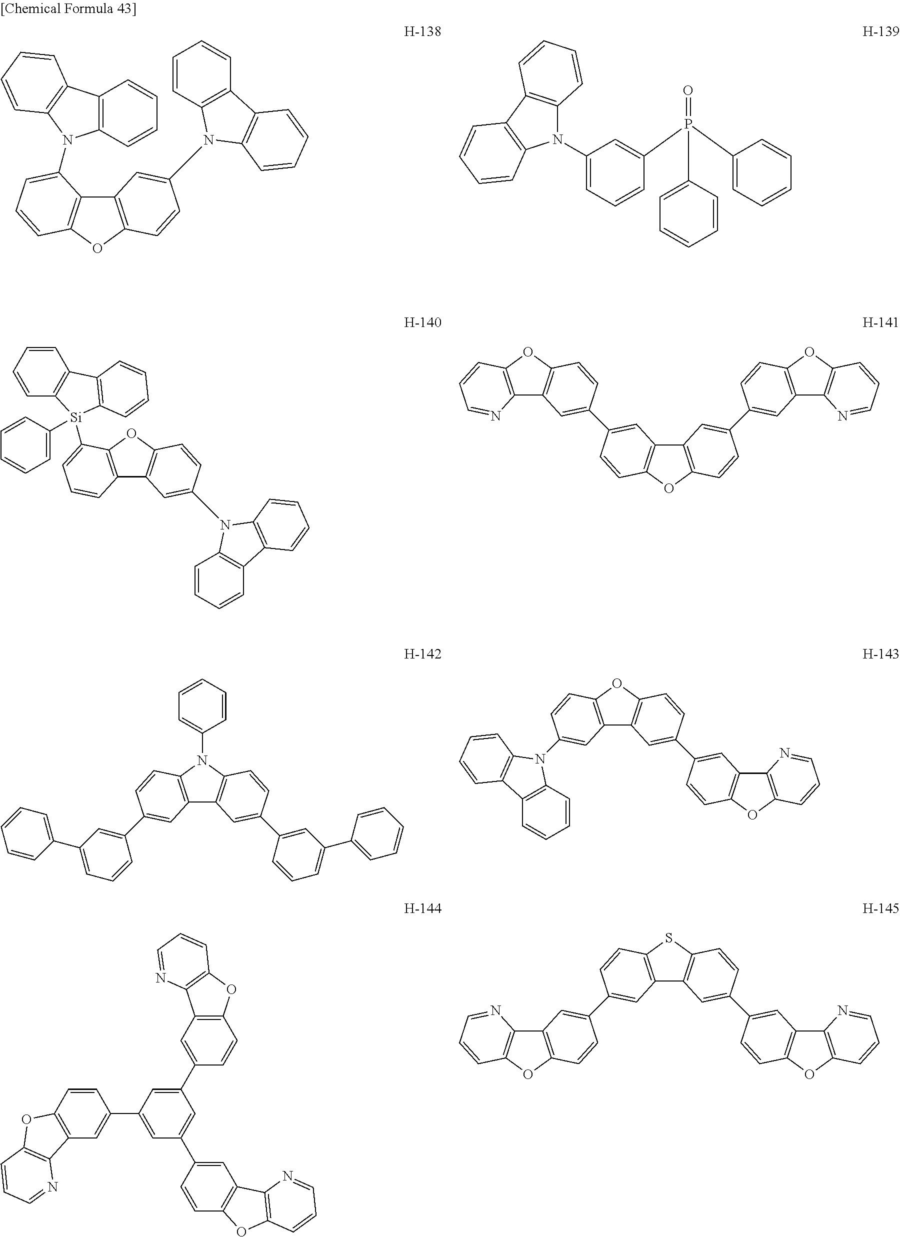

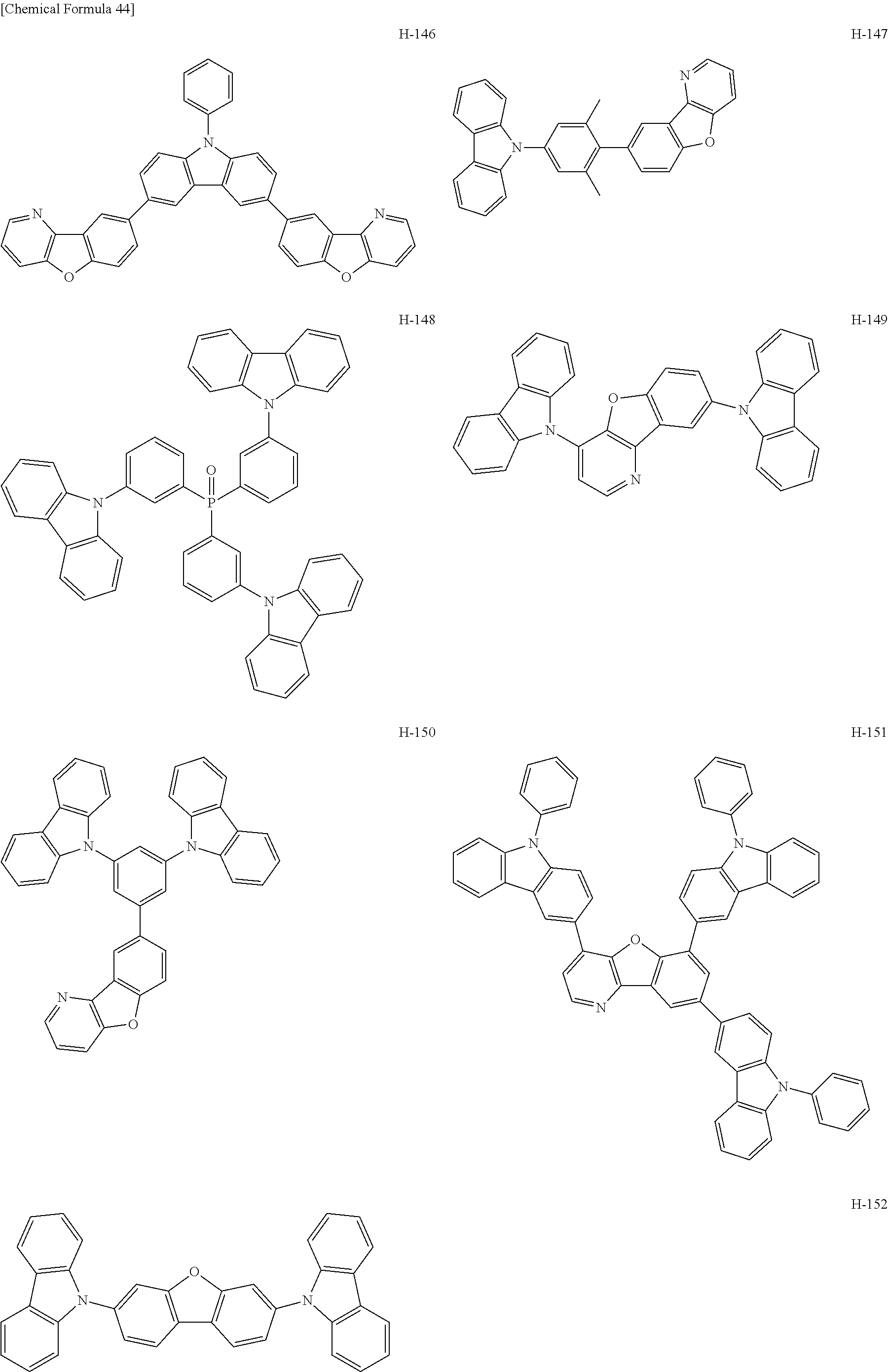

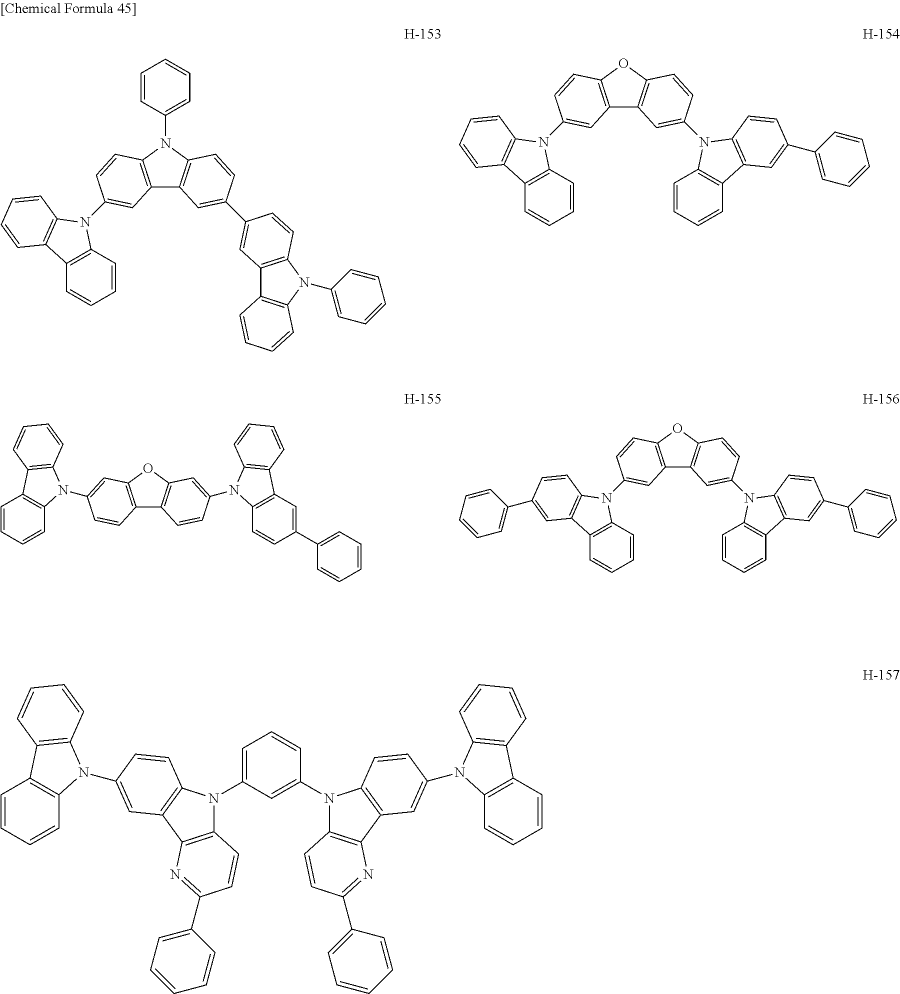 [SMILES: c1ccc(-n2c3ccccc3c3cc(-c4ccc5c(c4)c4cc(-n6c7ccccc7c7ccccc76)ccc4n5-c4ccccc4)ccc32)cc1 ; c1ccc(-c2ccc3c(c2)c2ccccc2n3-c2ccc3oc4ccc(-n5c6ccccc6c6ccccc65)cc4c3c2)cc1 ; c1ccc(-c2ccc3c(c2)c2ccccc2n3-c2ccc3c(c2)oc2cc(-n4c5ccccc5c5ccccc54)ccc23)cc1 ; c1ccc(-c2ccc3c(c2)c2ccccc2n3-c2ccc3oc4ccc(-n5c6ccccc6c6cc(-c7ccccc7)ccc65)cc4c3c2)cc1 ; c1ccc(-c2ccc3c(n2)c2cc(-n4c5ccccc5c5ccccc54)ccc2n3-c2cccc(-n3c4ccc(-n5c6ccccc6c6ccccc65)cc4c4nc(-c5ccccc5)ccc43)c2)cc1]

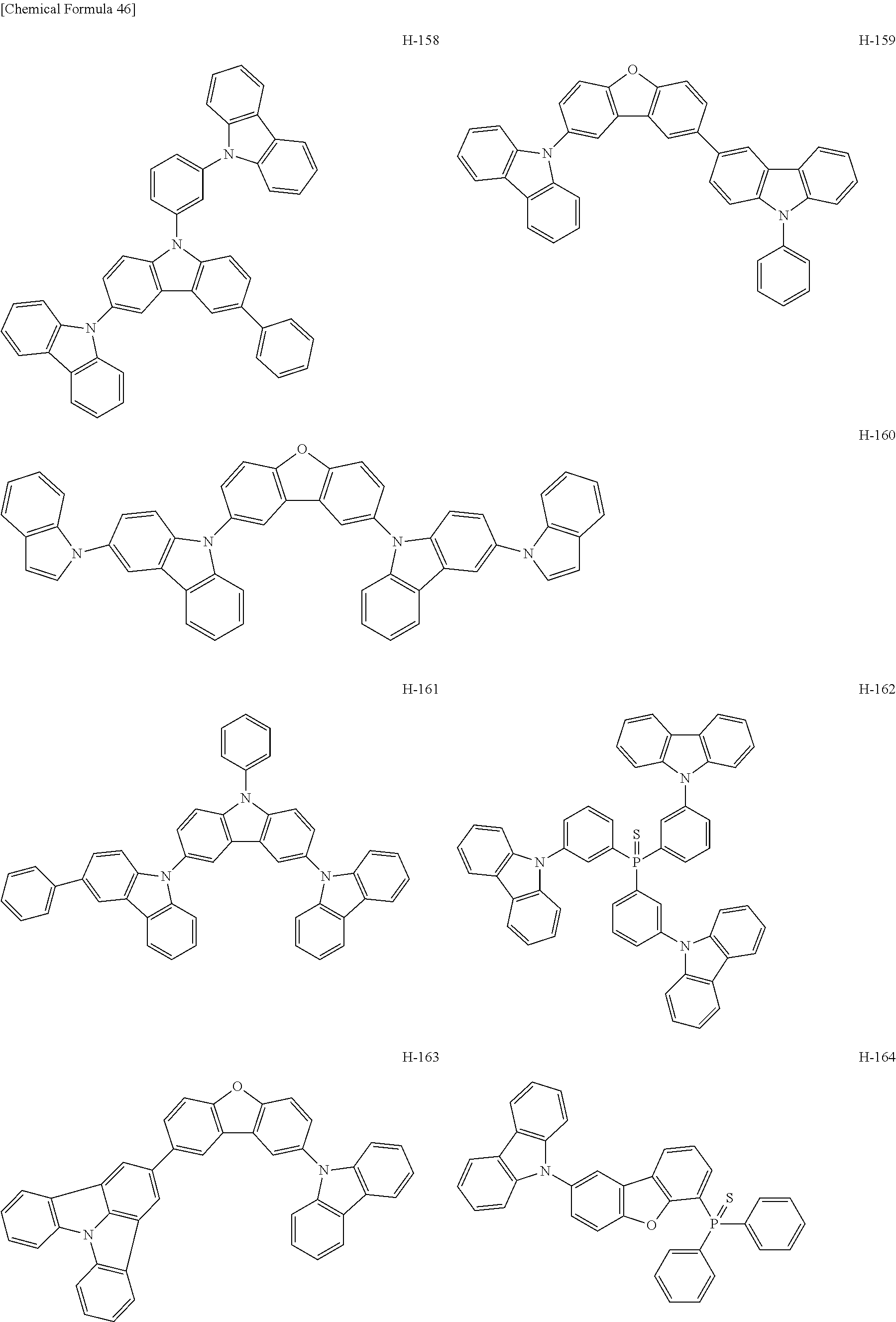

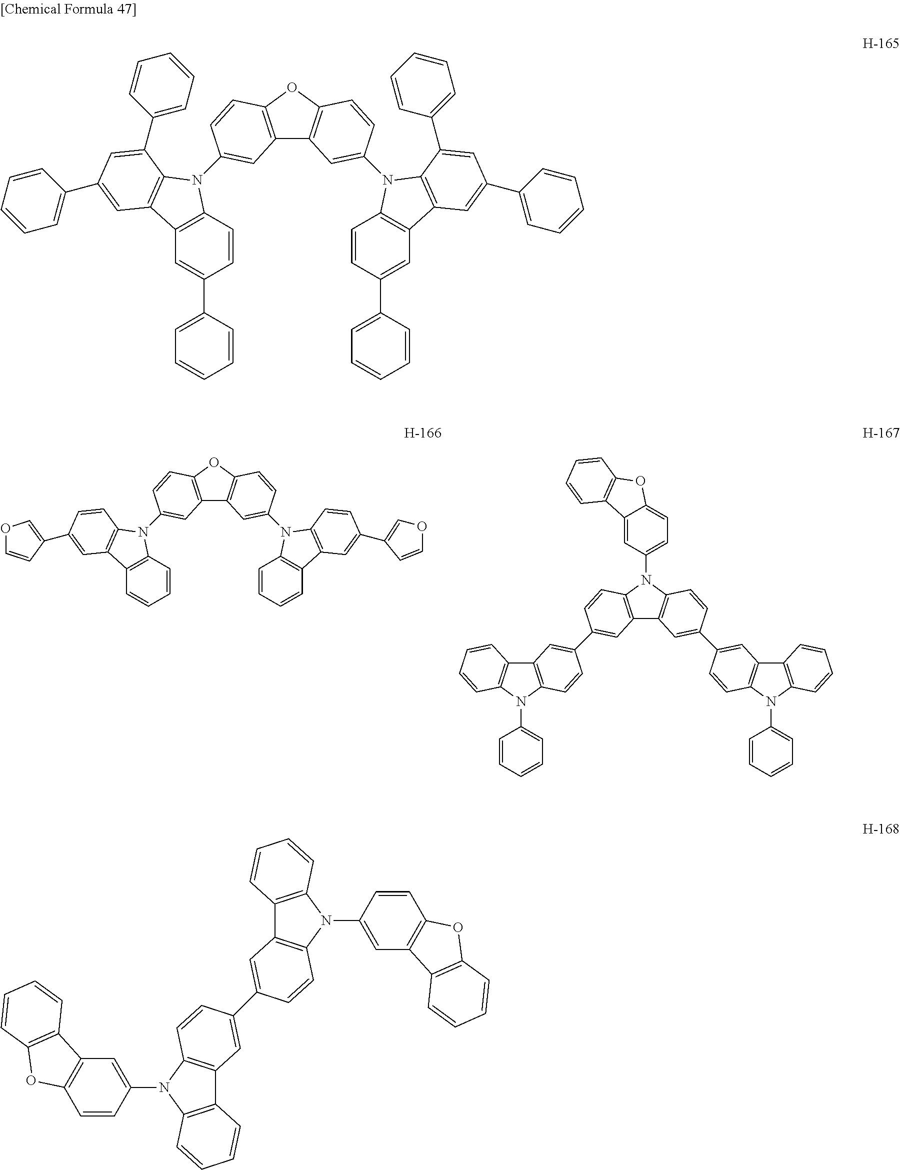

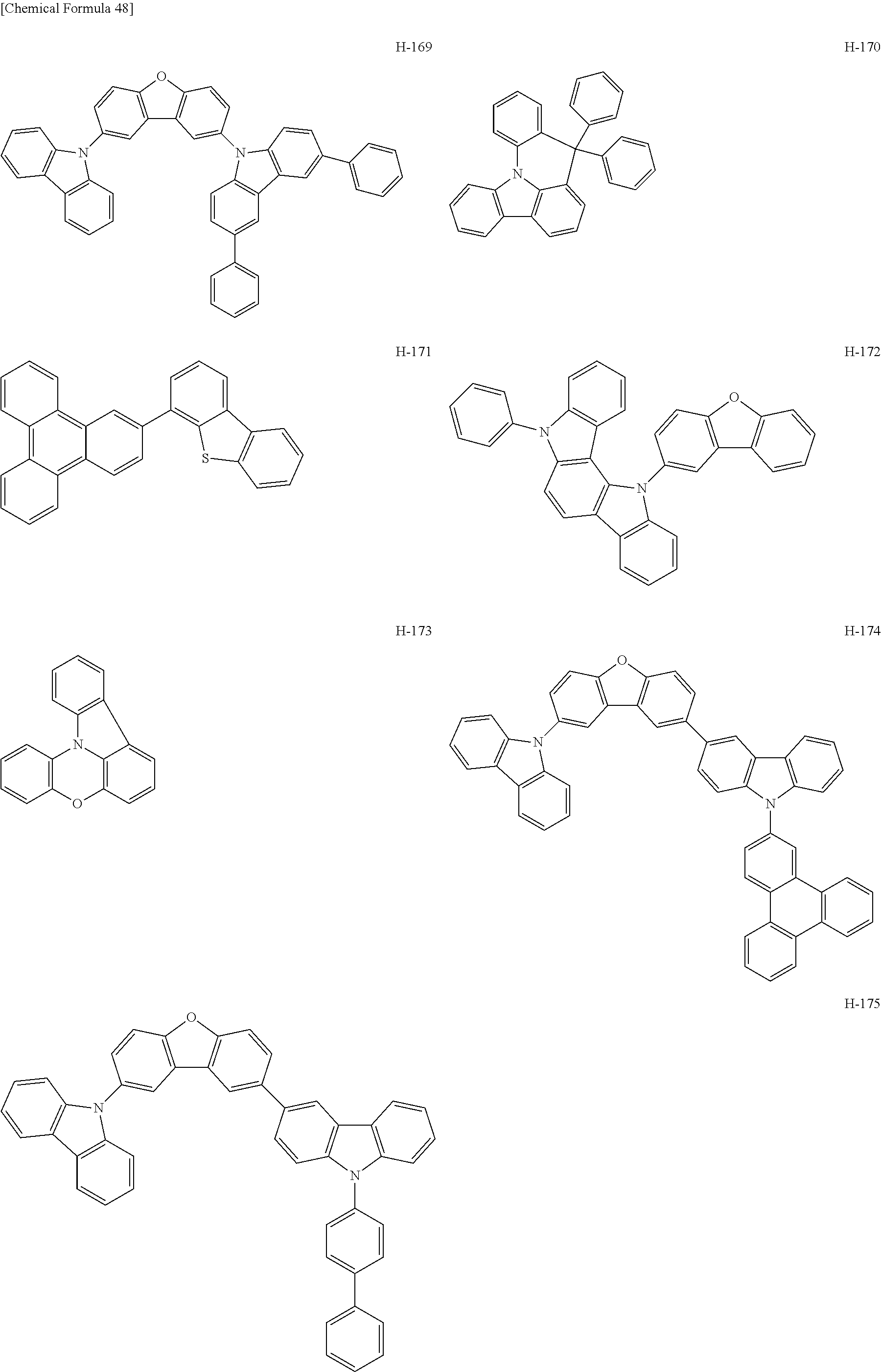

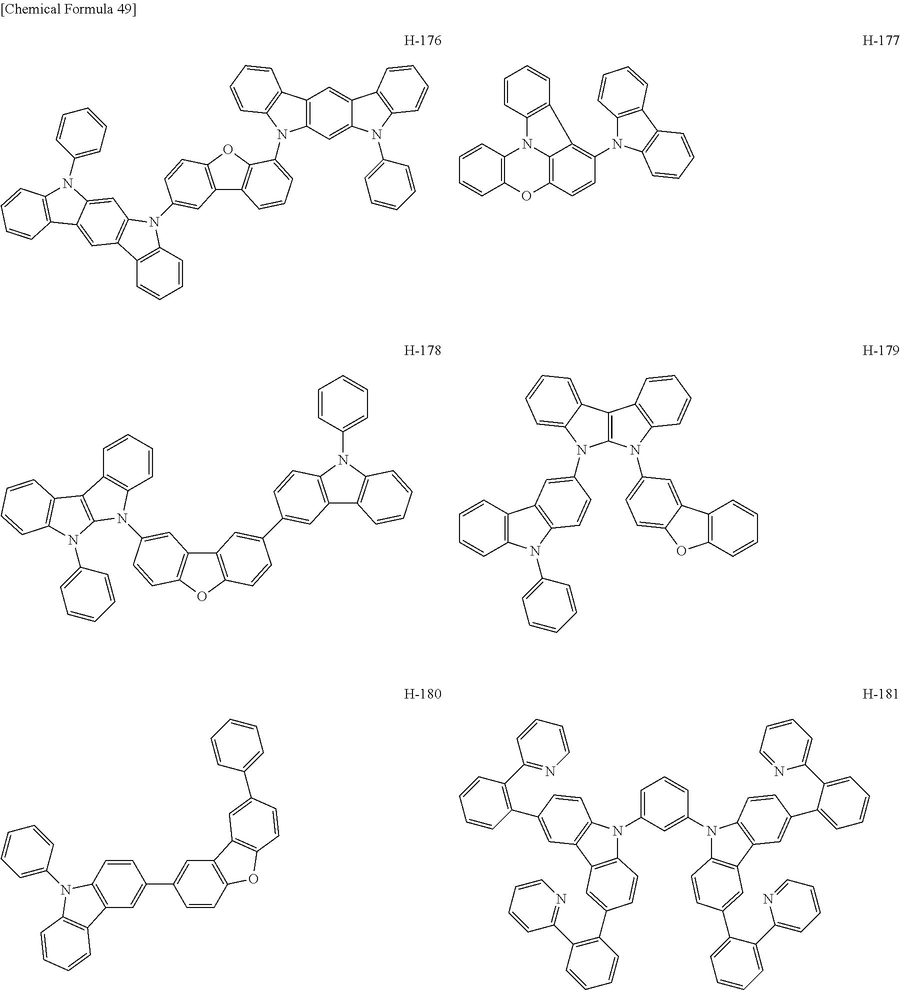

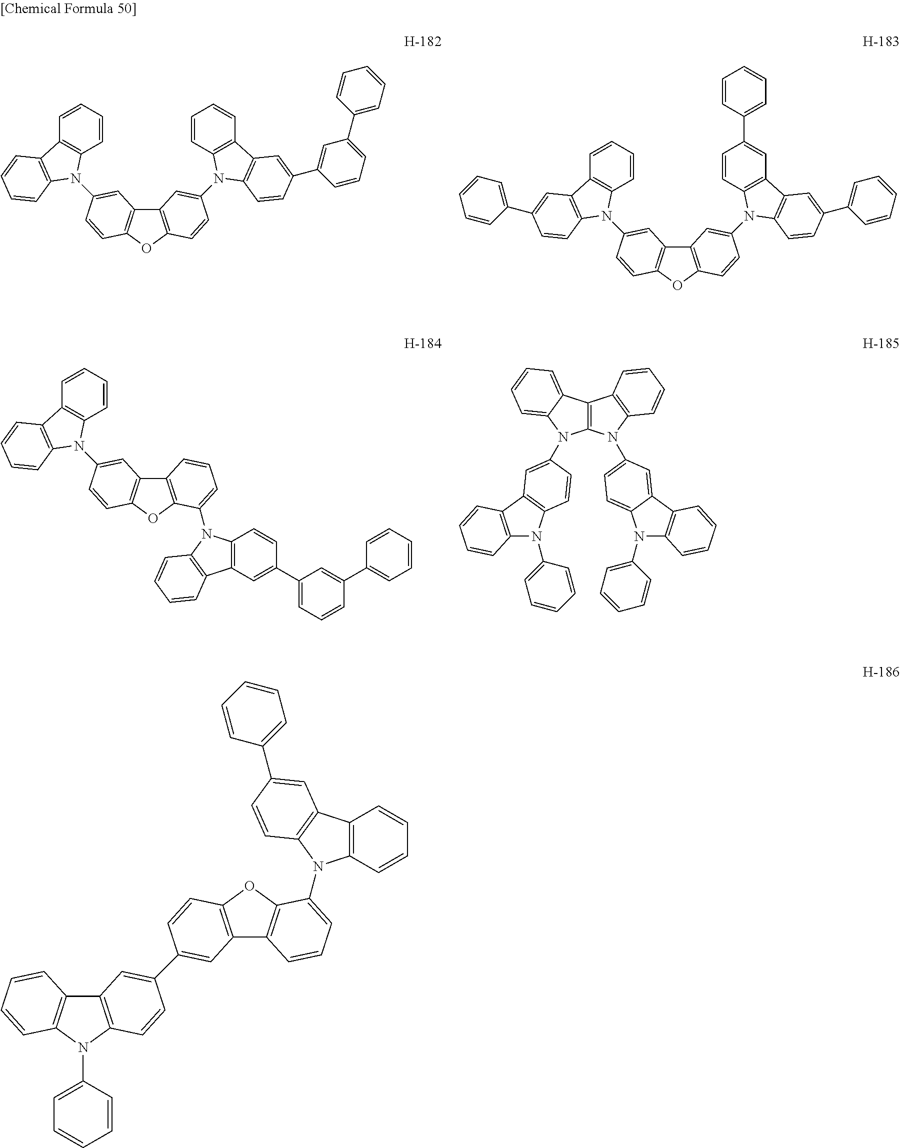 [SMILES: c1ccc(-c2cccc(-c3ccc4c(c3)c3ccccc3n4-c3ccc4oc5ccc(-n6c7ccccc7c7ccccc76)cc5c4c3)c2)cc1 ; c1ccc(-c2ccc3c(c2)c2ccccc2n3-c2ccc3oc4ccc(-n5c6ccc(-c7ccccc7)cc6c6cc(-c7ccccc7)ccc65)cc4c3c2)cc1 ; c1ccc(-c2cccc(-c3ccc4c(c3)c3ccccc3n4-c3cccc4c3oc3ccc(-n5c6ccccc6c6ccccc65)cc34)c2)cc1 ; c1ccc(-n2c3ccccc3c3cc(-n4c5ccccc5c5c6ccccc6n(-c6ccc7c(c6)c6ccccc6n7-c6ccccc6)c54)ccc32)cc1 ; c1ccc(-c2ccc3c(c2)c2ccccc2n3-c2cccc3c2oc2ccc(-c4ccc5c(c4)c4ccccc4n5-c4ccccc4)cc23)cc1]

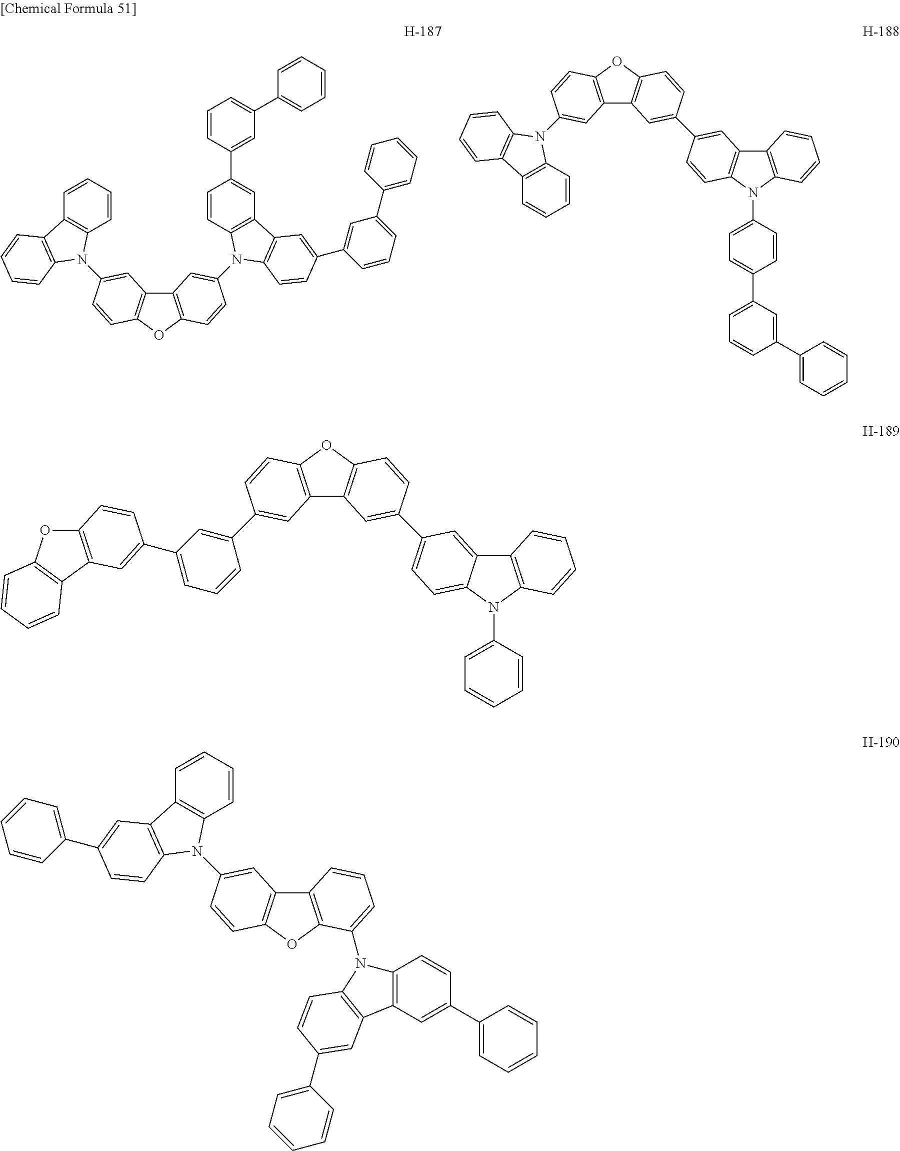 [SMILES: c1ccc(-c2cccc(-c3ccc4c(c3)c3cc(-c5cccc(-c6ccccc6)c5)ccc3n4-c3ccc4oc5ccc(-n6c7ccccc7c7ccccc76)cc5c4c3)c2)cc1 ; c1ccc(-c2cccc(-c3ccc(-n4c5ccccc5c5cc(-c6ccc7oc8ccc(-n9c%10ccccc%10c%10ccccc%109)cc8c7c6)ccc54)cc3)c2)cc1 ; c1ccc(-n2c3ccccc3c3cc(-c4ccc5oc6ccc(-c7cccc(-c8ccc9oc%10ccccc%10c9c8)c7)cc6c5c4)ccc32)cc1 ; c1ccc(-c2ccc3c(c2)c2ccccc2n3-c2ccc3oc4c(-n5c6ccc(-c7ccccc7)cc6c6cc(-c7ccccc7)ccc65)cccc4c3c2)cc1]

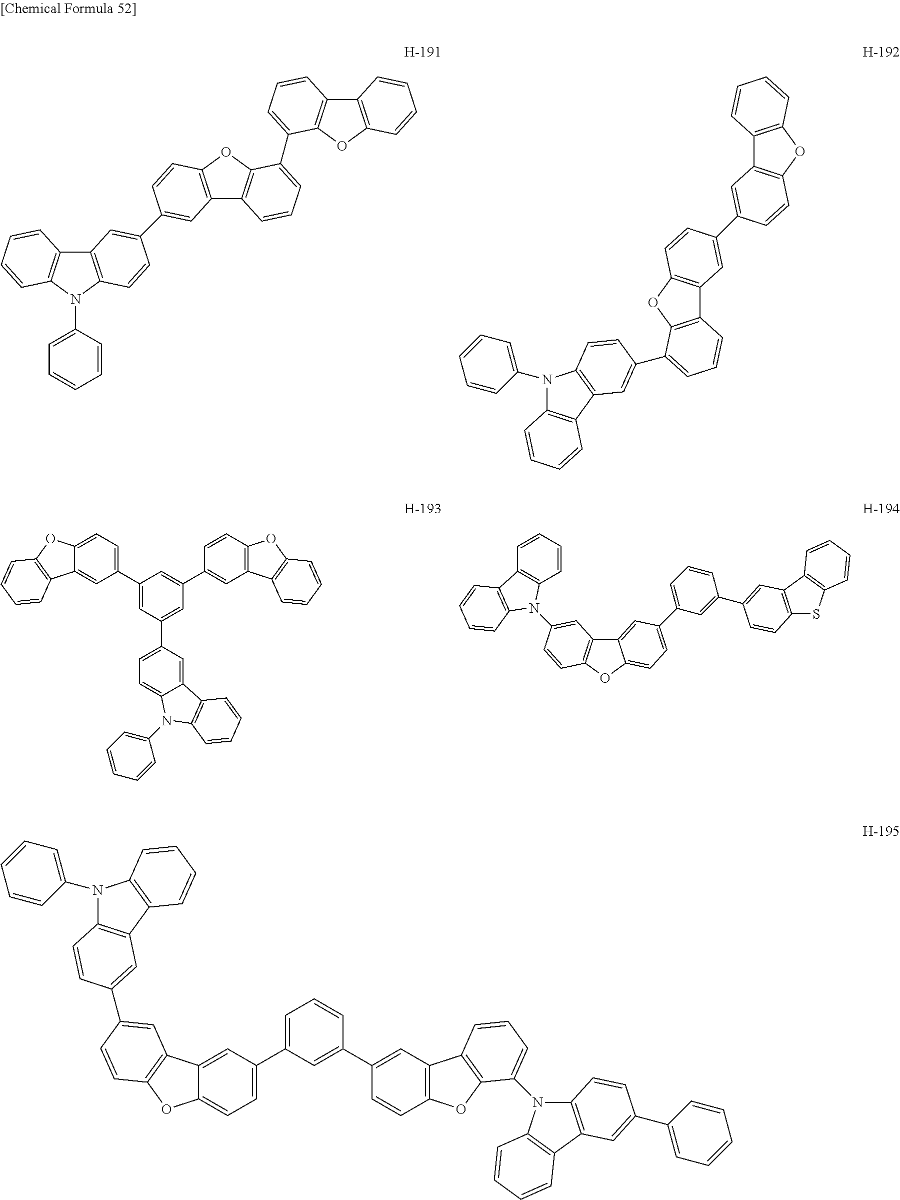 [SMILES: c1ccc(-n2c3ccccc3c3cc(-c4ccc5oc6c(-c7cccc8c7oc7ccccc78)cccc6c5c4)ccc32)cc1 ; c1ccc(-n2c3ccccc3c3cc(-c4cccc5c4oc4ccc(-c6ccc7oc8ccccc8c7c6)cc45)ccc32)cc1 ; c1ccc(-n2c3ccccc3c3cc(-c4cc(-c5ccc6oc7ccccc7c6c5)cc(-c5ccc6oc7ccccc7c6c5)c4)ccc32)cc1 ; c1cc(-c2ccc3oc4ccc(-n5c6ccccc6c6ccccc65)cc4c3c2)cc(-c2ccc3sc4ccccc4c3c2)c1 ; c1ccc(-c2ccc3c(c2)c2ccccc2n3-c2cccc3c2oc2ccc(-c4cccc(-c5ccc6oc7ccc(-c8ccc9c(c8)c8ccccc8n9-c8ccccc8)cc7c6c5)c4)cc23)cc1]

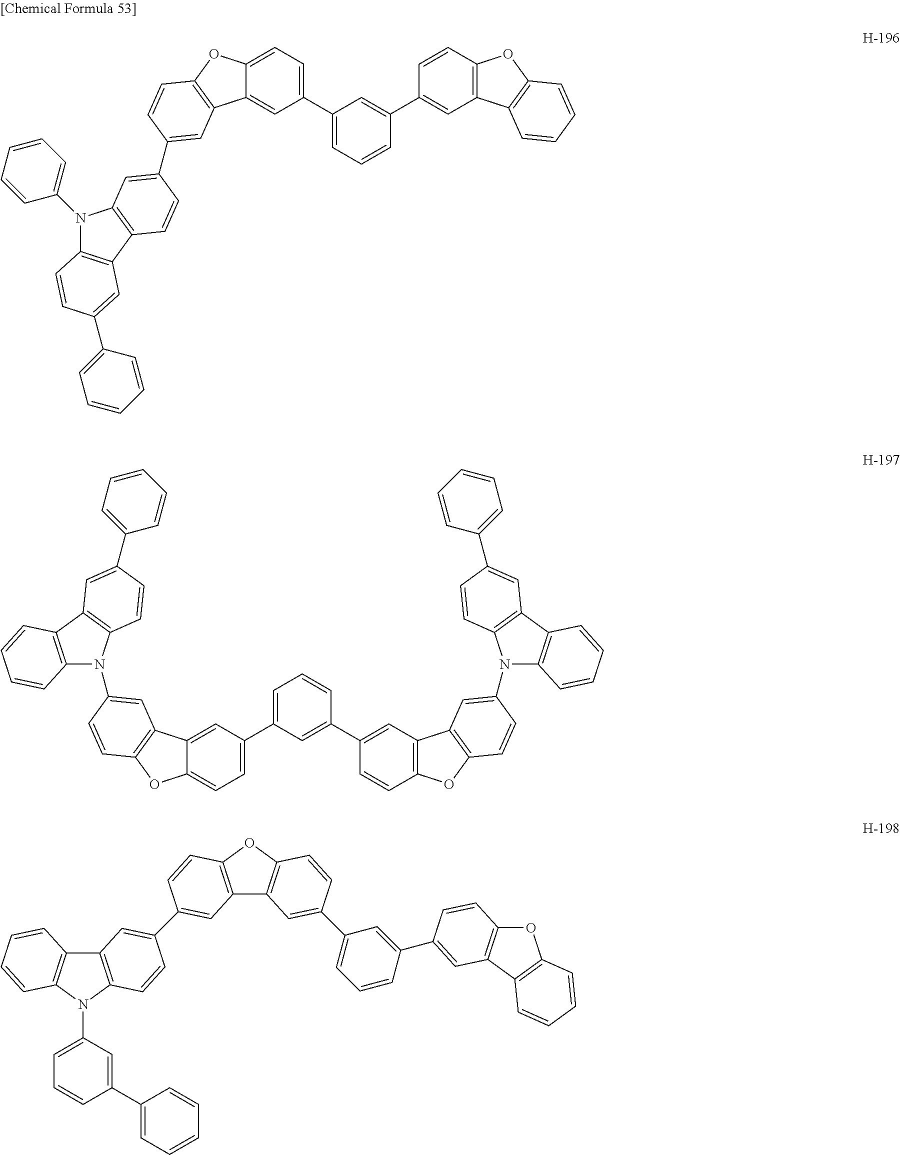 [SMILES: c1ccc(-c2ccc3c(c2)c2ccc(-c4ccc5oc6ccc(-c7cccc(-c8ccc9oc%10ccccc%10c9c8)c7)cc6c5c4)cc2n3-c2ccccc2)cc1 ; c1ccc(-c2ccc3c(c2)c2ccccc2n3-c2ccc3oc4ccc(-c5cccc(-c6ccc7oc8ccc(-n9c%10ccccc%10c%10cc(-c%11ccccc%11)ccc%109)cc8c7c6)c5)cc4c3c2)cc1 ; c1ccc(-c2cccc(-n3c4ccccc4c4cc(-c5ccc6oc7ccc(-c8cccc(-c9ccc%10oc%11ccccc%11c%10c9)c8)cc7c6c5)ccc43)c2)cc1]

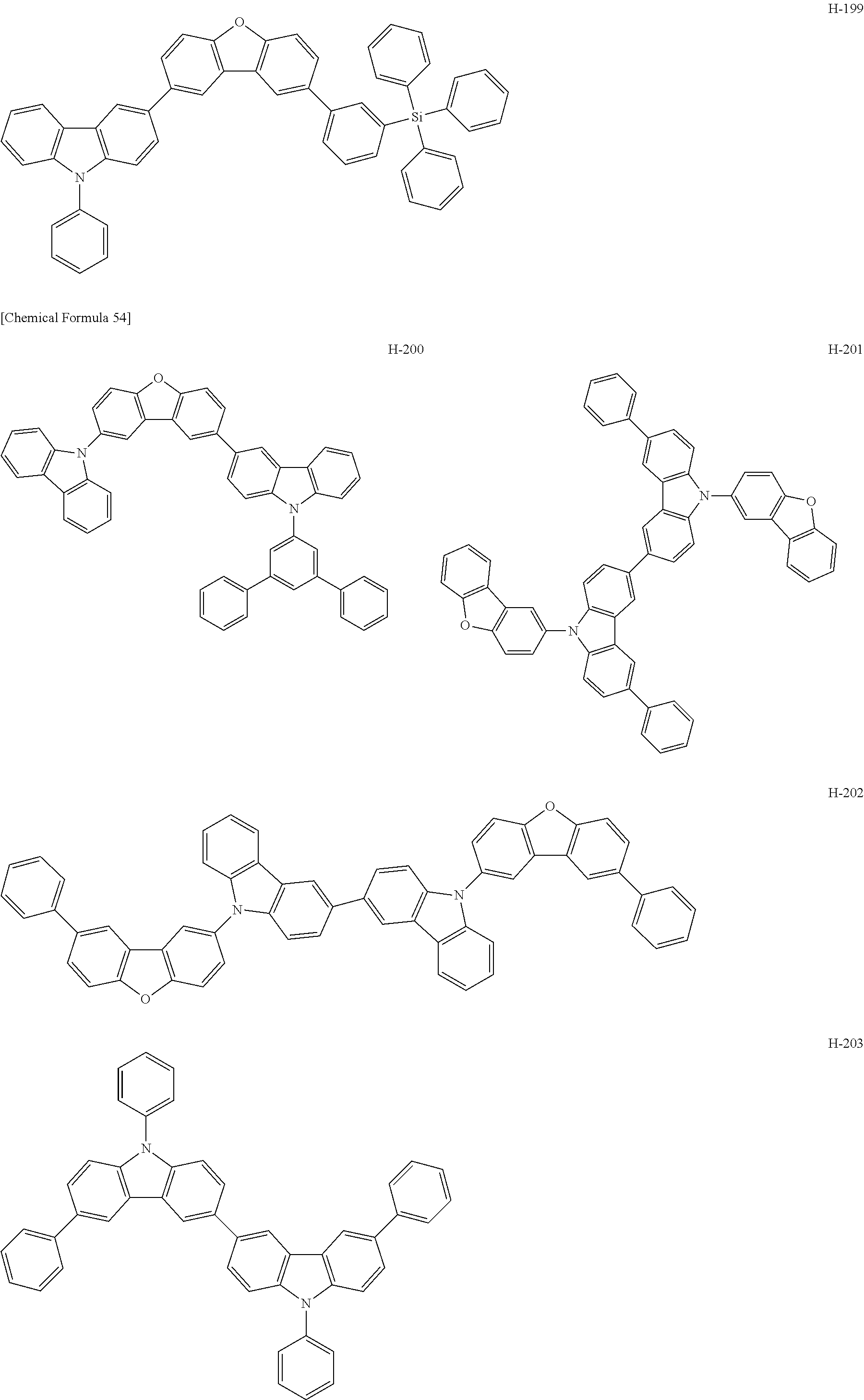

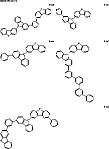

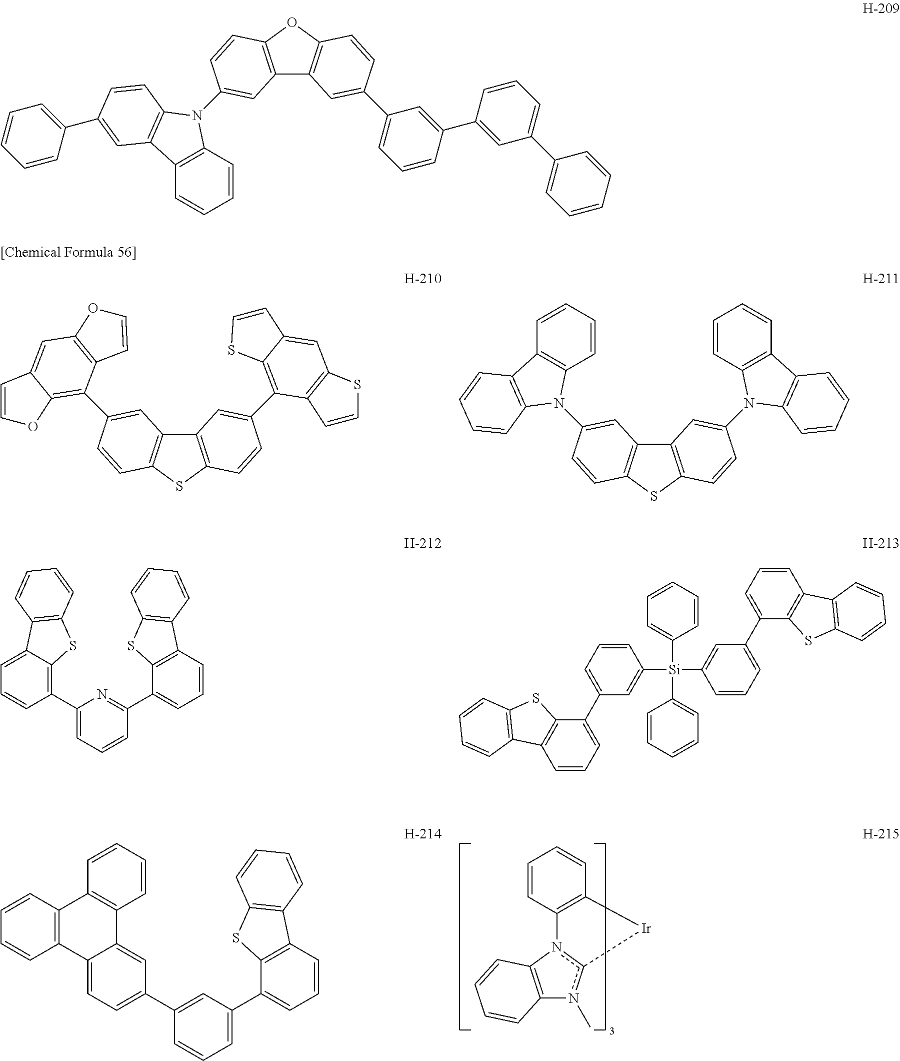

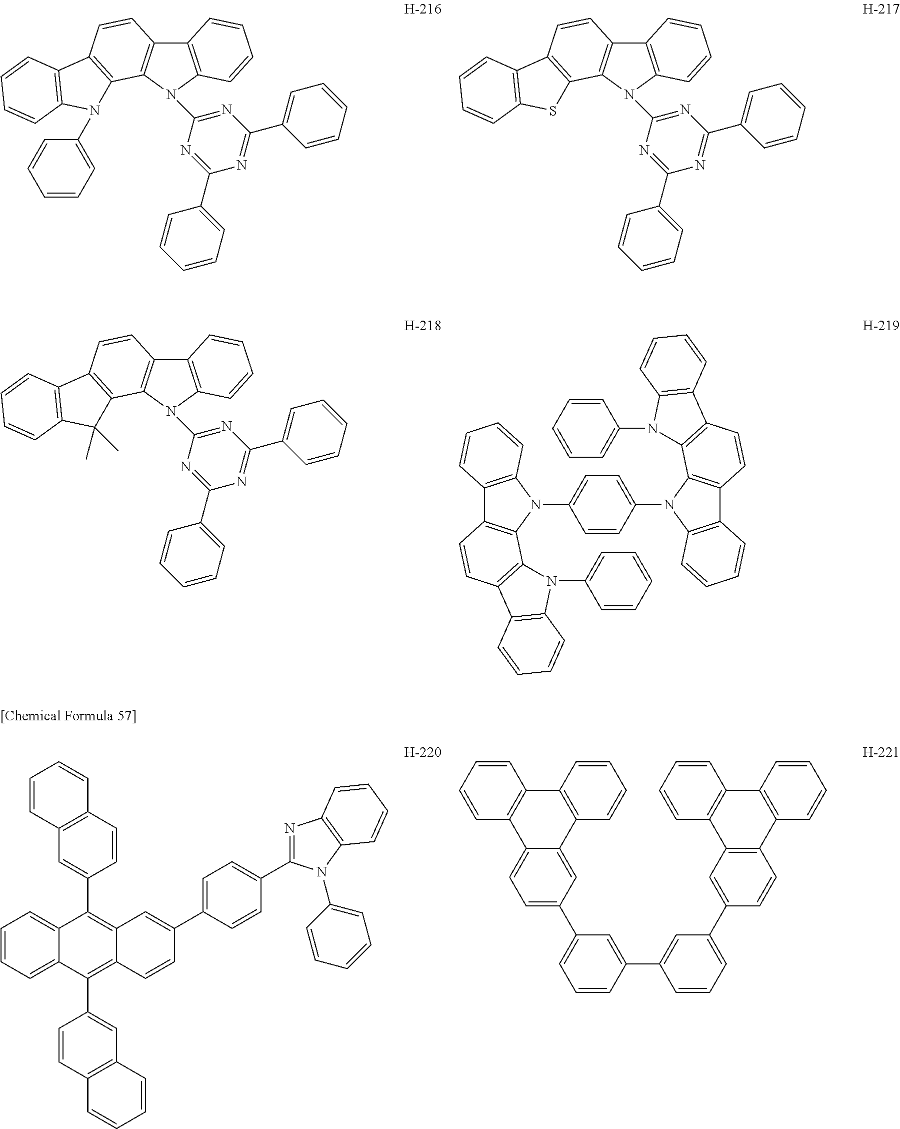

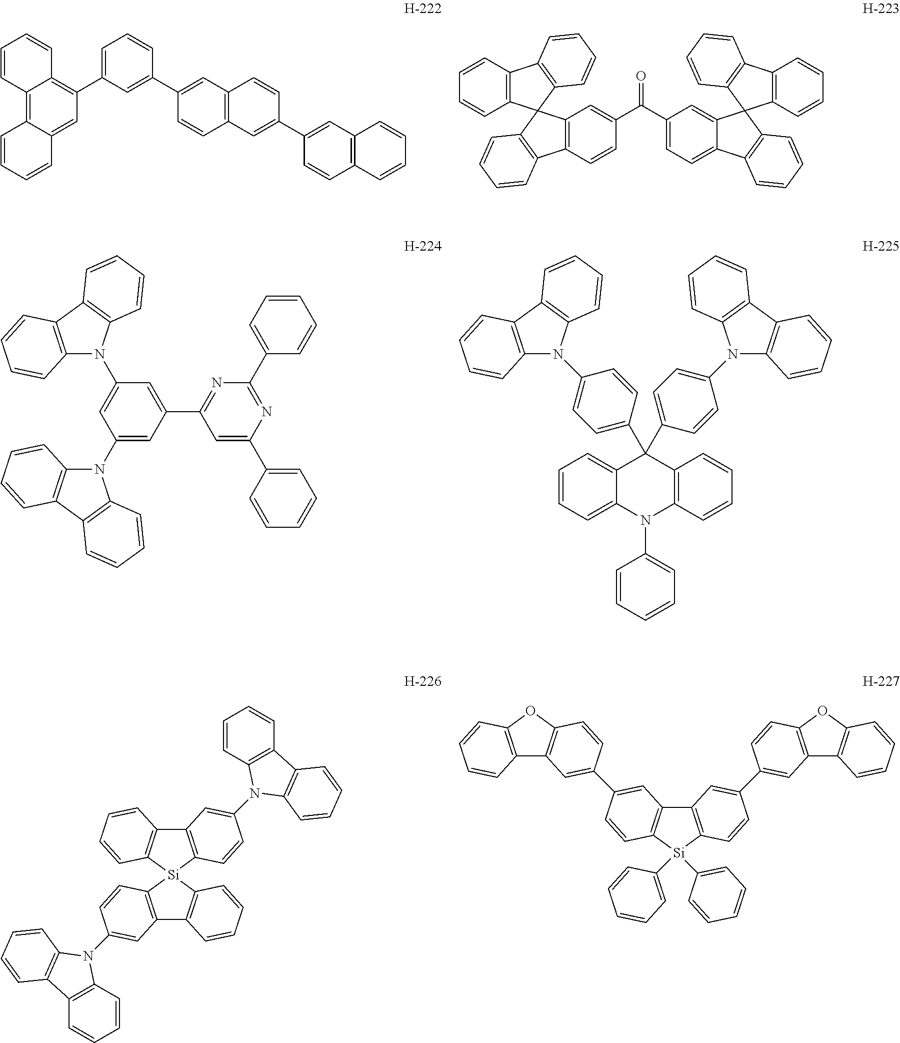

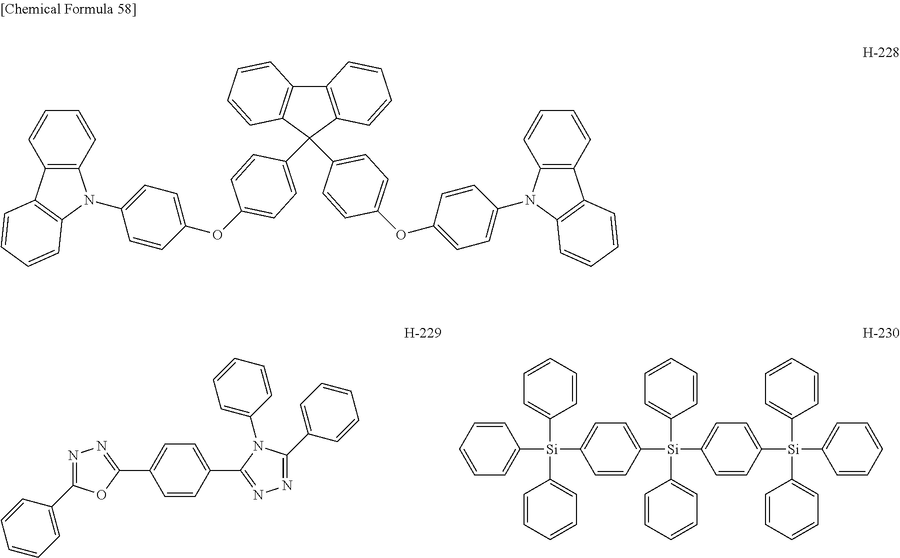 [SMILES: c1ccc2c(c1)-c1ccccc1C2(c1ccc(Oc2ccc(-n3c4ccccc4c4ccccc43)cc2)cc1)c1ccc(Oc2ccc(-n3c4ccccc4c4ccccc43)cc2)cc1 ; c1ccc(-c2nnc(-c3ccc(-c4nnc(-c5ccccc5)n4-c4ccccc4)cc3)o2)cc1 ; c1ccc([Si](c2ccccc2)(c2ccccc2)c2ccc([Si](c3ccccc3)(c3ccccc3)c3ccc([Si](c4ccccc4)(c4ccccc4)c4ccccc4)cc3)cc2)cc1]

The preferred host compound used in the present invention may be a compound having a low molecular weight that can be purified by sublimation, or may be a polymer having repeating units.

The compound of low molecular weight has an advantage in that it can be readily purified by sublimation into a high-purity material. The compound may have any molecular weight capable of purification by sublimation. The molecular weight is preferably 3,000 or less, more preferably 2,000 or less.

The polymer or oligomer having repeating units has an advantage in that it is readily formed into a film by a wet process. The polymer, which has high Tg in general, is preferred in view of thermal resistance. The host compound used in the present invention may be any polymer that can impart desired properties to the organic EL element, and is preferably a polymer having any of the structures represented by Formulae (I), (II), and (III-1) to (III-3) in the main chain or side chains. The polymer may have any molecular weight. The polymer preferably has a molecular weight of 5,000 or more or 10 or more repeating units.

The host compound preferably has a high glass transition temperature (Tg) in view of hole or electron transportability, prevention of an increase in emission wavelength, and stable operation of the organic EL element at high temperature. The glass transition temperature (Tg) is preferably 90° C. or higher, more preferably 120° C. or higher.

The glass transition point (Tg) is determined by differential scanning calorimetry (DSC) in accordance with JIS K 7121-2012.

<<Electron Transporting Layer>>

The electron transporting layer according to the present invention, which is composed of a material having electron transportability, only needs to have a function of transferring electrons injected from the cathode to the luminous layer.

The electron transporting layer may have any thickness. The electron transporting layer typically has a thickness of 2 nm to 5 μm, more preferably 2 to 500 nm, still more preferably 5 to 200 nm.

During the extracting process of light emitted from the luminous layer through an electrode in the organic EL element, light extracted directly from the luminous layer interferes with light reflected by the counter electrode. On light reflected by the cathode, the thickness of the electron transporting layer can be appropriately adjusted to several nanometers nm to several micrometers, to effectively utilize this interference phenomenon.

An increase in thickness of the electron transporting layer often causes an increase in voltage. Thus, an electron transporting layer having a large thickness preferably has an electron mobility of 10⁻⁵ cm²/Vs or more.

The material used for the electron transporting layer (hereinafter referred to as “electron transporting material”) may be any of traditional compounds capable of injecting or transporting electrons or blocking holes.

Examples of the electron transporting material include nitrogen-containing aromatic heterocyclic derivatives (e.g., carbazole derivatives, azacarbazole derivatives (wherein at least one of the carbon atoms forming the carbazole ring is replaced with a nitrogen atom), pyridine derivatives, pyrimidine derivatives, pyrazine derivatives, pyridazine derivatives, triazine derivatives, quinolone derivatives, quinoxaline derivatives, phenanthroline derivatives, azatriphenylene derivatives, oxazole derivatives, thiazole derivatives, oxadiazole derivatives, thiadiazole derivatives, triazole derivatives, benzimidazole derivatives, benzoxazole derivatives, and benzothiazole derivatives), dibenzofuran derivatives, dibenzothiophene derivatives, silole derivatives, and aromatic hydrocarbon derivatives (e.g., naphthalene derivatives, anthracene derivatives, and triphenylene derivatives).

The electron transporting material may be a metal complex having a quinolinol or dibenzoquinolinol skeleton as a ligand. Examples of the metal complex include tris(8-quinolinol) aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, bis(8-quinolinol)zinc (Znq), and metal complexes where the central metal of any of these complexes is replaced with In, Mg, Cu, Ca, Sn, Ga or Pb.

The electron transporting material may also be a metal phthalocyanine, a metal-free phthalocyanine, or a metal or metal-free phthalocyanine having an end substituted by an alkyl group or a sulfonate group. The electron transporting material may also be a distyrylpyrazine derivative, which has been exemplified above as a material for the luminous layer, or may be an inorganic semiconductor material (e.g., n-type Si or n-type SiC) as in the hole injecting layer or the hole transporting layer.

The electron transporting material may be a polymer material prepared by incorporation of any of these materials into a polymer chain, or a polymer material having a main chain composed of any of these materials.

The electron transporting layer used in the present invention may be a highly negative (electron-rich) electron transporting layer doped with a dopant or a guest. Examples of the dopant include n-type dopants, such as metal compounds (e.g., metal complexes and metal halides). Examples of the electron transporting layer having the aforementioned configuration include those disclosed in Japanese Unexamined Patent Application Publication Nos. H4-297076, H10-270172, 2000-196140, and 2001-102175, and J. Appl. Phys., 95, 5773 (2004).

Examples of known electron transporting materials preferably used in the organic EL element of the present invention include, but are not limited to, compounds described in U.S. Pat. Nos. 6,528,187 and 7,230,107, U.S. Patent Application Publication Nos. 2005/0025993, 2004/0036077, 2009/0115316, 2009/0101870, and 2009/0179554, International Patent Publication WO2003/060956 and WO2008/132085, Appl. Phys. Lett., 75, 4 (1999), Appl. Phys. Lett., 79, 449 (2001), Appl. Phys. Lett., 81, 162 (2002), Appl. Phys. Lett., 81, 162 (2002), Appl. Phys. Lett., 79, 156 (2001), U.S. Pat. No. 7,964,293, U.S. Patent Application Publication No. 2009/030202, International Patent Publication WO2004/080975, WO2004/063159, WO2005/085387, WO2006/067931, WO2007/086552, WO2008/114690, WO2009/069442, WO2009/066779, WO2009/054253, WO2011/086935, WO2010/150593, and WO2010/047707, EP 2311826, Japanese Unexamined Patent Application Publication Nos. 2010-251675, 2009-209133, 2009-124114, 2008-277810, 2006-156445, 2005-340122, 2003-45662, 2003-31367, and 2003-282270, and International Patent Publication WO2012/115034.

Examples of more preferred electron transporting materials in the present invention include aromatic heterocyclic compounds containing at least one nitrogen atom, such as pyridine derivatives, pyrimidine derivatives, pyrazine derivatives, triazine derivatives, dibenzofuran derivatives, dibenzothiophene derivatives, azadibenzofuran derivatives, azadibenzothiophene derivatives, carbazole derivatives, azacarbazole derivatives, and benzimidazole derivatives.

These electron transporting materials may be used alone or in combination.

<<Hole Blocking Layer>>

The hole blocking layer functions as an electron transporting layer in a broad sense and is preferably composed of a material that transports electrons and has a low capability of transporting holes. The hole blocking layer transports electrons and blocks holes, thereby increasing the probability of recombination of electrons and holes.

The aforementioned electron transporting layer may optionally be used as the hole blocking layer according to the present invention.

In the organic EL element of the present invention, the hole blocking layer is preferably disposed on the surface of the luminous layer adjacent to the cathode.

The hole blocking layer used in the present invention has a thickness of preferably 3 to 100 nm, more preferably 5 to 30 nm.

The hole blocking layer is preferably composed of a material used for the aforementioned electron transporting layer, and is also preferably composed of any of the aforementioned host compounds.

<<Electron Injecting Layer>>

The electron injecting layer used in the present invention (also referred to as “cathode buffer layer”) is provided between the cathode and the luminous layer for a reduction in driving voltage and an increase in luminance. The electron injecting layer is detailed in Chapter 2 “Denkyoku Zairyo (Electrode Material)” (pp. 123-166) of Part 2 of “Yuuki EL Soshi to Sono Kogyoka Saizensen (Organic EL Devices and Their Advanced Industrialization) (published by NTS Corporation, Nov. 30, 1998).”

In the present invention, the electron injecting layer is optionally provided. The electron injecting layer may be disposed between the cathode and the luminous layer as described above, or between the cathode and the electron transporting layer.

The electron injecting layer is preferably composed of a very thin film, and has a thickness of preferably 0.1 to 5 nm, which may vary depending on the raw material used. The electron injecting layer may be composed of a non-uniform film containing a discontinuously distributed material.

The electron injecting layer is also detailed in Japanese Unexamined Patent Application Publication Nos. H6-325871, H9-17574, and H10-74586. Examples of materials preferably used for the electron injecting layer include metals, such as strontium and aluminum; alkali metal compounds, such as lithium fluoride, sodium fluoride, and potassium fluoride; alkaline earth metal compounds, such as magnesium fluoride and calcium fluoride; metal oxides, such as aluminum oxide; and metal complexes, such as lithium 8-hydroxyquinolinate (Liq). The aforementioned electron transporting materials may also be used.

These materials for the electron injecting layer may be used alone or in combination.

<<Hole Transporting Layer>>

The hole transporting layer according to the present invention, which is composed of a material having hole transportability, only needs to have a function of transferring holes injected from the anode to the luminous layer.

The hole transporting layer may have any thickness. The electron transporting layer has a thickness of generally 5 nm to 5 μm, more preferably 2 to 500 nm, still more preferably 5 to 200 nm.

The material used for the hole transporting layer (hereinafter referred to as “hole transporting material”) may be any of traditional compounds capable of injecting or transporting holes or blocking electrons.

Examples of the hole transporting material include porphyrin derivatives, phthalocyanine derivatives, oxazole derivatives, oxadiazole derivatives, triazole derivatives, imidazole derivatives, pyrazoline derivatives, pyrazolone derivatives, phenylenediamine derivatives, hydrazone derivatives, stilbene derivatives, polyarylalkane derivatives, triarylamine derivatives, carbazole derivatives, indolocarbazole derivatives, isoindole derivatives, acene derivatives (e.g., anthracene and naphthalene), fluorene derivatives, fluorenone derivatives, poly(vinylcarbazole), polymer materials and oligomers having an aromatic amine in the main chain or side chain, polysilanes, and conductive polymers and oligomers (e.g., PEDOT/PSS, aniline copolymers, polyaniline, and polythiophene).

Examples of the triarylamine derivatives include benzidine derivatives, such as α-NPD, starburst amine derivatives, such as MTDATA, and compounds having fluorene or anthracene on the bonding cores of triarylamines.

The hole transporting material may also be hexaazatriphenylene derivatives described in Japanese Translation of PCT International Application Publication No. 2003-519432 and Japanese Unexamined Patent Application Publication No. 2006-135145.

The hole transporting layer may be a highly positive hole transporting layer doped with an impurity. Examples of such an electron transporting layer include those described in Japanese Unexamined Patent Application Publication Nos. H4-297076, 2000-196140, and 2001-102175, and J. Appl. Phys., 95, 5773 (2004).

The hole transporting material may be a p-type hole transporting material or an inorganic compound (e.g., p-type Si or p-type SiC) described in Japanese Unexamined Patent Application Publication No. H11-251067 and J. Huang, et al., Applied Physics Letters 80 (2002), p. 139. The hole transporting material is preferably an ortho-metalated organometallic complex having Ir or Pt as a central metal, such as Ir(ppy)₃.

Among the aforementioned hole transporting materials, preferred are triarylamine derivatives, carbazole derivatives, indolocarbazole derivatives, azatriphenylene derivatives, organometallic complexes, and polymer materials and oligomers having an aromatic amine in the main chain or side chain.

Examples of known hole transporting materials preferably used in the organic EL element of the present invention include, but are not limited to, compounds described in the aforementioned publications and described in Appl. Phys. Lett., 69, 2160 (1996), J. Lumin., 72-74, 985 (1997), Appl. Phys. Lett., 78, 673 (2001), Appl. Phys. Lett., 90, 183503 (2007), Appl. Phys. Lett., 90, 183503 (2007), Appl. Phys. Lett., 51, 913 (1987), Synth. Met., 87, 171 (1997), Synth. Met., 91, 209 (1997), Synth. Met., 111, 421 (2000), SID Symposium Digest, 37, 923 (2006), J. Mater. Chem., 3, 319 (1993), Adv. Mater., 6, 677 (1994), Chem. Mater., 15, 3148 (2003), U.S. Patent Application Publication Nos. 2003/0162053, 2002/0158242, 2006/0240279, and 2008/0220265, U.S. Pat. No. 5,061,569, International Patent Publication WO2007/002683 and WO2009/018009, EP No. 650955, U.S. Patent Application Publication Nos. 2008/0124572, 2007/0278938, 2008/0106190, and 2008/0018221, International Patent Publication WO2012/115034, Japanese Translation of PCT International Application Publication No. 2003-519432, Japanese Unexamined Patent Application Publication No. 2006-135145, and U.S. patent application Ser. No. 13/585,981.

These hole transporting materials may be used alone or in combination.

<<Electron Blocking Layer>>

The electron blocking layer functions as a hole transporting layer in a broad sense and is preferably composed of a material that transports holes and has a low capability of transporting electrons. The electron blocking layer transports holes and blocks electros, thereby increasing the probability of recombination of electrons and holes.

The aforementioned hole transporting layer may optionally be used as the electron blocking layer in the present invention.

In the organic EL element of the present invention, the electron blocking layer is preferably disposed on the surface of the luminous layer adjacent to the anode.

The electron blocking layer used in the present invention has a thickness of preferably 3 to 100 nm, more preferably 5 to 30 nm.

The electron blocking layer is preferably composed of a material used for the aforementioned hole transporting layer, and is also preferably composed of any of the aforementioned host compounds.

<<Hole Injecting Layer>>

The hole injecting layer used in the present invention (also referred to as “anode buffer layer”) is provided between the anode and the luminous layer for a reduction in driving voltage and an increase in luminance. The hole injecting layer is detailed in Chapter 2 “Denkyoku Zairyo (Electrode Material)” (pp. 123-166) of Part 2 of “Yuuki EL Soshi to Sono Kogyoka Saizensen (Organic EL Devices and Their Advanced Industrialization) (published by NTS Corporation, Nov. 30, 1998).”

In the present invention, the hole injecting layer is optionally provided. The hole injecting layer may be disposed between the anode and the luminous layer as described above, or between the anode and the hole transporting layer.

The hole injecting layer is also detailed in Japanese Unexamined Patent Application Publication Nos. H9-45479, H9-260062, and H8-288069. Examples of the material for the hole injecting layer include those used for the aforementioned hole transporting layer.

Examples of particularly preferred materials include phthalocyanine derivatives, such as copper phthalocyanine; hexaazatriphenylene derivatives disclosed in Japanese Translation of PCT International Application Publication No. 2003-519432 and Japanese Unexamined Patent Application Publication No. 2006-135145; metal oxides, such as vanadium oxide; amorphous carbon; conductive polymers, such as polyaniline (emeraldine) and polythiophene; ortho-metalated complexes, such as a tris(2-phenylpyridine)iridium complex; and triarylamine derivatives.

These materials for the hole injecting layer may be used alone or in combination.

<<Other Additives>>

Each of the aforementioned organic layers according to the present invention may contain any other additive.

Examples of the additive include halogens, such as bromine, iodine, and chlorine; halides; and compounds, complexes, and salts of alkali metals, alkaline earth metals, and transition metals, such as Pd, Ca, and Na.

The additive content of the organic layer may be appropriately determined. The additive content is preferably 1,000 ppm or less, more preferably 500 ppm or less, still more preferably 50 ppm or less, relative to the entire mass of the layer containing the additive.

The additive content may fall outside of this range for improvement of electron or hole transportability or effective energy transfer of excitons.

<<Formation of Organic Layer>>

Now will be described a process of forming the organic layers (hole injecting layer, hole transporting layer, luminous layer, hole blocking layer, electron transporting layer, and electron injecting layer) according to the present invention.

The organic layer according to the present invention can be formed by any known process, such as a vacuum vapor deposition process or a wet process.

Examples of the wet process include spin coating, casting, ink jetting, printing, dye coating, blade coating, roll coating, spray coating, curtain coating, and the Langmuir-Blodgett (LB) method. Preferred are processes highly suitable for a roll-to-roll system, such as die coating, roll coating, ink jetting, and spray coating, in view of easy formation of a thin homogeneous film and high productivity.

Examples of the liquid medium for dissolution or dispersion of the organic EL materials used in the present invention include ketones, such as methyl ethyl ketone and cyclohexanone; fatty acid esters, such as ethyl acetate; halogenated hydrocarbons, such as dichlorobenzene; aromatic hydrocarbons, such as toluene, xylene, mesitylene, and cyclohexylbenzene; aliphatic hydrocarbons, such as cyclohexane, decalin, and dodecane; and organic solvents, such as DMF and DMSO.

Examples of the usable dispersion technique include ultrasonic dispersion, high shearing force dispersion, and media dispersion.

Individual layers may be formed through different processes. Conditions of a vapor evaporation process for formation of a layer may vary depending on the type of a compound used. In general, the process is performed under the following conditions: a boat heating temperature of 50 to 450° C., a vacuum of 10⁻⁶ to 10⁻² Pa, a deposition rate of 0.01 to 50 nm/second, a substrate temperature of −50 to 300° C., and a layer (film) thickness of 0.1 nm to 5 μm (preferably 5 to 200 nm).

The organic EL element of the present invention is preferably produced by forming the aforementioned organic layers (including the hole injecting layer and the cathode) through a single vacuuming process. The vacuuming process may be intermitted, and then the layers may be formed by a deposition process other than the vacuuming process. In such a case, the process is preferably performed in a dry inert gas atmosphere.

<<Anode>>

The anode of the organic EL element is preferably composed of an electrode material having a high work function (4 eV or more, preferably 4.5 eV or more), such as a metal, an alloy, a conductive compound, or a mixture thereof. Examples of the electrode material include metals, such as Au, and transparent conductive materials, such as CuI, indium thin oxide (ITO), SnO₂, and ZnO. An amorphous material capable of forming a transparent conductive film, such as IDIXO (In₂O₃—ZnO), may also be used.

The anode can be prepared through formation of a thin film from any of the aforementioned electrode materials by vapor deposition or sputtering, followed by patterning through photolithography, to form a desired pattern. If high patterning accuracy is not required (i.e., an accuracy of about 100 μm or more), a pattern may be formed with a mask having a desired shape during deposition or sputtering of the aforementioned electrode material.

In use of an applicable substance (e.g., an organic conductive compound), the anode may be prepared by a wet process, such as printing or coating. For extraction of emitted light through the anode, the transmittance of the anode is preferably 10% or more, and the sheet resistance of the anode is preferably several hundred ohms/square or less.

The anode has a thickness of typically 10 nm to 1 μm, preferably 10 to 200 nm, which may vary depending on the material used.

<<Cathode>>

The cathode is composed of an electrode material having a low work function (4 eV or less), such as a metal (referred to as “electron-injecting metal”), an alloy, a conductive compound, or a mixture thereof. Examples of the electrode material include sodium, sodium-potassium alloys, magnesium, lithium, magnesium-copper mixtures, magnesium-silver mixtures, magnesium-aluminum mixtures, magnesium-indium mixtures, aluminum-aluminum oxide (Al₂O₃) mixtures, indium, lithium-aluminum mixtures, aluminum, and rare earth metals. Among these materials, preferred is a mixture of an electron-injecting metal and a second metal that is stable and has a work function higher than that of the electron-injecting material, in view of electron injecting ability and resistance against oxidation, for example. Examples of the mixture include magnesium-silver mixtures, magnesium-aluminum mixtures, magnesium-indium mixtures, aluminum-aluminum oxide (Al₂O₃) mixtures, lithium-aluminum mixtures, and aluminum.

The cathode can be prepared through formation of a thin film from any of the aforementioned electrode materials by vapor deposition or sputtering. The cathode has a sheet resistance of preferably several hundred ohms/square or less, and has a thickness of typically 10 nm to 5 μm, preferably 50 to 200 nm.

From the viewpoint of transmission of emitted light, the anode or cathode of the organic EL element is preferably transparent or translucent for an increase in luminance.

The cathode can be provided with transparency or translucency by formation of a film having a thickness of 1 to 20 nm on the cathode from any of the aforementioned metals, followed by coating of the film with any of the transparent conductive materials used for the anode. The application of this process can produce an organic El element including a transparent anode and a transparent cathode.

[Supporting Substrate]

The supporting substrate used for the organic EL element of the present invention (hereinafter also referred to as “substrate,” “base,” or “support”) may be composed of any glass or plastic material, and may be transparent or opaque. In extraction of light through the supporting substrate, the supporting substrate should preferably be transparent. Examples of preferred transparent supporting substrates include glass films, quartz films, and transparent resin films. Particularly preferred is a resin film that can impart flexibility to the organic EL element.

Examples of the resin film include films of polyesters, such as poly(ethylene terephthalate) (PET) and poly(ethylene naphthalate) (PEN), polyethylene, polypropylene, cellophane, cellulose esters and their derivatives, such as cellulose diacetate, cellulose triacetate (TAC), cellulose acetate butyrate, cellulose acetate propionate (CAP), cellulose acetate phthalate, and cellulose nitrate, poly(vinylidene chloride), poly(vinyl alcohol), poly(ethylene-vinyl alcohol), syndiotactic polystyrene, polycarbonates, norbornene resins, polymethylpentene, polyetherketones, polyimides, polyethersulfones (PES), poly(phenylene sulfide), polysulfones, polyetherimides, polyetherketoneimides, polyamides, fluororesins, nylons, poly(methyl methacrylate), acrylic resins, polyarylates, and cycloolefin resins, such as ARTON (trade name, manufactured by JSR Corp.) and APEL (trade name, manufactured by Mitsui Chemicals Inc.).

The surface of the resin film may be provided with an inorganic or organic coating film or a hybrid coating film composed of both. The coating film is preferably a barrier film having a water vapor permeability (25±0.5° C., relative humidity (90±2)% RH) of 0.01 g/(m²·24 h) or less as determined in accordance with JIS K 7129-1992. The coating film is more preferably a high barrier film having an oxygen permeability of 1×10⁻³ mL/m²·24 h·atm or less as determined in accordance with JIS K 7126-1987 and a water vapor permeability of 1×10⁻⁵ g/m²·24 h or less.

The barrier film may be formed from any material capable of preventing intrusion of a substance that causes degradation of the organic EL element, such as moisture or oxygen. Examples of the material include silicon oxide, silicon dioxide, and silicon nitride. In view of enhancement of the strength, the barrier film preferably has a layered structure composed of an inorganic layer and an organic material layer. The inorganic layer and the organic layer may be disposed in any order. Preferably, a plurality of inorganic layers and organic layers are alternately disposed.

The barrier film may be formed by any known process. Examples of the process include vacuum vapor deposition, sputtering, reactive sputtering, molecular beam epitaxy, ionized-cluster beam deposition, ion plating, plasma polymerization, atmospheric pressure plasma polymerization, plasma CVD, laser CVD, thermal CVD, and coating. In particular, the barrier film is preferably formed through atmospheric pressure plasma polymerization as disclosed in Japanese Unexamined Patent Application Publication No. 2004-68143.

Examples of the opaque supporting substrate include metal plates and films composed of aluminum and stainless steel, opaque resin substrates, and ceramic substrates.

The organic EL element of the present invention has an external quantum efficiency at room temperature (25° C.) of preferably 1% or more, more preferably 5% or more.

The external quantum efficiency (%) is determined by the following expression:

external quantum efficiency (%)=(the number of photons emitted to the outside of the organic EL element/the number of electrons flowing through the organic EL element)×100.

The supporting substrate may be used in combination with a hue improving filter (e.g., a color filter). Alternatively, the supporting substrate may be used in combination with a color conversion filter that converts the color of light emitted from the organic EL element into multiple colors with a fluorescent material.

[Sealing]

Examples of the means for sealing of the organic EL element of the present invention include a process of bonding a sealing member to the electrode and the supporting substrate with an adhesive. The sealing member only needs to be disposed to cover a display area of the organic EL element. The sealing member may be in the form of concave plate or flat plate. The sealing member may have transparency or electrical insulating properties.

Examples of the sealing member include a glass plate, a composite of polymer plate and film, and a composite of metal plate and film. Examples of the glass plate include plates of soda-lime grass, glass containing barium and strontium, lead glass, aluminosilicate glass, borosilicate glass, barium borosilicate glass, and quartz. Examples of the polymer plate include plates of polycarbonate, acrylic resin, poly(ethylene terephthalate), poly(ether sulfide), and polysulfone. Examples of the metal plate include plates composed of one or more metals selected from the group consisting of stainless steel, iron, copper, aluminum, magnesium, nickel, zinc, chromium, titanium, molybdenum, silicon, germanium, and tantalum, and plates composed of alloys of these metals.

In the present invention, a polymer film or a metal film is preferably used for reducing the thickness of the organic EL element. The polymer film preferably has an oxygen permeability of 1×10⁻³ mL/m²·24 h or less as determined in accordance with JIS K 7126-1987 and a water vapor permeability (25±0.5° C., relative humidity of 90±2%) of 1×10⁻³ g/m²·24 h or less as determined in accordance with JIS K 7129-1992.

The sealing member may be formed into a concave plate by sandblasting or chemical etching.

Examples of the adhesive include photocurable and thermosetting adhesives containing reactive vinyl groups of acrylic acid oligomers and methacrylic acid oligomers, moisture-curable adhesives, such as 2-cyanoacrylate esters, and thermosetting and chemically curable adhesives (two-component adhesives), such as epoxy adhesives. Other examples include hot-melt polyamides, polyesters, and polyolefins, and cationic UV-curable epoxy resin adhesives.

In consideration that the organic EL element may be degraded through thermal treatment, an adhesive is preferably used which can be cured at a temperature of room temperature to 80° C. The adhesive may contain a desiccant dispersed therein. The adhesive may be applied to a sealing site with a commercially available dispenser or by screen printing.

An inorganic or organic layer (serving as a sealing film) is preferably formed on the electrode that sandwiches the organic layer with the supporting substrate so as to cover the electrode and the organic layer and to come into contact with the supporting substrate. The sealing film may be formed from any material capable of preventing intrusion of a substance that causes degradation of the organic EL element, such as moisture or oxygen. Examples of the material include silicon oxide, silicon dioxide, and silicon nitride.

In view of enhancement of the strength, the sealing film preferably has a layered structure composed of an inorganic layer and an organic material layer. The sealing film may be formed by any known process. Examples of the process include vacuum vapor deposition, sputtering, reactive sputtering, molecular beam epitaxy, ionized-cluster beam deposition, ion plating, plasma polymerization, atmospheric pressure plasma polymerization, plasma CVD, laser CVD, thermal CVD, and coating.

The gap between the sealing member and the display area of the organic EL element is preferably filled with an inert gas (e.g., nitrogen or argon) or an inert liquid (e.g., fluorohydrocarbon or silicone oil). The gap may be vacuum. Alternatively, the gap may be filled with a hygroscopic compound.

Examples of the hygroscopic compound include metal oxides (e.g., sodium oxide, potassium oxide, calcium oxide, barium oxide, magnesium oxide, and aluminum oxide), sulfates (e.g., sodium sulfate, calcium sulfate, magnesium sulfate, and cobalt sulfate), metal halides (e.g., calcium chloride, magnesium chloride, cesium fluoride, tantalum fluoride, cerium bromide, magnesium bromide, barium iodide, and magnesium iodide), and perchlorates (e.g., barium perchlorate and magnesium perchlorate). Preferred are anhydrous salts of sulfates, metal halides, and perchlorates.

[Protective Film, Protective Plate]

In order to increase the mechanical strength of the organic EL element, a protective film or plate may be provided on the outer surface of the sealing film that faces the supporting substrate with the organic layer being disposed therebetween. If the sealing film is used for sealing of the organic EL element, such a protective film or plate is preferably provided because the mechanical strength of the element is not necessarily high. Examples of the material for the protective film or plate include those used for the aforementioned sealing member, such as a glass plate, a composite of polymer plate and film, and a composite of metal plate and film. A polymer film is preferably used in view of a reduction in weight and thickness.

[Technique for Improvement of Light Extraction]

In a common organic EL element, light is emitted in the interior of a layer having a refractive index higher than that of air (i.e., a refractive index of about 1.6 to 2.1), and only about 15 to 20% of the light emitted in the layer is extracted to the outside. The reason for this is attributed to the following fact: light incident on an interface (interface between a transparent substrate and air) at an angle θ equal to or larger than the critical angle cannot be extracted from the element to the outside due to total reflection, or light is totally reflected at the interface between the transparent substrate and the transparent electrode or the luminous layer and is guided along the transparent electrode or the luminous layer, resulting in leakage of the light along the side face of the element.

Examples of the technique for improving the efficiency of light extraction include a technique for preventing total reflection at the interface between the transparent substrate and air by forming irregularities on the surface of the transparent substrate (refer to, for example, U.S. Pat. No. 4,774,435); a technique for improving the efficiency of light extraction by providing the substrate with light collecting properties (refer to, for example, Japanese Unexamined Patent Application Publication No. S63-314795); a technique for forming a reflective surface on the side faces of the element (refer to, for example, Japanese Unexamined Patent Application Publication No. H1-220394); a technique for providing an anti-reflective film by disposing a flat layer between the substrate and the luminous layer, the flat layer having a refractive index intermediate between those of the substrate and the luminous layer (refer to, for example, Japanese Unexamined Patent Application Publication No. S62-172691); a technique for disposing a flat layer between the substrate and the luminous layer, the flat layer having a refractive index lower than that of the substrate (refer to, for example, Japanese Unexamined Patent Application Publication No. 2001-202827); and a technique for providing a diffractive grating between any layers of the substrate, the transparent electrode layer, and the luminous layer (including the gap between the substrate and the outside of the element) (Japanese Unexamined Patent Application Publication No. H11-283751).

In the present invention, any of these techniques can be used for the organic EL element of the present invention. Preferred is a technique for disposing a flat layer between the substrate and the luminous layer, the flat layer having a refractive index lower than that of the substrate, or a technique for forming a diffractive grating between any layers of the substrate, the transparent electrode layer, and the luminous layer (including the gap between the substrate and the outside of the element).

The present invention can provide an organic EL element exhibiting higher luminance and superior durability by combination of the aforementioned techniques.

If a medium (layer) of low refractive index having a thickness larger than a light wavelength is provided between the transparent electrode and the transparent substrate, the efficiency of extraction of light from the transparent electrode to the outside increases with a decrease in refractive index of the medium.

The layer of low refractive index may be composed of, for example, aerogel, porous silica, magnesium fluoride, or a fluorine-containing polymer. The refractive index of the layer of low refractive index is preferably about 1.5 or less because the transparent substrate generally has a refractive index of about 1.5 to 1.7. The refractive index of the layer of low refractive index is more preferably 1.35 or less.

The medium of low refractive index preferably has a thickness twice or more the wavelength of light in the medium for the following reason. If the medium of low refractive index has a thickness nearly equal to the light wavelength, the electromagnetic wave exuding as an evanescent wave enters the substrate, leading to a reduction in the effects of the layer of low refractive index.

The technique for providing a diffractive grating at any interface where total reflection occurs or in any layer can highly improve the efficiency of light extraction. A diffractive grating directs light to a specific direction other than the refractive direction by Bragg diffraction (e.g., a primary diffraction or a secondary diffraction). This technique uses the diffractive grating disposed at any interface or in any layer (e.g., in the transparent substrate or the transparent electrode), and achieves extraction of a light component emitted from the luminous layer, which would otherwise fail to be extracted to the outside due to the total reflection, to the outside by diffraction with the diffractive grating.

The diffractive grating used preferably has a two-dimensional periodic refractive index profile, for the following reasons. Since light is emitted in any direction randomly in the luminous layer, a common one-dimensional diffractive grating having a periodic refractive index profile in a specific direction diffracts light only in the specific direction, resulting in a low effect of improving the efficiency of light extraction.

In contrast, the diffractive grating having a two-dimensional diffractive index profile can diffract light in any direction and thus highly improve the efficiency of light extraction.

The diffractive grating may be disposed at any interface or any layer (e.g., in the transparent substrate or the transparent electrode). Preferably, the diffractive grating is disposed adjacent to the organic luminous layer, which emits light. The pitch of the diffractive grating is preferably about a half to three times of the wavelength of light in the layer. The diffractive grating preferably has a two-dimensional repeated pattern, such as a square lattice, triangular lattice, or honeycomb lattice pattern.

[Light Condensing Sheet]

In the organic EL element of the present invention, a microlens array structure or a light condensing sheet may be disposed on the supporting substrate at the surface for light extraction, to collect light in a specific direction (e.g., in a front direction of the luminous face of the element), thereby increasing luminance in the specific direction.

For example, the microlens array includes two-dimensionally arranged quadrangular pyramids each having a 30-μm side and a vertex angle of 90°. Each side of the quadrangular pyramid has a length of preferably 10 to 100 μm. A side having a length below this range leads to coloring caused by diffraction, whereas an excessively long side leads to an undesirable increase in thickness of the element.

The light condensing sheet may be, for example, a commercially available sheet used in an LED backlight of a liquid crystal display device. Examples of such a sheet include Brightness Enhancement Film (BEF) (prism sheet) manufactured by Sumitomo 3M Ltd. The prism sheet may be composed of a substrate with triangular stripes having a vertex angle of 90° C. which are arranged at pitches of 50 μm. The vertexes of the triangular prisms may be rounded, or the pitches may be randomly varied. The prism sheet may have any other structure.

In order to control the radiation angle of light from the organic EL element, the light condensing sheet may be used in combination with a light diffusing plate or film; for example, a diffusing film (LIGHT-UP, manufactured by KIMOTO Co., Ltd.).

[Applications]

The organic EL element of the present invention may be used for electronic devices, such as display devices and various light sources.

Examples of light sources include, but are not limited to, lighting devices (e.g., household and in-vehicle lighting devices), backlight units of clocks and liquid crystal displays, billboards, traffic signals, light sources for optical storage media, light sources for electrophotocopiers, light sources for optical communication processors, and light sources for optical sensors. In particular, the organic EL element can be effectively used for a backlight unit of a liquid crystal display device and a light source for illumination.

In the organic EL element of the present invention, the layers may optionally be patterned with a metal mask or by ink jet printing during formation of the layers. The patterning process may be performed on only the electrodes, both the electrodes and the luminous layer, or all the layers of the element. Any known process may be used for preparation of the element.

The color of light emitted from the organic EL element or compound according to the present invention is determined by applying values obtained with a spectroradiometer CS-1000 (manufactured by Konica Minolta, Inc.) to the CIE chromaticity coordinate shown in FIG. 11.16 on page 108 of “Shinpen Shikisai Kagaku Handobukku (Handbook of Color Science)” (edited by the Color Science Association of Japan, published from University of Tokyo Press, 1985).

For emission of white light from the organic EL element of the present invention, the chromaticity in the CIE 1931 Color Specification System at 1,000 cd/m² falls within a region of x=0.33±0.07 and y=0.33±0.1 during determination of front luminance (viewing angle: 2°) by the aforementioned process.

<Display Device>

The display device of the present invention includes the organic EL element of the present invention. The display device of the present invention may be a monochromatic or multicolor display device. Now will be described a multicolor display device.

In the case of a multicolor display device, a shadow mask is provided only during formation of the luminous layer, and each of the other layers may be formed over the entire surface by, for example, vacuum vapor deposition, casting, spin coating, ink jetting, or printing.

Any process can be used for patterning of only the luminous layer. The patterning is preferably performed by vacuum vapor deposition, ink jetting, spin coating, or printing.

The configuration of the organic EL element of the display device is optionally selected from the above-exemplified configurations.

The process of producing the organic EL element of the present invention is as described above in one embodiment.

Application of a DC voltage of about 2 to 40V (anode: positive electrode, cathode: negative electrode) to the resultant multicolor display device leads to emission of light. In contrast, application of a voltage with reverse polarity results in no current flow through the device and no emission of light. If an AC voltage is applied to the device, light is emitted only in the state where the anode is positive and the cathode is negative. The AC voltage to be applied may have any waveform.

The multicolor display device can be used for various display devices or light sources. In the display device, full-color display is achieved with three types of organic EL elements; i.e., blue, red, and green light-emitting elements.

Examples of the display device include television sets, personal computers, mobile devices, AV devices, teletext displays, and information displays in automobiles. In particular, the display device may be used for reproducing still images or moving images. The driving system used in the display device for reproducing moving images may be a simple matrix (passive matrix) type or an active matrix type.

Examples of the light source include, but are not limited to, household lighting devices, in-vehicle lighting devices, backlight units of clocks and liquid crystal displays, billboards, traffic signals, light sources for optical storage media, light sources for electrophotocopiers, light sources for optical communication processors, and light sources for optical sensors.

Now will be described an example of the display device including the organic EL element of the present invention with reference to the drawings.

FIG. 16 is a schematic illustration of an exemplary display device including the organic EL element. FIG. 16 schematically illustrates a display for, for example, a mobile phone to display image information through emission of light by the organic EL element.

A display 1 includes a display unit A having a plurality of pixels, a control unit B for image scanning on the display unit A on the basis of image information, and a wiring unit C that electrically connects the display unit A and the control unit B.

The control unit B, which is electrically connected to the display unit A via the wiring unit C, transmits scanning signals and image data signals to the individual pixels on the basis of external image information. The pixels in each scanning line sequentially emit light in response to the scanning signal on the basis of the image data signal, and the image information is displayed on the display unit A through image scanning.

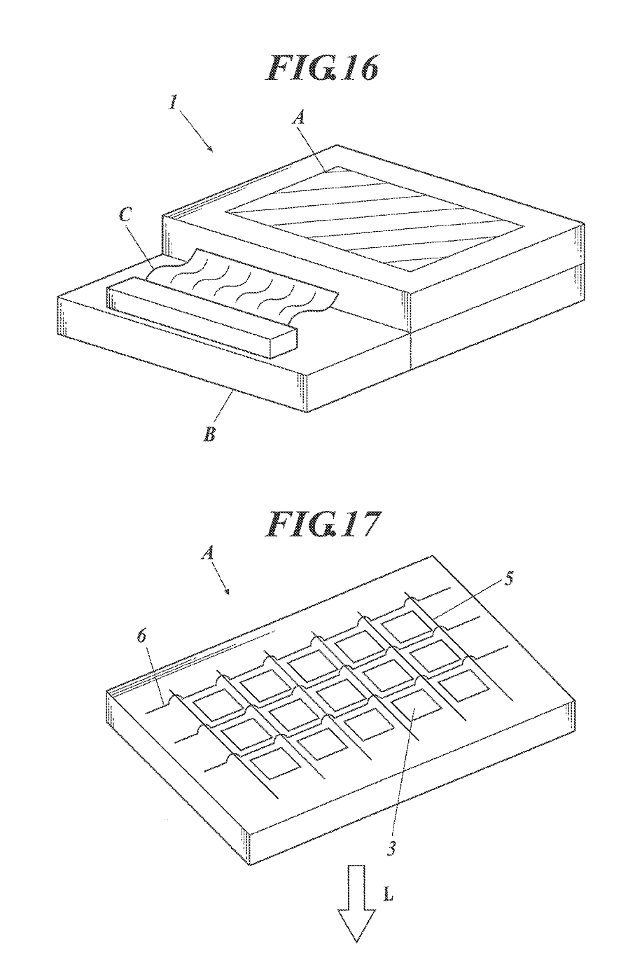

FIG. 17 is a schematic illustration of an active matrix display device.

A display unit A has, on a substrate, a wiring unit C including a plurality of scanning lines 5 and data lines 6, and a plurality of pixels 3. The main components of the display unit A will be described below.

With reference to FIG. 17, light L emitted from the pixels 3 is extracted to the direction shown by the white arrow (downward direction).

The scanning lines 5 and the data lines 6 of the wiring unit are composed of a conductive material and are orthogonal to each other to form a grid pattern. The scanning lines 5 and the data lines 6 are connected to the pixels 3 at orthogonal intersections (details are not illustrated).

When a scanning signal is applied to the scanning lines 5, the pixels 3 receive an image data signal from the data lines 6 and emit light in response to the received image data.

Full-color display is achieved by appropriate arrangement of red, green, and blue light-emitting pixels on a single substrate.

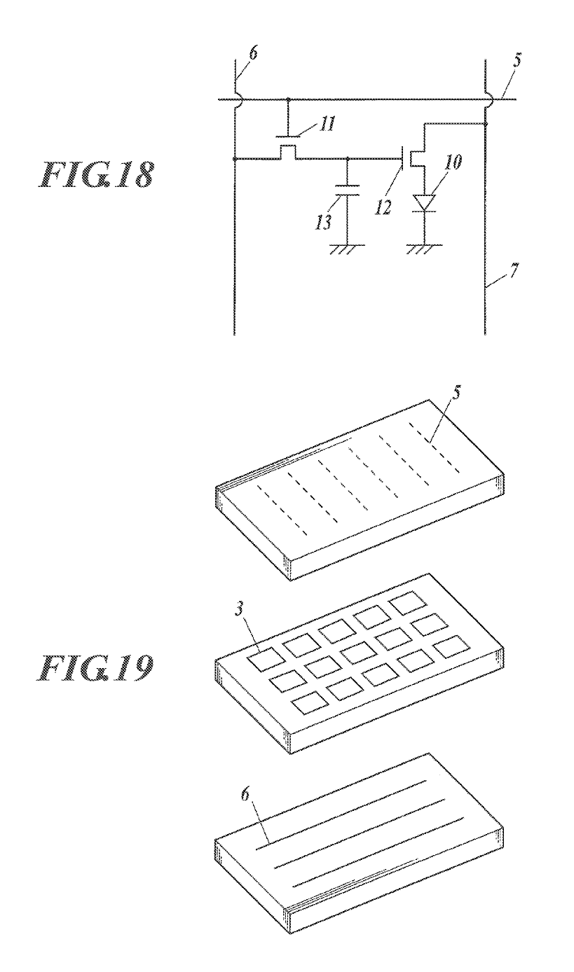

Now will be described the emission process of a pixel. FIG. 18 is a schematic illustration of a pixel circuit.

The pixel includes an organic EL element 10, a switching transistor 11, a driving transistor 12, and a capacitor 13. Full color display is achieved by using a plurality of pixels arranged on a single substrate, each of the pixels including red, green, and blue light-emitting organic EL elements 10.

With reference to FIG. 18, an image data signal from the control unit B is applied to the drain of the switching transistor 11 via the data line 6. When a scanning signal from the control unit B is applied to the gate of the switching transistor 11 via the scanning line 5, the switching transistor 11 is turned on, and the image data signal applied to the drain is transmitted to the gates of the capacitor 13 and the driving transistor 12.

The capacitor 13 is charged through transmission of the image data signal depending on the potential of the image data signal, and the driving transistor 12 is turned off. The drain and source of the driving transistor 12 are connected to a power source line 7 and the electrode of the organic EL element 10, respectively. Depending on the potential of the image data signal applied to the gate, a current is supplied from the power source line 7 to the organic EL element 10.

When the scanning signal is transmitted to the next scanning line 5 through sequential scanning by the control unit B, the switching transistor 11 is turned off. Since the capacitor 13 maintains the charged potential corresponding to the image data signal even after turning off of the switching transistor 11, the driving transistor 12 is maintained in an ON state, and the organic EL element 10 continues to emit light until application of the next scanning signal. Through application of the next scanning signal by sequential scanning, the driving transistor 12 is driven depending on the potential of the subsequent image data signal in synchronization with the scanning signal, and the organic EL element 10 emits light.

In each of the pixels 3, the organic EL element 10 emits light through driving of the switching transistor 11 and the driving transistor 12 serving as active elements. This light-emitting system is called “active matrix type.”

Multi-tone light may be emitted from the organic EL element 10 in response to multivalued image data signals having different gradient potentials. Alternatively, light with a specific intensity from the organic EL element 10 may be turned on or off in response to a binary image data signal. The potential of the capacitor 13 may be maintained until application of the subsequent scanning signal, or the capacitor 13 may be discharged immediately before application of the subsequent scanning signal.

In the present invention, the display device may be not only of the aforementioned active matrix type, but also of a passive matrix type, in which light is emitted from the organic EL element in response to the data signal only during application of the scanning signals.

FIG. 19 is a schematic illustration of a passive matrix display device. With reference to FIG. 19, pixels 3 are disposed between a plurality of scanning lines 5 and a plurality of image data lines 6 to form a grid pattern.

When a scanning signal is applied to a scanning line 5 through sequential scanning, the pixel 3 connected to the scanning line 5 emits light in response to the image data signal.

The passive matrix display device can reduce production cost because of no active element in each pixel 3.

The use of the organic EL element of the present invention achieves a display device exhibiting improved emission efficiency.

<Lighting Device>

The organic EL element of the present invention can also be used for a lighting device.

The organic EL element of the present invention may have a resonator structure. Examples of the application of the organic EL element having a resonator structure include, but are not limited to, light sources for optical storage media, light sources for electrophotocopiers, light sources for optical communication processors, and light sources for optical sensors. Alternatively, the organic EL element of the present invention may be used for the aforementioned purposes by laser oscillation.

The organic EL element of the present invention may be used in a lamp, such as a lighting source or an exposure light source, or may be used in a projector for projecting images or a display device for directly viewing still or moving images.

If the organic EL element is used in a display device for playback of moving images, the display device may be of a passive matrix type or an active matrix type. A full-color display device can be produced from two or more organic EL elements of the present invention that emit light of different colors.

The compound according to the present invention can be applied to a lighting device including an organic EL element that emits substantially white light. White light is produced by mixing light of different colors simultaneously emitted from a plurality of luminous materials. The combination of emitted light of different colors may include light of three primary colors (red, green, and blue) with three maximum emission wavelengths, or light of complementary colors (e.g., blue and yellow or blue-green and orange) with two maximum emission wavelengths.

For preparation of the organic EL element of the present invention, a mask is disposed only during formation of the luminous layer, the hole transporting layer, or the electron transporting layer such that a patterning process is performed simply through the mask. The other layers, which have a common structure, do not require any patterning process with a mask. Thus, an electrode film can be formed on the entire surface of such a layer through, for example, vacuum vapor deposition, casting, spin coating, ink jetting, or printing, resulting in improved productivity.

The element produced by this process emits white light, unlike a white light-emitting organic EL device including arrayed luminous elements that emit light of a plurality of colors.

[Embodiment of Lighting Device of the Present Invention]

Now will be described an embodiment of the lighting device including the organic EL element of the present invention.

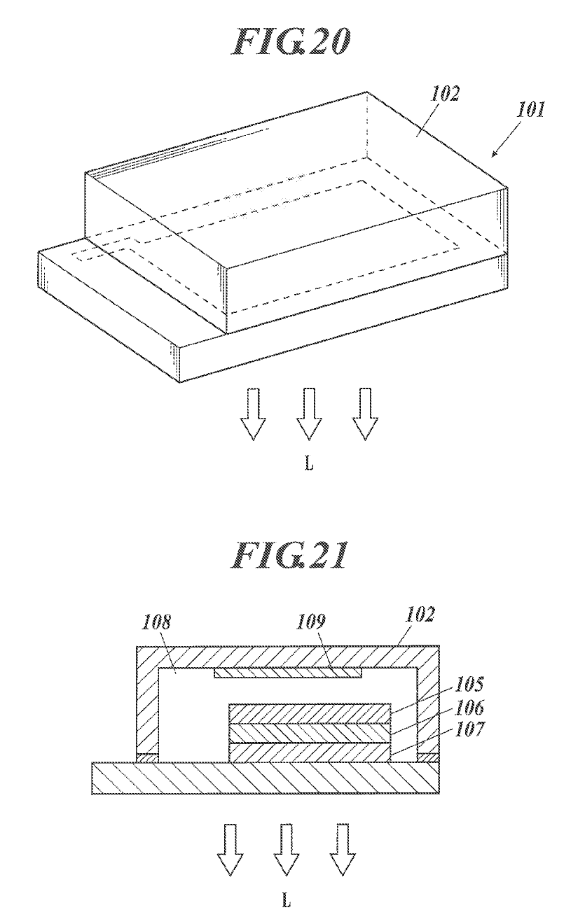

The non-luminous surface of the organic EL element of the present invention is covered with a glass casing, and a glass substrate having a thickness of 300 μm is used as a sealing substrate. A photocurable epoxy adhesive (LUXTRACK LC0629B, manufactured by TOAGOSEI CO., LTD.), serving as a sealing material, is applied to the periphery of the substrate, and the glass casing is placed on the cathode and is attached to the transparent supporting substrate, followed by curing of the adhesive by irradiation of the glass substrate with UV rays. A lighting device shown in FIG. 20 or 21 is thereby produced.

FIG. 20 is a schematic illustration of the lighting device. The organic EL element 101 (in the lighting device) of the present invention is covered with a glass casing 102 (sealing with the glass casing is performed in a glove box under a nitrogen atmosphere (an atmosphere of nitrogen gas having a purity of 99.999% or more) for preventing the organic EL element 101 from being exposed to air). FIG. 21 is a cross-sectional view of the lighting device. As illustrated in FIG. 21, the lighting device includes a cathode 105, an organic EL layer 106, and a glass substrate 107 having a transparent electrode. The interior of the glass casing 102 is filled with nitrogen gas 108 and is provided with a desiccant 109. With reference to FIGS. 17, 20, and 21, emitted light L is extracted to the direction shown by the white arrow (downward direction).

The use of the organic EL element of the present invention achieves a lighting device exhibiting improved emission efficiency.

### EXAMPLES

The present invention will now be described in detail by way of Examples, which should not be construed to limit the invention. Unless otherwise specified, the terms “part(s)” and “%” in the following description indicate “part(s) by mass” and “mass %,” respectively.

In the Examples, the vol % of a compound is determined on the basis of the thickness of a layer composed of the compound measured by a quartz crystal microbalance technique, the calculated mass of the layer, and the specific weight of the compound.

### Example 1

### Preparation of Organic EL Element 1-1

An indium tin oxide (ITO) film having a thickness of 100 nm was deposited on a glass substrate with dimensions of 100 mm by 100 mm by 1.1 mm (NA45, manufactured by AvanStrate Inc. (former company name: NH Techno Glass)) and was patterned into an anode. The transparent support substrate provided with the transparent ITO electrode was ultrasonically cleaned in isopropyl alcohol, dried with dry nitrogen gas, and then subjected to UV ozone cleaning for five minutes.

A solution of 70% poly(3,4-ethylenedioxythiophene)-poly(styrene sulfonate) (PEDOT/PSS; Baytron P Al 4083, manufactured by Bayer) in pure water was applied by spin coating onto the transparent support substrate at 3,000 rpm for 30 seconds. The resultant thin film was dried at 200° C. for one hour, to form a hole injecting layer having a thickness of 20 nm.

The transparent support substrate was fixed to a substrate holder in a commercially available vacuum vapor deposition apparatus. 4,4′,4″-tris[phenyl(m-tolyl)amino]triphenylamine (m-MTDATA) (200 mg) was placed in a molybdenum resistive heating boat, 4,4′,4″-(carbazol-9-yl)-triphenylamine (TCTA) (200 mg) was placed in another molybdenum resistive heating boat, comparative compound C1 (H-159) (200 mg) was placed in still another molybdenum resistive heating boat, and 2,9-dimethyl-4,7-diphenyl-1,10-phenanthroline (BCP) (200 mg) was placed in yet another molybdenum resistive heating boat. These molybdenum resistive heating boats were then placed in the vacuum vapor deposition apparatus.

After evacuation of the vacuum vessel to 4×10⁻⁴ Pa, the heating boat containing m-MTDATA was electrically heated to deposit m-MTDATA onto the hole injecting layer at a deposition rate of 0.1 nm/second, to form a hole transporting layer having a thickness of 30 nm.

The heating boats containing TCTA and comparative compound C1 were then electrically heated to co-deposit TCTA and comparative compound C1 onto the hole transporting layer at deposition rates of 0.1 nm/second and 0.010 nm/second, respectively, to form a luminous layer having a thickness of 30 nm.

The heating boat containing BCP was then electrically heated to deposit BCP onto the luminous layer at a deposition rate of 0.1 nm/second, to form an electron transporting layer having a thickness of 30 nm.

Subsequently, lithium fluoride was deposited into a thickness of 0.5 nm to form a cathode buffer layer, and then aluminum was deposited into a thickness of 110 nm to form a cathode, to prepare an organic EL element 1-1.

### Preparation of Organic EL Elements 1-2 to 1-8

Organic EL elements 1-2 to 1-8 were prepared as in organic EL element 1-1, except that comparative compound C1 was replaced with compounds described in Table 2.

(Evaluation of Continuous Driving Stability (Half-Life))

The luminance of each organic EL element was measured with a spectroradiometer CS-2000, to determine a half-life of luminance (LT50).

Each organic EL element was driven under application of a voltage such that the luminance at initiation of continuous driving was 3,000 cd/m².

The relative LT50 of each organic EL element was determined on the basis of the LT50 (taken as 100) of organic EL element 1-1. The determined relative value was used as an indicator of continuous driving stability. Table 2 illustrates the results of evaluation. As illustrated in Table 2, a larger relative value indicates a higher continuous driving stability (longer lifetime).

TABLE 2

| | | | | | | | Half-life | | |
|---|---|---|---|---|---|---|---|---|---|
| Element | | HOMO | LUMO | ΔE_{H} | ΔE_{L} | ΔE_{H} + ΔE_{L} | of luminance | Delayed | |
| number | Dopant | [eV] | [eV] | [eV] | [eV] | [eV] | (relative value) | fluorescence | Note |
| 1-1 | C1 | −5.3 | −1.2 | 1.0 | 0.3 | 1.3 | 100 | X | Comparative |
| 1-2 | D20 | −4.6 | −1.8 | 1.9 | 1.6 | 3.5 | 117 | ◯ | Inventive |
| 1-3 | D62 | −4.8 | −1.3 | 1.6 | 0.8 | 2.4 | 165 | ◯ | Inventive |
| 1-4 | D13 | −4.8 | −1.6 | 1.8 | 1.1 | 2.9 | 191 | ◯ | Inventive |
| 1-5 | D35 | −5.1 | −1.7 | 2.1 | 0.7 | 2.8 | 183 | ◯ | Inventive |
| 1-6 | D64 | −5.0 | −1.7 | 1.4 | 1.0 | 2.4 | 197 | ◯ | Inventive |
| 1-7 | D10 | −4.8 | −1.8 | 1.8 | 1.5 | 3.3 | 202 | ◯ | Inventive |
| 1-8 | D66 | −5.2 | −1.7 | 1.6 | 0.9 | 2.5 | 141 | ◯ | Inventive |

The results of Table 2 demonstrate that the organic EL element of the present invention exhibits a longer operational life than the comparative organic EL element. The results indicate that an improvement in carrier balance by the configuration of the present invention leads to an enhanced continuous driving stability.

### Example 2

### Preparation of Organic EL Element 2-1

An indium tin oxide (ITO) film having a thickness of 100 nm was deposited on a glass substrate with dimensions of 100 mm by 100 mm by 1.1 mm (NA45, manufactured by AvanStrate Inc. (former company name: NH Techno Glass)) and was patterned into an anode. The transparent support substrate provided with the transparent ITO electrode was ultrasonically cleaned in isopropyl alcohol, dried with dry nitrogen gas, and then subjected to UV ozone cleaning for five minutes.

The transparent support substrate was fixed to a substrate holder in a commercially available vacuum vapor deposition apparatus. Subsequently, 1,4,5,8,9,12-hexaazatriphenylenehexacarbonitrile (HAT-CN) (200 mg), 4,4′-bis[N-(1-naphthyl)-N-phenylamino]biphenyl (α-NPD) (200 mg), 3,3-di(9H-carbazol-9-yl)biphenyl (mCBP) (200 mg), comparative compound C2 (H-146) (200 mg), and 1,3,5-tris(N-phenylbenzimidazol-2-yl)benzene (TPBi) (200 mg) were placed in different molybdenum resistive heating boats, and these heating boats were placed in the vacuum vapor deposition apparatus.

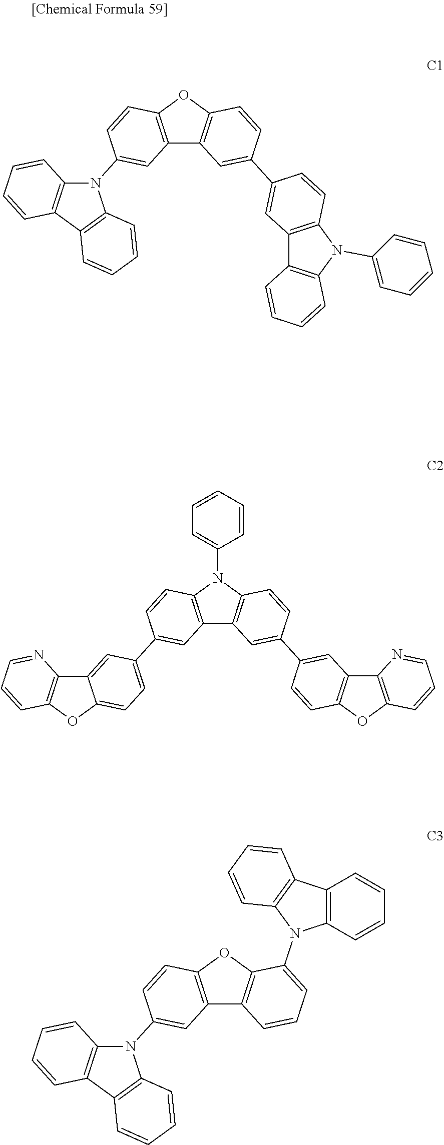 [SMILES: c1ccc(-n2c3ccccc3c3cc(-c4ccc5oc6ccc(-n7c8ccccc8c8ccccc87)cc6c5c4)ccc32)cc1 ; c1ccc(-n2c3ccc(-c4ccc5oc6cccnc6c5c4)cc3c3cc(-c4ccc5oc6cccnc6c5c4)ccc32)cc1 ; c1cc(-n2c3ccccc3c3ccccc32)c2oc3ccc(-n4c5ccccc5c5ccccc54)cc3c2c1]

After evacuation of the vacuum vessel to 4×10⁻⁴ Pa, the heating boat containing HAT-CN was electrically heated to deposit HAT-CN onto the transparent support substrate provided with the transparent ITO electrode at a deposition rate of 0.1 nm/second, to form a hole injecting layer having a thickness of 20 nm.

The heating boat containing α-NPD was electrically heated to deposit α-NPD onto the hole injecting layer at a deposition rate of 0.1 nm/second, to form a hole transporting layer having a thickness of 30 nm.

The heating boats containing mCP and comparative compound C2 were electrically heated to co-deposit mCP and comparative compound C2 onto the hole transporting layer at deposition rates of 0.1 nm/second and 0.010 nm/second, respectively, to form a luminous layer having a thickness of 30 nm.

The heating boat containing TPBi was then electrically heated to deposit TPBi onto the luminous layer at a deposition rate of 0.1 nm/second, to form an electron transporting layer having a thickness of 30 nm.

Subsequently, lithium fluoride was deposited into a thickness of 0.5 nm to form a cathode buffer layer, and then aluminum was deposited into a thickness of 110 nm to form a cathode, to prepare an organic EL element 2-1.

### Preparation of Organic EL Elements 2-2 to 2-8

Organic EL elements 2-2 to 2-8 were prepared as in organic EL element 2-1, except that comparative compound C2 was replaced with compounds described in Table 3.

(Variation in Resistance Through Driving of Organic EL Element)

Each of the organic EL elements prepared as described above was subjected to measurement of the resistance of the luminous layer at a bias voltage of 1 V with 1260 Impedance Analyzer and 1296 Dielectric Interface (manufactured by Solartron) in accordance with the method described in “Hakumaku no Hyoka Handobukku (Handbook of Characterization of Thin Film)” (published by Technosystem Co., Ltd., pp. 423 to 425).

In detail, each of the organic EL elements was driven for 1,000 hours at a constant current density of 2.5 mA/cm² and room temperature (25° C.), and was subjected to measurement of the resistance of the luminous layer before and after the driving of the element. On the basis of the results of measurement, a variation in resistance was calculated for the organic EL element by the expression described below.

Variation in resistance through driving=|(resistance after the driving)/(resistance before the driving)−1|×100

A value near to zero indicates a small variation in resistance through the driving.

Table 3 illustrates the variation in resistance of each organic EL element as a relative value to that (taken as 100) of organic EL element 2-1. A smaller value indicates a smaller variation in resistivity over time.

TABLE 3

| | | | | | | | Variation | | |
|---|---|---|---|---|---|---|---|---|---|
| Element | | HOMO | LUMO | ΔE_{H} | ΔE_{L} | ΔE_{H} + ΔE_{L} | in resistance | Delayed | |
| number | Dopant | [eV] | [eV] | [eV] | [eV] | [eV] | (relative value) | fluorescence | Note |
| 2-1 | C 2 | −5.2 | −1.2 | 1.0 | 0.4 | 1.4 | 100 | X | Comparative |
| 2-2 | D21 | −4.7 | −1.9 | 1.9 | 1.7 | 3.6 | 89 | ◯ | Inventive |
| 2-3 | D63 | −4.9 | −1.6 | 1.4 | 1.0 | 2.4 | 58 | ◯ | Inventive |
| 2-4 | D44 | −4.9 | −1.7 | 1.3 | 1.2 | 2.5 | 43 | ◯ | Inventive |
| 2-5 | D48 | −4.9 | −1.6 | 1.3 | 1.2 | 2.5 | 39 | ◯ | Inventive |
| 2-6 | D55 | −5.0 | −1.4 | 2.5 | 0.8 | 3.3 | 25 | ◯ | Inventive |
| 2-7 | D34 | −5.1 | −1.5 | 2.7 | 0.9 | 3.6 | 33 | ◯ | Inventive |
| 2-8 | D67 | −5.0 | −1.9 | 1.7 | 1.2 | 2.8 | 73 | ◯ | Inventive |

The results of Table 3 demonstrate that variations in physical properties of thin films by energization are reduced in the organic EL element of the present invention as compared with the comparative organic EL element. The results indicate that an improvement in carrier balance by the configuration of the present invention leads to an enhanced stability of thin films.

### Example 3

### Preparation of Organic EL Element 3-1

An indium tin oxide (ITO) film having a thickness of 100 nm was deposited on a glass substrate with dimensions of 100 mm by 100 mm by 1.1 mm (NA45, manufactured by AvanStrate Inc. (former company name: NH Techno Glass)) and was patterned into an anode. The transparent support substrate provided with the transparent ITO electrode was ultrasonically cleaned in isopropyl alcohol, dried with dry nitrogen gas, and then subjected to UV ozone cleaning for five minutes.

A solution of 70% PEDOT/PSS in pure water was applied by spin coating onto the transparent support substrate at 3,000 rpm for 30 seconds. The resultant thin film was dried at 200° C. for one hour, to form a hole injecting layer having a thickness of 20 nm.

The transparent support substrate was fixed to a substrate holder in a commercially available vacuum vapor deposition apparatus. α-NPD (200 mg) was placed in a molybdenum resistive heating boat, CBP (200 mg) was placed in another molybdenum resistive heating boat, comparative compound C3 (H-115) (200 mg) was placed in still another molybdenum resistive heating boat, and 4,7-diphenyl-1,10-phenanthroline (Bphen) (200 mg) was placed in yet another molybdenum resistive heating boat. These molybdenum resistive heating boats were then placed in the vacuum vapor deposition apparatus.

After evacuation of the vacuum vessel to 4×10⁻⁴ Pa, the heating boat containing α-NPD was electrically heated to deposit α-NPD onto the hole injecting layer at a deposition rate of 0.1 nm/second, to form a hole transporting layer having a thickness of 30 nm.

The heating boats containing CBP and comparative compound C3 were then electrically heated to co-deposit CBP and comparative compound C3 onto the hole transporting layer at deposition rates of 0.1 nm/second and 0.010 nm/second, respectively, to form a luminous layer having a thickness of 20 nm.

The heating boat containing BPhen was then electrically heated to deposit BPhen onto the luminous layer at a deposition rate of 0.1 nm/second, to form an electron transporting layer having a thickness of 30 nm.

Subsequently, lithium fluoride was deposited into a thickness of 0.5 nm to form a cathode buffer layer, and then aluminum was deposited into a thickness of 110 nm to form a cathode, to prepare an organic EL element 3-1.

### Preparation of Organic EL Elements 3-2 to 3-6

Organic EL elements 3-2 to 3-6 were prepared as in organic EL element 3-1, except that comparative compound C3 was replaced with compounds described in Table 4.

(Evaluation of Continuous Driving Stability (Half-Life))

The luminance of each organic EL element was measured with a spectroradiometer CS-2000, to determine a half-life of luminance (LT50).

Each organic EL element was driven under application of a voltage such that the luminance at initiation of continuous driving was 3,000 cd/m².

The relative LT50 of each organic EL element was determined on the basis of the LT50 (taken as 100) of organic EL element 3-1. The determined relative value was used as an indicator of continuous driving stability. Table 4 illustrates the results of evaluation. As illustrated in Table 4, a larger relative value indicates a higher continuous driving stability (longer lifetime).

TABLE 4

| | | | | | | | Half-life | |
|---|---|---|---|---|---|---|---|---|
| Element | | HOMO | LUMO | ΔE_{H} | ΔE_{L} | ΔE_{H} + ΔE_{L} | of luminance | |
| number | Dopant | [eV] | [eV] | [eV] | [eV] | [eV] | (relative value) | Note |
| 3-1 | C3 | −5.4 | −1.4 | 1.1 | 0.7 | 1.8 | 100 | Comparative |
| 3-2 | D54 | −4.9 | −1.8 | 1.2 | 1.0 | 2.2 | 129 | Inventive |
| 3-3 | D64 | −5.0 | −1.7 | 1.4 | 1.0 | 2.5 | 168 | Inventive |
| 3-4 | D69 | −5.1 | −1.5 | 2.1 | 0.6 | 2.7 | 132 | Inventive |
| 3-5 | D53 | −5.0 | −1.5 | 2.1 | 0.7 | 2.8 | 180 | Inventive |
| 3-6 | D29 | −4.9 | −1.8 | 1.7 | 1.3 | 3.0 | 207 | Inventive |

The results of Table 4 demonstrate that the organic EL element of the present invention exhibits a longer operational life than the comparative organic EL element. The results also demonstrate that a ΔE_{H} value of higher than the threshold leads to a significant improvement in performance of the organic EL element of the present invention, and a ΔE_{L} value of higher than the threshold also leads to a significant improvement in performance of the organic EL element. These results indicate that the sum of ΔE_{H} and ΔE_{L} should be 2.0 eV or more for an improvement in the carrier balance in the organic EL element of the present invention, and a ΔE_{H} value of 1.3 eV or more and a ΔE_{L} value of 0.7 eV or more are preferred for an improvement in the carrier balance.

### Example 4

Each of the dopants (exemplary compounds) described in Tables 2 to 4 was dissolved in toluene, and the emission lifetime of a solution sample was measured at 300 K. The emission lifetime of the solution sample was determined on the basis of transient PL characteristics. Transient PL characteristics were determined with a small fluorescence lifetime analyzer (C11367-03, manufactured by Hamamatsu Photonics K.K.). In detail, a slow decay component was measured by an M9003-01 mode using a flash lamp as an excitation source, and a fast decay component was measured by a TCC900 mode using an LED (340 nm) as an excitation source. In this case, a fluorescence component is observed on the order of nanoseconds, and a delayed fluorescence component derived from phosphorescence and the triplet state is observed on the order of microseconds or milliseconds. All the compounds (except for C1 and C2) exhibited an emission lifetime of one microsecond or longer in an oxygen-free atmosphere, and only emission with a lifetime on the order of nanoseconds was observed in an oxygen atmosphere. Table 5 illustrates the results of measurement. The results demonstrate that the triplet state affects the emission of the dopant compounds (except for C1, C2, and C3) described in Table 5. Thus, the dopant compounds (except for C1, C2, and C3) described in Table 5 were determined to be thermally activated delayed fluorescent (TADF) compounds in consideration of observation of an emission component exhibiting a lifetime of one microsecond or longer at room temperature.

TABLE 5

| | Delayed | |
|---|---|---|
| Depant | fluorescence | Note |
| C1 | X | Comparative |
| C2 | X | Comparative |
| C3 | X | Comparative |
| D20 | ◯ | Inventive |
| D62 | ◯ | Inventive |
| D13 | ◯ | Inventive |
| D35 | ◯ | Inventive |
| D64 | ◯ | Inventive |
| D10 | ◯ | Inventive |
| D21 | ◯ | Inventive |
| D63 | ◯ | Inventive |
| D44 | ◯ | Inventive |
| D48 | ◯ | Inventive |
| D55 | ◯ | Inventive |
| D34 | ◯ | Inventive |
| D66 | ◯ | Inventive |
| D67 | ◯ | Inventive |
| D54 | ◯ | Inventive |
| D69 | ◯ | Inventive |
| D53 | ◯ | Inventive |
| D29 | ◯ | Inventive |

The above-described results demonstrate that an organic EL element satisfying the requirements of the present invention maintains the quality of thin films and exhibits prolonged operational life.

### INDUSTRIAL APPLICABILITY

The present invention can provide an organic electroluminescent element that emits blue light with high chromaticity and that exhibits high emission efficiency over a long period of time. The organic EL element is suitable for use in display devices, household lighting devices, in-vehicle lighting devices, backlight units of clocks and liquid crystal displays, billboards, traffic signals, light sources for optical storage media, light sources for electrophotocopiers, light sources for optical communication processors, light sources for optical sensors, and light sources for, for example, common household electric appliances requiring display devices.

### EXPLANATION OF REFERENCE NUMERALS

AC: electron acceptor moiety
DN: electron donor moiety
1: display
3: pixel
5: scanning line
6: data line
7: power source line
10: organic EL element
11: switching transistor
12: driving transistor
13: capacitor
101: organic EL element in lighting device
102: glass casing
105: cathode
106: organic EL layer
107: glass substrate having transparent electrode
108: nitrogen gas
109: water-collecting agent
A: display unit
B: control unit
C: wiring unit
L: light

1. An organic electroluminescent element comprising:
an organic layer comprising a compound having an electron donor moiety and an electron acceptor moiety in a single molecule, the compound satisfying the following expression: (ΔE_{H}+ΔE_{L})≧2.0 eV where ΔE_{H} represents a difference in energy level between a highest energy occupied molecular orbital spreading over the electron donor moiety and a highest energy occupied molecular orbital spreading over the electron acceptor moiety, and ΔE_{L} represents a difference in energy level between a lowest energy unoccupied molecular orbital spreading over the electron donor moiety and a lowest energy unoccupied molecular orbital spreading over the electron acceptor moiety, these energy levels being determined by molecular orbital calculation, wherein
a highest energy occupied molecular orbital of the compound has an energy level of −5.2 eV or more determined by the molecular orbital calculation, and
a lowest energy unoccupied molecular orbital of the compound has an energy level of −1.2 eV or less determined by the molecular orbital calculation.

2. The organic electroluminescent element according to claim 1, wherein the compound emits thermally activated delayed fluorescence.

3. The organic electroluminescent element according to claim 1, wherein the compound has a structure including a conjugated plane having at least 18 π-electrons.

4. The organic electroluminescent element according to claim 1, wherein the compound has a condensed ring structure composed of two or more 5-membered rings.

5. The organic electroluminescent element according to claim 1, wherein the compound has a structure represented by Formula (1): 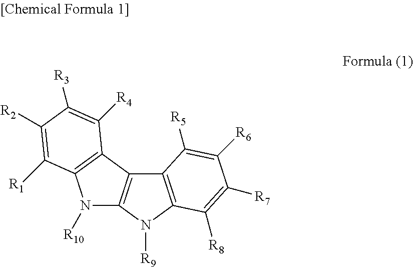
where R₁ to R₁₀, which are optionally identical to or different from one another, each represent a hydrogen atom, an alkyl group having 1 to 10 carbon atoms, an aryl or heteroaryl group having 6 to 30 carbon atoms; at least one of R₁ to R₁₀ represents an electron withdrawing aryl or heteroaryl group; and R₁ to R₁₀ each optionally have an substituent.

6. The organic electroluminescent element according to claim 5, wherein the compound has a structure represented by Formula (2): 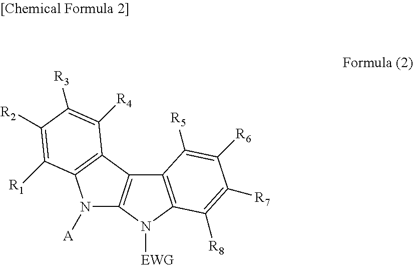
where R₁ to R₈, which are optionally identical to or different from one another, each represent a hydrogen atom, an alkyl group having 1 to 10 carbon atoms, or an aryl or heteroaryl group having 6 to 30 carbon atoms; A represents an alkyl group having 1 to 10 carbon atoms or an aryl or heteroaryl group having 6 to 30 carbon atoms, and A is optionally substituted by an alkyl group having 1 to 10 carbon atoms or an aryl or heteroaryl group having 6 to 12 carbon atoms, or optionally forms a ring with any substituent; EWG represents an electron withdrawing aryl or heteroaryl group; and R₁ to R₈, A, and EWG each optionally have a substituent.

7. The organic electroluminescent element according to claim 6, wherein the compound has a structure represented by Formula (3): 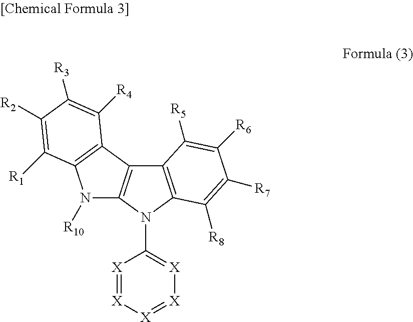
where R₁ to R₈, which are optionally identical to or different from one another, each represent a hydrogen atom, an alkyl group having 1 to 10 carbon atoms, or an aryl or heteroaryl group having 6 to 30 carbon atoms; A represents an alkyl group having 1 to 10 carbon atoms or an aryl or heteroaryl group having 6 to 30 carbon atoms, and A is optionally substituted by an alkyl group having 1 to 10 carbon atoms or an aryl or heteroaryl group having 6 to 12 carbon atoms, or optionally forms a ring with any substituent; X represents a carbon or nitrogen atom and is optionally substituted by an alkyl group having 1 to 10 carbon atoms or an aryl or heteroaryl group having 6 to 50 carbon atoms; the atoms represented by X are optionally identical to or different from one another; and R₁ to R₈, A, and X each optionally have a substituent.

8. A display device comprising the organic electroluminescent element according to claim 1.

9. A lighting device comprising the organic electroluminescent element according to claim 1.

10. A luminous composition comprising:
a compound having an electron donor moiety and an electron acceptor moiety in a single molecule, the compound satisfying the following expression: (ΔE_{H}+ΔE_{L})≧2.0 eV where ΔE_{H} represents a difference in energy level between a highest energy occupied molecular orbital spreading over the electron donor moiety and a highest energy occupied molecular orbital spreading over the electron acceptor moiety, and ΔE_{L} represents a difference in energy level between a lowest energy unoccupied molecular orbital spreading over the electron donor moiety and a lowest energy unoccupied molecular orbital spreading over the electron acceptor moiety, these energy levels being determined by molecular orbital calculation, wherein
a highest energy occupied molecular orbital of the compound has an energy level of −5.2 eV or more determined by the molecular orbital calculation, and
a lowest energy unoccupied molecular orbital of the compound has an energy level of −1.2 eV or less determined by the molecular orbital calculation.
